(19) United States
(12) Patent Application Publication
(10) Pub. No.: US 2025/0179104 A1
(43) Pub. Date: Jun. 5, 2025

(54) ORGANIC COMPOUND AND ORGANIC LIGHT-EMITTING ELEMENT

(71) Applicant: CANON KABUSHIKI KAISHA, TOKYO (JP)

(72) Inventors: TAKAYUKI HORIUCHI, KANAGAWA (JP); YOSUKE NISHIDE, KANAGAWA (JP); NAOKI YAMADA, TOKYO (JP)

(21) Appl. No.: 18/967,430

(22) Filed: Dec. 3, 2024

(30) Foreign Application Priority Data
Dec. 5, 2023 (JP) 2023-205002

(51) Int. Cl. C07F 15/00; C09K 11/06; H10K 85/30

(52) U.S. Cl. CPC C07F 15/0033; C09K 11/06; H10K 85/342

(57) ABSTRACT

An organic light-emitting element with high color purity and durability by introducing one ligand L₁ with a naphtho[2,1-f]isoquinoline skeleton and a tricyclic or polycyclic ring A bound together and two ligands L₂ with a phenylpyridine skeleton into a molecule to produce an iridium complex with high color purity and thermal stability and introducing the iridium complex as a guest into a light-emitting layer.

### BACKGROUND OF THE INVENTION

### Technical Field

The present disclosure relates to a novel organic compound and an organic light-emitting element using the organic compound.

### Description of the Related Art

An organic light-emitting element (hereinafter sometimes referred to as an “organic electroluminescent element” or an “organic EL element”) is an electronic element that includes a pair of electrodes and an organic compound layer between the electrodes. Electrons and holes are injected from the pair of electrodes to generate an exciton of a light-emitting organic compound in the organic compound layer. When the exciton returns to its ground state, the organic light-emitting element emits light. With recent significant advances in organic light-emitting elements, it is possible to realize low drive voltage, various emission wavelengths, high-speed responsivity, and thin and lightweight light-emitting devices.

Compounds suitable for organic light-emitting elements have been actively developed. This is because a compound that provides an element with good lifetime characteristics is important for high-performance organic light-emitting elements. The following iridium complex is described in Japanese Patent Laid-Open No. 2014-127687 as a compound that has been developed.

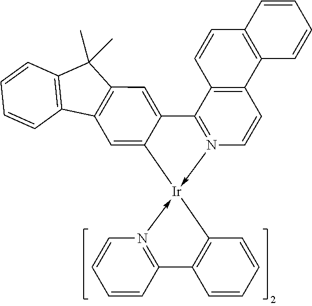

Japanese Patent Laid-Open No. 2014-127687 discloses the use of an iridium complex as a light-emitting material in a light-emitting layer of an organic light-emitting element, but further improvements in color purity and thermal stability are desired.

### SUMMARY OF THE INVENTION

The present disclosure has been made in view of the above disadvantages and provides an organic compound with high color purity and thermal stability and an organic light-emitting element with high color purity and durability using the organic compound.

An organic compound according to the present disclosure is represented by formula (1):

Ir(L₁)(L₂)₂ (1)
wherein Ir(L₁) is represented by formula (1-1), and Ir(L₂)₂ is represented by formula (1-2):

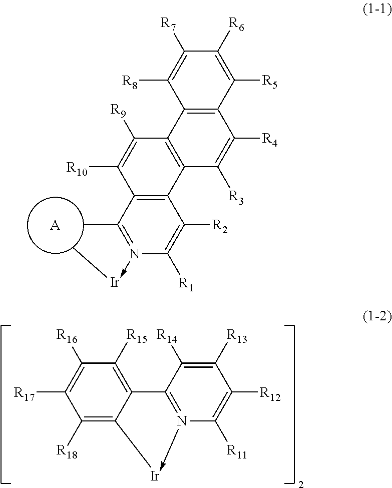

wherein a ring A is selected from a substituted or unsubstituted tricyclic or polycyclic fused ring,
R₁ to R₁₀ in formula (1-1) and R₁₁ to R₁₈ in formula (1-2) are each independently selected from the group consisting of a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heterocyclic group, a substituted or unsubstituted amino group, a substituted or unsubstituted aryloxy group, a substituted or unsubstituted heteroaryloxy group, and a cyano group,
adjacent substituents Rs in R₁ to R₁₀ and R₁₁ to R₁₈ may be bonded together to form a ring, and
two ligands L₂ may have different structures.

Further features of the present disclosure will become apparent from the following description of exemplary embodiments with reference to the attached drawings.

### BRIEF DESCRIPTION OF THE DRAWINGS

FIG. 1A is a schematic cross-sectional view of an example of a pixel of a display apparatus according to an embodiment of the present disclosure.

FIG. 1B is a schematic cross-sectional view of an example of a display apparatus including an organic light-emitting element according to an embodiment of the present disclosure.

FIG. 2 is a schematic view of an example of a display apparatus according to an embodiment of the present disclosure.

FIG. 3A is a schematic view of an example of an imaging apparatus according to an embodiment of the present disclosure.

FIG. 3B is a schematic view of an example of electronic equipment according to an embodiment of the present disclosure.

FIG. 4A is a schematic view of an example of a display apparatus according to an embodiment of the present disclosure.

FIG. 4B is a schematic view of an example of a foldable display apparatus.

FIG. 5A is a schematic view of an example of a lighting apparatus according to an embodiment of the present disclosure.

FIG. 5B is a schematic view of an example of an automobile with a vehicle lamp according to an embodiment of the present disclosure.

FIG. 6A is a schematic view of an example of a wearable device according to an embodiment of the present disclosure.

FIG. 6B is a schematic view of another example of a wearable device according to an embodiment of the present disclosure.

FIG. 7A is a schematic view of an example of an image-forming apparatus according to an embodiment of the present disclosure.

FIGS. 7B and 7C are schematic views of an exposure light source for an image-forming apparatus according to an embodiment of the present disclosure.

### DESCRIPTION OF THE EMBODIMENTS

Embodiments of the present disclosure are described below. The invention is not limited to the following description, and it is easily understood by those skilled in the art that modes and details thereof can be modified in various ways without departing from the gist and scope of the present disclosure. Thus, the invention is not construed as being limited by the following description.

### [Organic Compound]

First, an organic compound according to the present disclosure is described. An organic compound according to the present disclosure is a compound represented by the following general formula (1):

Ir(L₁)(L₂)₂ (1)
wherein a substructure Ir(L₁) is represented by the following general formula (1-1), and a substructure Ir(L₂)₂ is represented by the following general formula (1-2),

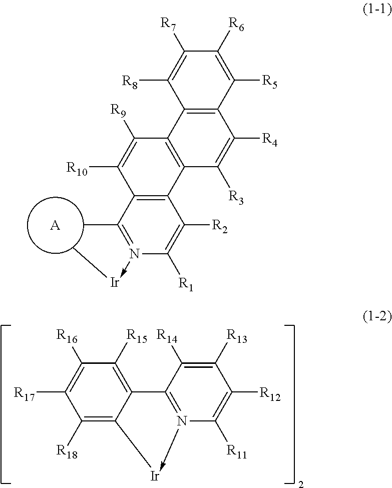

wherein a ring A is selected from a substituted or unsubstituted tricyclic or polycyclic fused ring,
R₁ to R₁₀ in the general formula (1-1) and R₁₁ to R₁₈ in the general formula (1-2) are each independently selected from a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heterocyclic group, a substituted or unsubstituted amino group, a substituted or unsubstituted aryloxy group, a substituted or unsubstituted heteroaryloxy group, and a cyano group,
adjacent substituents Rs in R₁ to R₁₀ and R₁₁ to R₁₈ may be bonded together to form a ring, and
two ligands L₂ may have different structures.

The tricyclic or polycyclic fused ring constituting the ring A is, for example, but not limited to, a fluorene ring, an anthracene ring, a phenanthrene ring, a fluoranthene ring, a pyrene ring, a chrysene ring, a benzo[c]phenanthrene ring, a benzo[a]fluorene ring, a benzo[b]fluorene ring, a benzo[c]fluorene ring, a triphenylene ring, a perylene ring, an acridine ring, a phenanthroline ring, a dibenzofuran ring, a dibenzothiophene ring, a carbazole ring, a benzo[b]naphtho[1,2-d]furan ring, a benzo[b]naphtho[2,3-d]furan ring, a benzo[b]naphtho[2,1-d]furan ring, a benzo[b]naphtho[1,2-d]thiophene ring, a benzo[b]naphtho[2,3-d]thiophene ring, a benzo[b]naphtho[2,1-d]thiophene ring, an indolo[3,2,1-jk]carbazole ring, or the like. In particular, a fluorene ring, a phenanthrene ring, a dibenzofuran ring, a dibenzothiophene ring, and a carbazole ring can be used.

At least one of R₁ to R₁₀ in the general formula (1-1) and at least one of R₁₁ to R₁₈ in the general formula (1-2) can be selected from a deuterium atom, a halogen atom, a substituted or unsubstituted alkyl group, a substituted or unsubstituted aryl group, a substituted or unsubstituted heterocyclic group, and a cyano group.

The halogen atom can be fluorine, chlorine, bromine, iodine, or the like.

The alkyl group is, for example, but not limited to, a methyl group, an ethyl group, a n-propyl group, an iso-propyl group, a n-butyl group, a tert-butyl group, an iso-butyl group, a sec-butyl group, an octyl group, a dodecyl group, a cyclohexyl group, a 1-adamantyl group, a 2-adamantyl group, or the like. In particular, a methyl group and a tert-butyl group can be used.

The alkoxy group is, for example, but not limited to, a methoxy group, an ethoxy group, a propoxy group, a 2-ethyl-octyloxy group, a benzyloxy group, or the like.

The silyl group is, for example, but not limited to, a trimethylsilyl group, a triphenylsilyl group, or the like.

The aryl group is, for example, but not limited to, a phenyl group, a naphthyl group, an indenyl group, a biphenyl group, a terphenyl group, a fluorenyl group, an anthracenyl group, a phenanthryl group, a fluoranthenyl group, a pyrenyl group, a chrysenyl group, a triphenylenyl group, a perylenyl group, or the like. In particular, a phenyl group, a biphenyl group, and a terphenyl group can be used.

The heterocyclic group is, for example, but not limited to, a pyridyl group, a pyrimidyl group, a pyrazyl group, a triazyl group, a triazolyl group, an oxazolyl group, an oxadiazolyl group, a thiazolyl group, a thiadiazolyl group, a quinolyl group, an acridinyl group, a phenanthrolyl group, a dibenzofuranyl group, a dibenzothienyl group, or the like. In particular, a pyridyl group, a pyrimidyl group, a pyrazyl group, and a triazyl group can be used. The heterocyclic group can be a heteroaryl group or a group bonded through a carbon atom.

The amino group is, for example, but not limited to, an N-methylamino group, an N-ethylamino group, an N,N-dimethylamino group, an N,N-diethylamino group, an N-methyl-N-ethylamino group, an N-benzylamino group, an N-methyl-N-benzylamino group, an N,N-dibenzylamino group, an anilino group, an N,N-diphenylamino group, an N,N-dinaphthylamino group, an N,N-difluorenylamino group, an N-phenyl-N-tolylamino group, an N,N-ditolylamino group, an N-methyl-N-phenylamino group, an N,N-dianisolylamino group, an N-mesityl-N-phenylamino group, an N,N-dimesitylamino group, an N-phenyl-N-(4-tert-butylphenyl)amino group, an N-phenyl-N-(4-trifluoromethylphenyl)amino group, an N-piperidyl group, a carbazolyl group, or the like.

The aryloxy group and the heteroaryloxy group are, but not limited to, a phenoxy group, a thienyloxy group, or the like.

An additional optional substituent of the tricyclic or polycyclic fused ring, the alkyl group, the alkoxy group, the silyl group, the aryl group, the heterocyclic group, the amino group, the aryloxy group, and the heteroaryloxy group is, for example, but not limited to, a deuterium atom; a halogen atom, such as fluorine, chlorine, bromine, or iodine; an alkyl group, such as a methyl group, an ethyl group, a n-propyl group, an iso-propyl group, a n-butyl group, or a tert-butyl group; an alkoxy group, such as a methoxy group, an ethoxy group, or a propoxy group; an amino group, such as a dimethylamino group, a diethylamino group, a dibenzylamino group, a diphenylamino group, or a ditolylamino group; an aryloxy group, such as a phenoxy group; an aromatic hydrocarbon group, such as a phenyl group or a biphenyl group; a heterocyclic group, such as a pyridyl group or a pyrrolyl group; a cyano group, a hydroxy group, a thiol group, or the like.

The two ligands L₂ may have different structures.

An organic compound according to the present disclosure is an iridium complex composed of a ligand L₁ and a ligand L₂, the ligand L₁ having a structure with a naphtho[2,1-f]isoquinoline skeleton bonded to the ring A, which is a tricyclic or polycyclic fused ring, and the ligand L₂ having a phenylpyridine skeleton. An organic compound according to the present disclosure has one L₁ and two L₂s in its molecule and can therefore have high color purity and thermal stability. Furthermore, an organic compound according to the present disclosure used as a light-emitting material in a light-emitting layer of an organic light-emitting element can achieve high durability. The operation and effect mechanism thereof is described in detail below.

### <Ring A>

In the general formula (1-1), the ring A is a fused ring bonded to the naphtho[2,1-f]isoquinoline skeleton and affects the phosphorescence characteristics of the organic compound represented by the general formula (1). The ring A is selected from a substituted or unsubstituted tricyclic or polycyclic fused ring. In doing so, the organic compound represented by the general formula (1) generates red phosphorescence with high color purity. The term “red”, as used herein, refers to light with a maximum peak wavelength of 590 nm or more and 640 nm or less in an emission spectrum. Furthermore, red with high color purity is preferably 630 nm or more.

For red-light emission with higher color purity, the ring A can be selected from a substituted or unsubstituted fluorene ring, a substituted or unsubstituted phenanthrene ring, a substituted or unsubstituted dibenzofuran ring, a substituted or unsubstituted dibenzothiophene ring, and a substituted or unsubstituted carbazole ring.

An indicator of emission color may be (X, Y) chromaticity coordinates of the CIE color system. The primary color point of red is (0.670, 0.330) in the NTSC standard and (0.708, 0.292) in the BT. 2020. The higher the X value and the lower the Y value of the chromaticity coordinates, the higher the red color purity and the easier it is to improve the coverage. Since the light-emitting material tends to aggregate in the light-emitting layer of the organic light-emitting element and the color purity tends to deteriorate as compared with that in the solution, preferably, X is 0.69 or more and Y is 0.31 or less in the solution as red with high color purity.

Tables 1 and 2 show the phosphorescence peak wavelength in a dilute toluene solution and the chromaticity calculated from a phosphorescence spectrum of Exemplary Compound A-1 of an organic compound according to the present disclosure and Comparative Compounds 1 to 7 not corresponding to organic compounds according to the present disclosure. Exemplary Compound A-1 and Comparative Compounds 3 and 4 have a ligand with naphtho[2,1-f]isoquinoline and 9,9-dimethylfluorene bound together, have chromaticity beyond that of the NTSC standard red, and can therefore be suitably used in an organic light-emitting element for display applications. On the other hand, Comparative Compounds 1 and 2 having a ligand with benzo[f]isoquinoline and 9,9-dimethylfluorene bound together had chromaticity similar to that of the NTSC standard red. Comparative Compound 5 having a ligand with naphtho[2,1-f]isoquinoline bonded to a benzene ring had poorer chromaticity than that of the NTSC standard red, and Comparative Compound 6 having a ligand with naphtho[2,1-f]isoquinoline bonded to a naphthalene ring, which is a bicyclic fused ring, had chromaticity similar to that of the NTSC standard red. On the other hand, Comparative Compound 7 having a ligand with naphtho[2,1-f]isoquinoline and a benzene ring bound together and having an acetylacetone ligand had slightly poorer chromaticity than that of the NTSC standard red.

A phosphorescence spectrum was measured with a fluorescence spectrophotometer (F-4500 manufactured by Hitachi, Ltd.) after a 1×10⁻⁶ mol·dm⁻³ toluene solution of each compound was prepared and subjected to nitrogen bubbling for 3 minutes.

TABLE 1

| | | Phosphorescence | |
|---|---|---|---|
| | | peak | |
| Compound | | wavelength | |
| name | Structure | [nm] | Chromaticity |
| Exemplary compound A-1 | 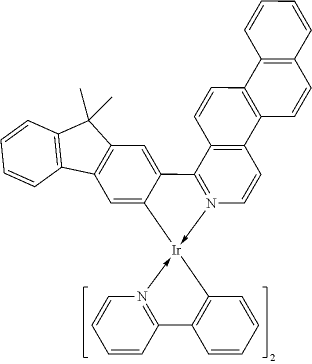 | 635 | (0.694, 0.303) |
| Comparative compound 1 | 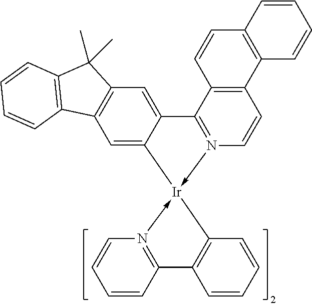 | 623 | (0.674, 0.324) |
| Comparative compound 2 | 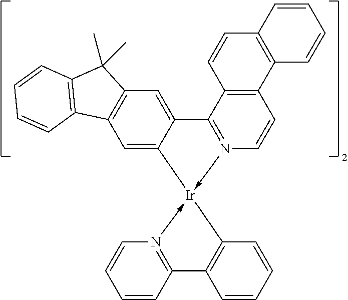 | 622 | (0.676, 0.322) |
| Comparative compound 3 | 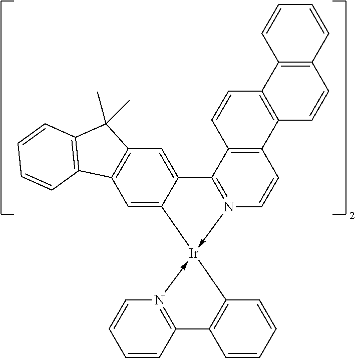 | 640 | (0.692, 0.300) |
| Comparative compound 4 | 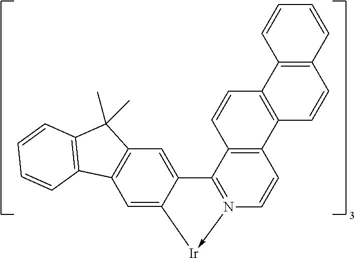 | 639 | (0.692, 0.297) |

TABLE 2

| | | Phosphorescence | |
|---|---|---|---|
| | | peak | |
| Compound | | wavelength | |
| name | Structure | [nm] | Chromaticity |
| Comparative compound 5 | 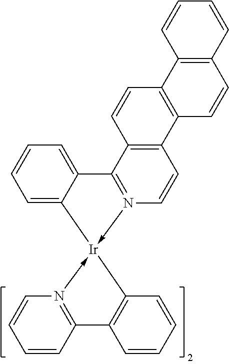 | 607 | (0.639, 0.360) |
| Comparative compound 6 | 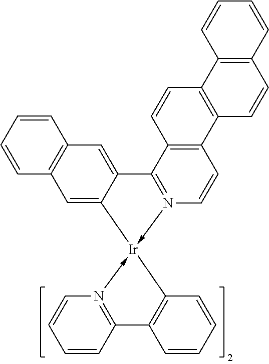 | 625 | (0.679, 0.321) |
| Comparative compound 7 | 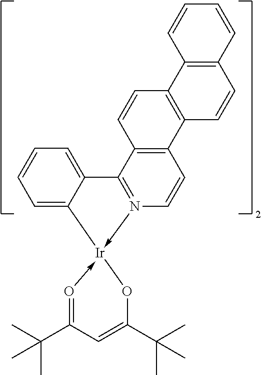 | 616 | (0.659, 0.341) |

### <Ligand L₁>

An organic compound according to the present disclosure has the ligand L₁ with the naphtho[2,1-f]isoquinoline skeleton and the ligand L₂ with the phenylpyridine skeleton as ligands to an iridium atom. The ligand L₁ is a site that dominates light emission properties, but on the other hand, because of its high planarity, reduces sublimability due to intermolecular stacking. Thus, from the perspective of sublimability, the molecule can have only one ligand L₁ and two ligands L₂.

Table 3 shows the initial sublimation temperature Ts [° C.], the decomposition temperature Td [° C.], and the difference ΔT (=Td−Ts) [° C.] between the initial sublimation temperature Ts and the decomposition temperature Td of Exemplary Compound A-1, which is an organic compound according to the present disclosure, and Comparative Compounds 1 to 4 and 7 not corresponding to organic compounds according to the present disclosure. As ΔT increases, decomposition is less likely to occur during a sublimation process, such as sublimation purification or vapor deposition film formation, and degradation of element performance due to a decomposition product is also less likely to occur. Among the compounds in Table 2, Exemplary Compound A-1 and Comparative Compound 1 have high ΔT and thermal stability. Comparative Compounds 2 and 7 can be subjected to the sublimation process but, due to low ΔT, may be decomposed depending on the heating state. Comparative Compounds 3 and 4 are decomposed before sublimation and cannot be subjected to the sublimation process.

Ts and Td were measured with a thermogravimetric-differential thermal analyzer (manufactured by Bruker AXS K.K.). More specifically, under a vacuum of the order of 10⁻⁴ Pa, a sample was heated at a constant temperature for 10 minutes in a stepwise manner at 10° C. intervals between 300° C. and 420° C. The temperature at which weight loss started was denoted by Ts, and the temperature at which a decrease in the degree of vacuum due to thermal decomposition started was denoted by Td. The heating rate to 300° C. is 10° C./min, and the rate at which the temperature is raised by 10° C. at 300° C. or more is 1° C./min.

TABLE 3

| Compound name | Structure | Ts [°C.] | Td [°C.] | ΔT [°C.] |
|---|---|---|---|---|
| Exemplary compound A-1 | 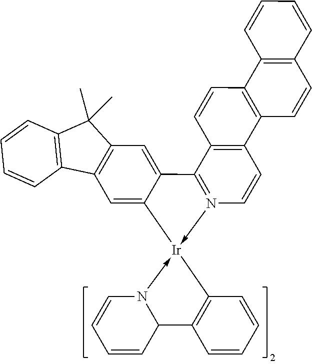 | 330 | 380 | 50 |
| Comparative compound 1 | 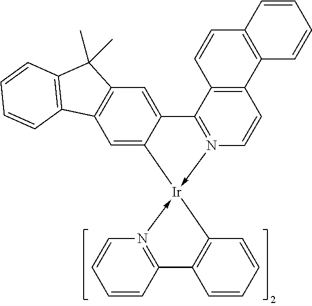 | 320 | 380 | 60 |
| Comparative compound 2 | 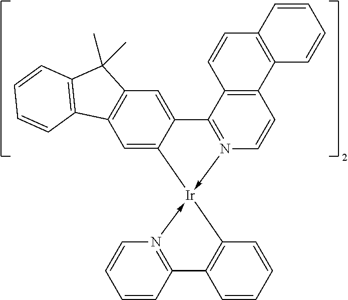 | 370 | 390 | 20 |
| Comparative compound 3 | 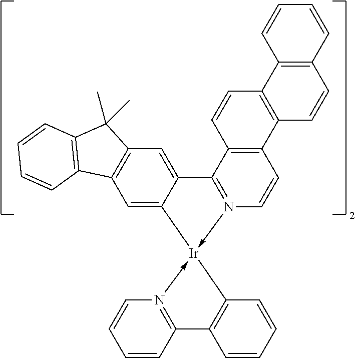 | — | 390 | — |
| Comparative compound 4 | 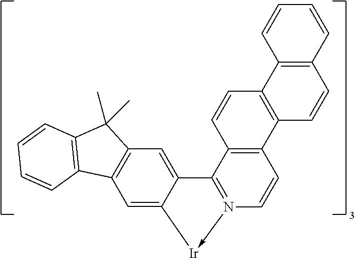 | — | 400 | — |
| Comparative compound 7 | 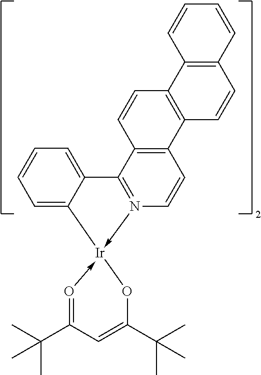 | 380 | 400 | 20 |

From these results, an organic compound having one ligand L₁ with a naphtho[2,1-f]isoquinoline skeleton and a tricyclic or polycyclic ring A bound together and having two ligands L₂ with a phenylpyridine skeleton in the molecule can be used to achieve high color purity and thermal stability.

Although specific structural formulae of an organic compound according to the present disclosure are exemplified below, the invention is not limited thereto.

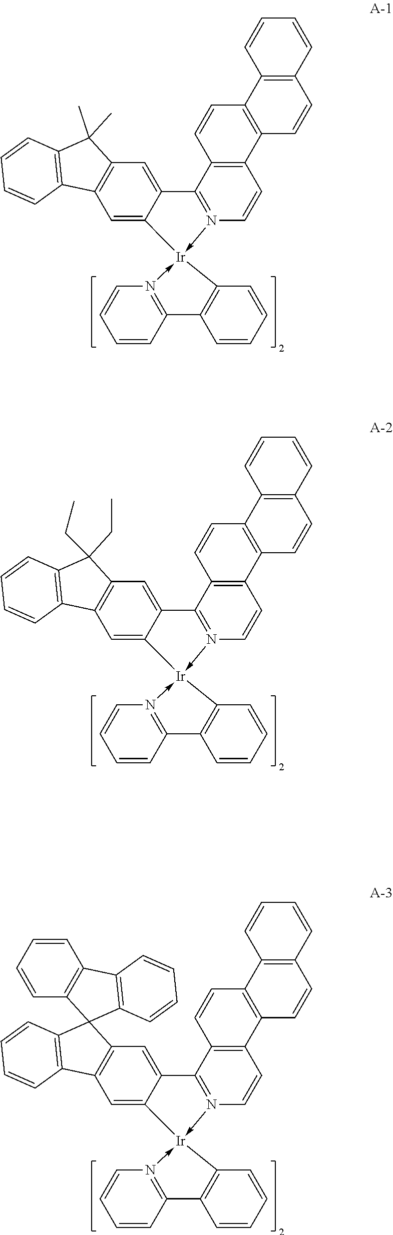

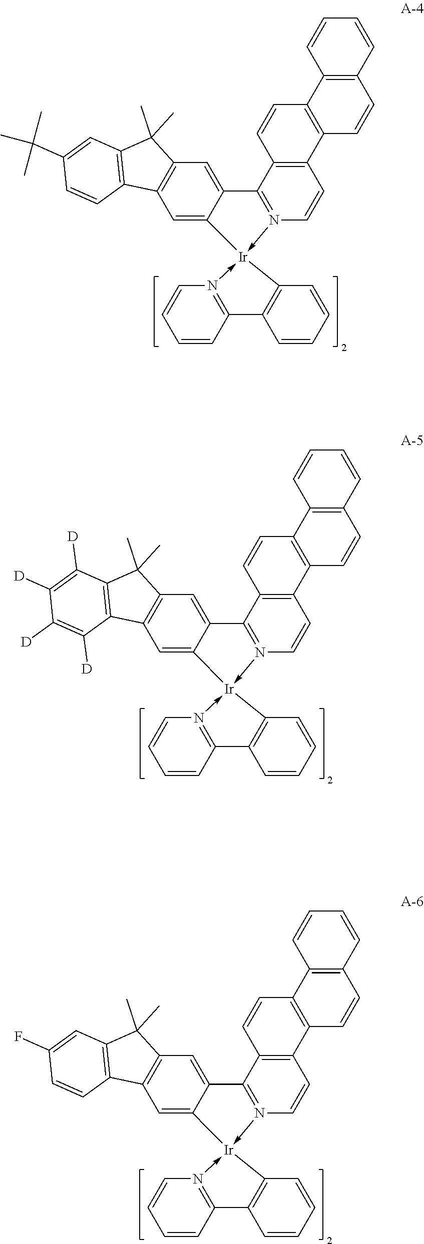

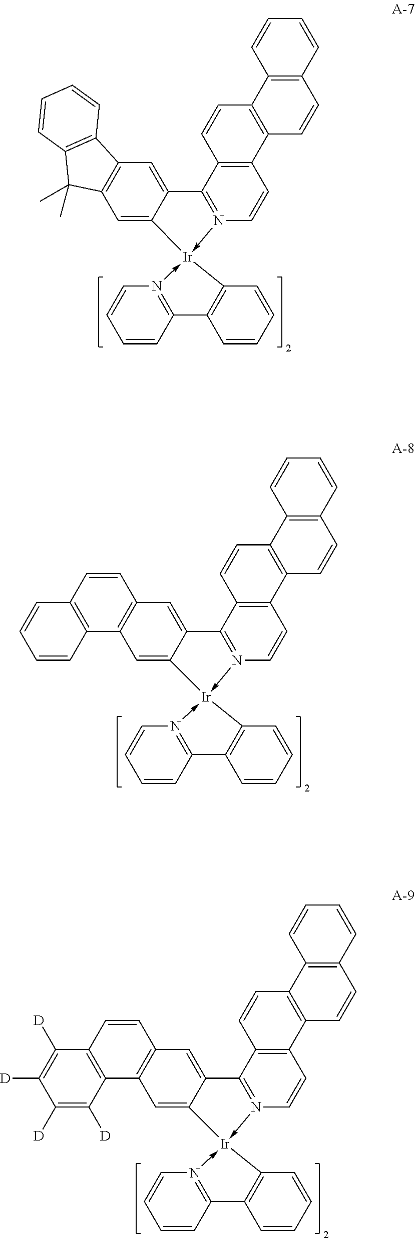

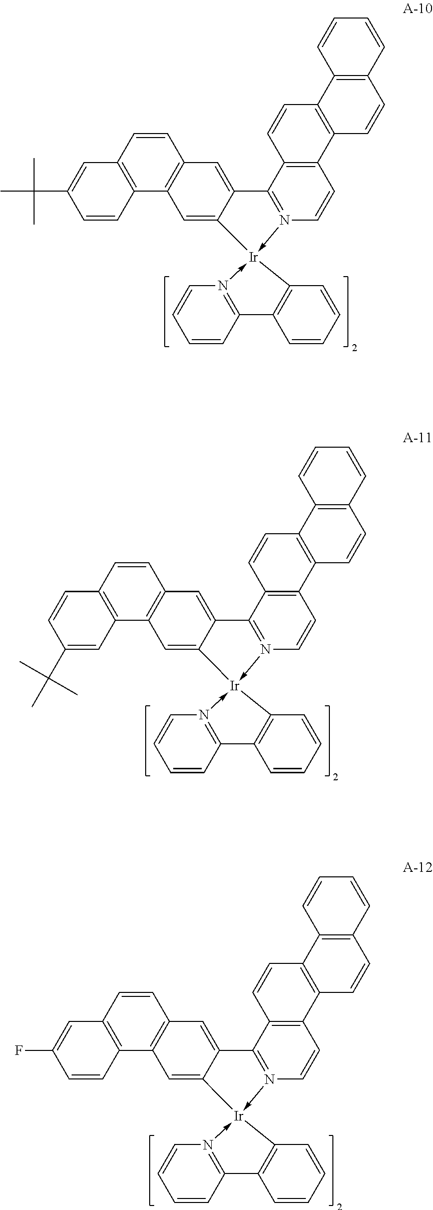

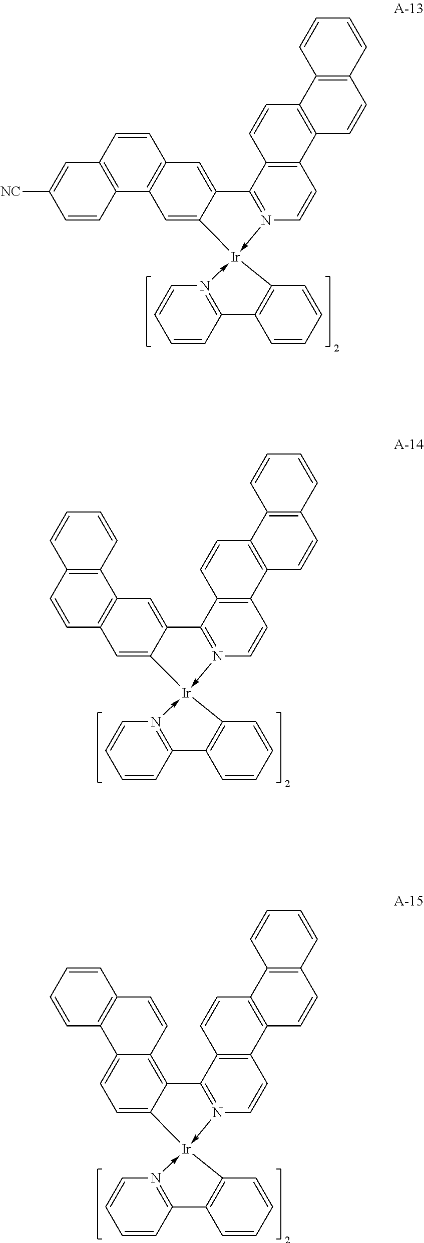

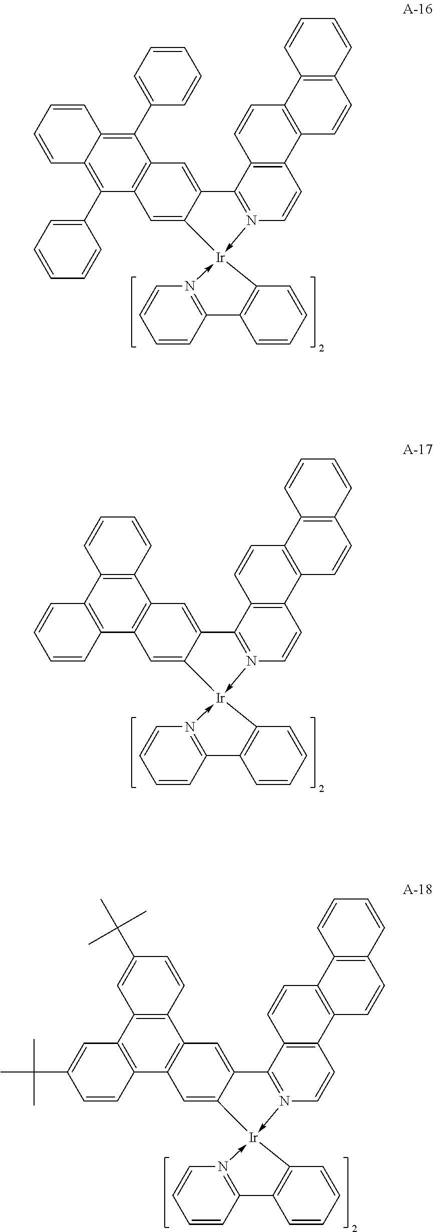

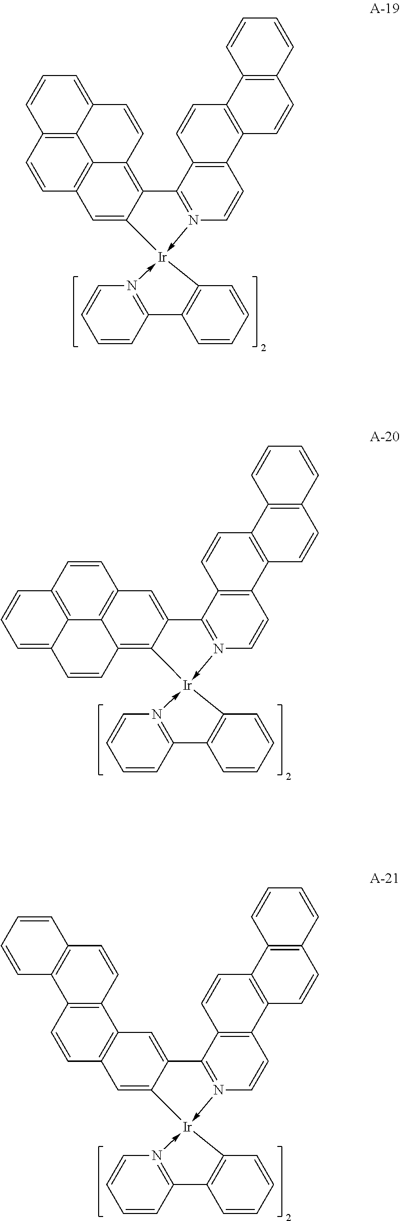

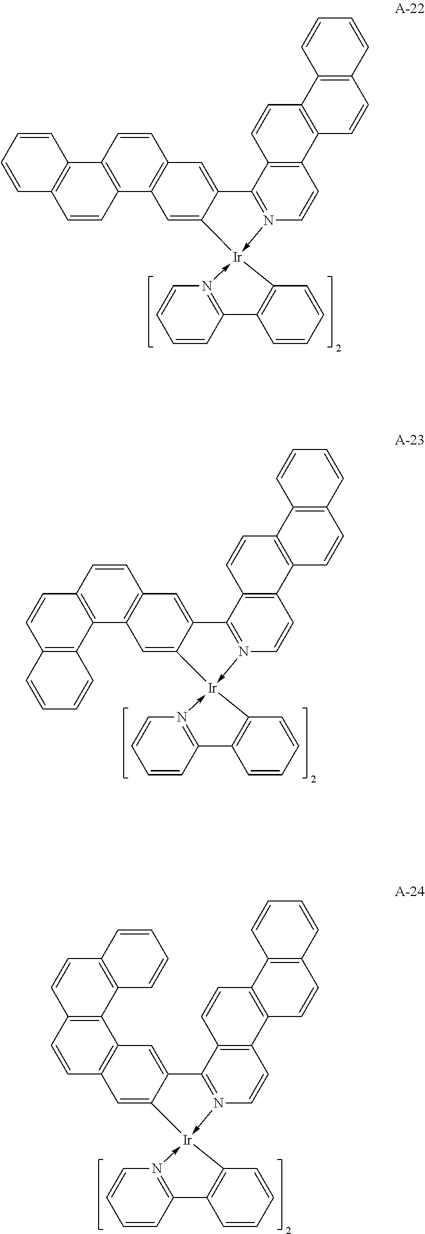

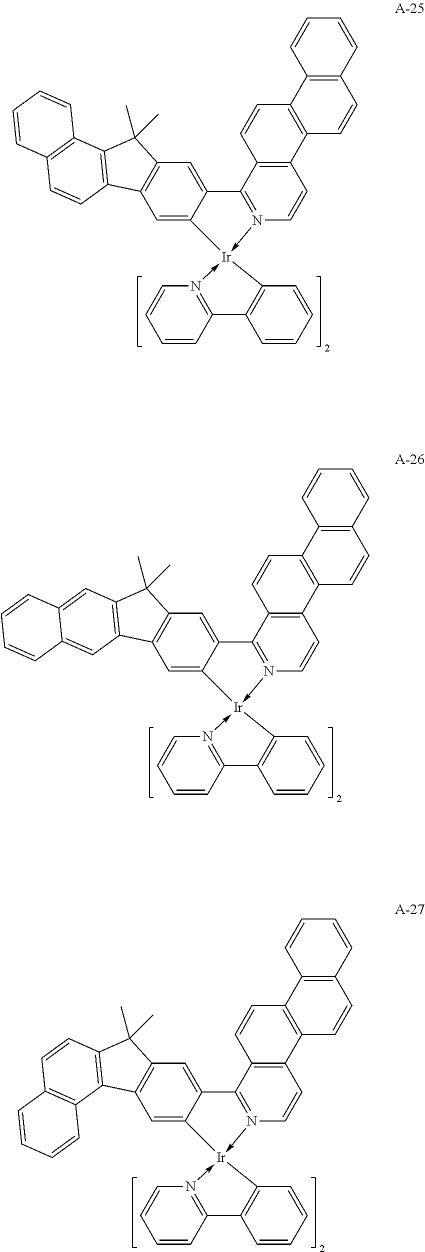

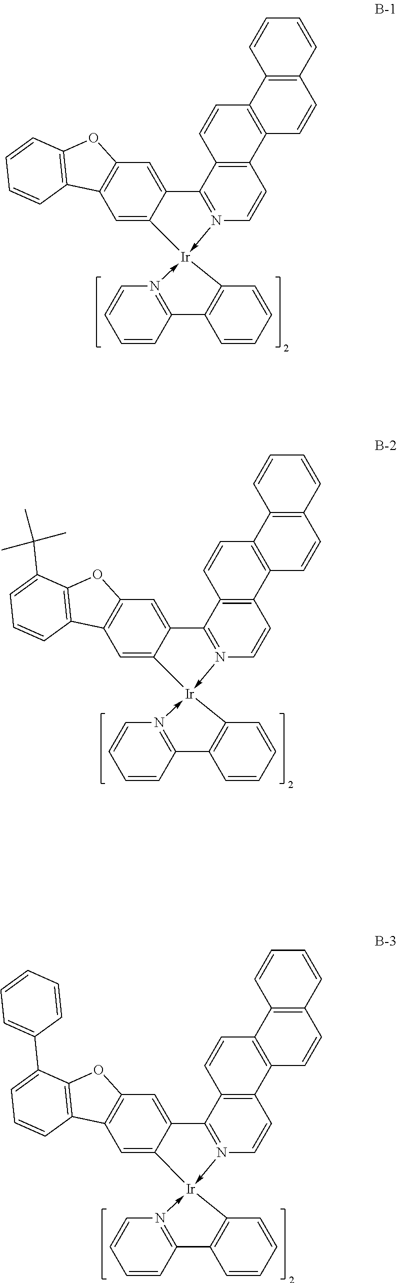

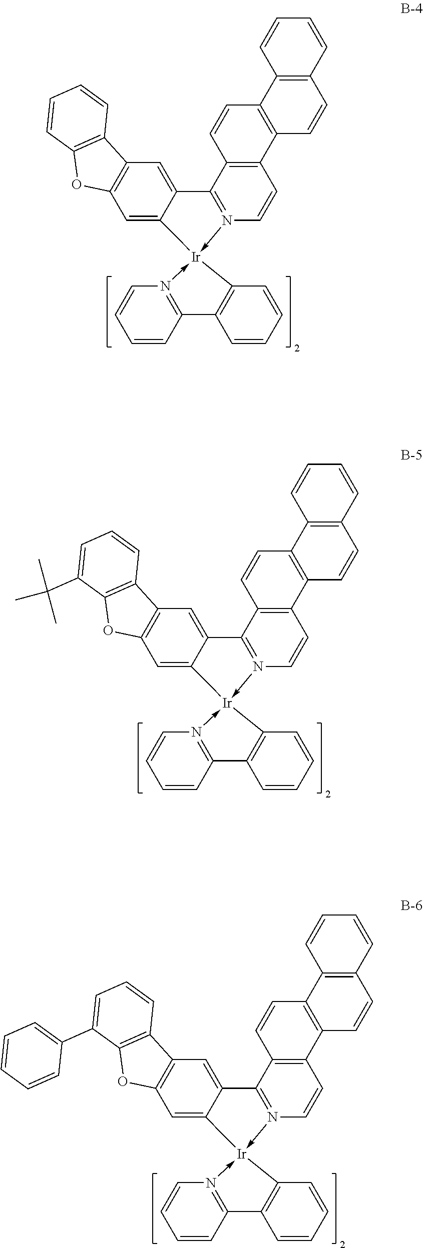

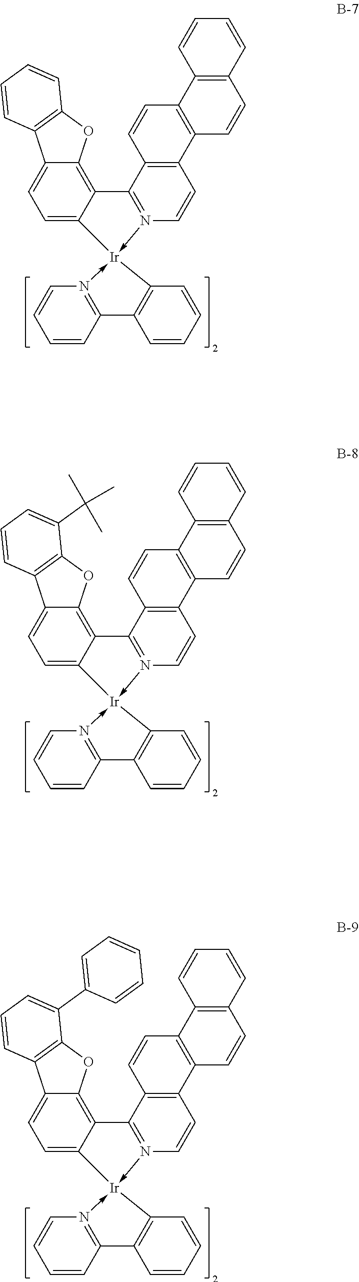

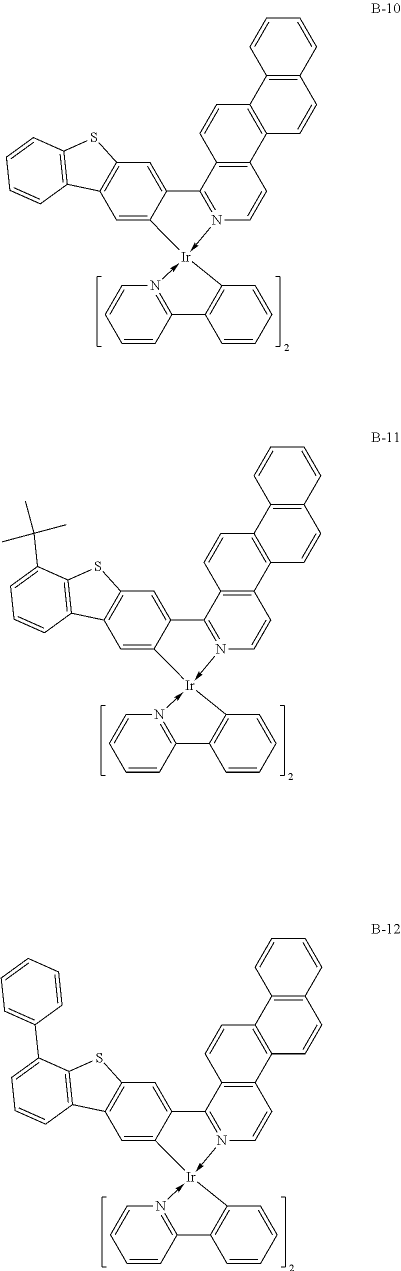

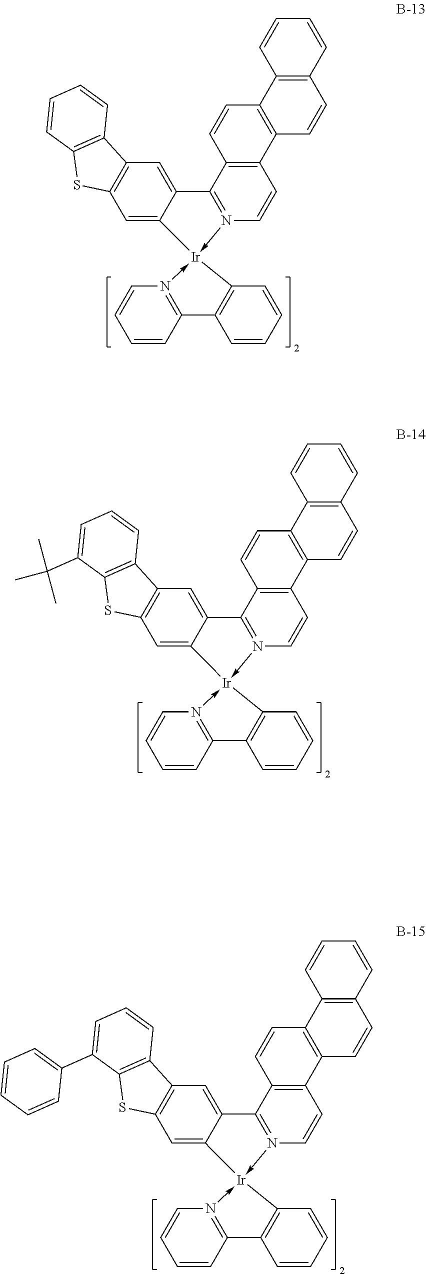

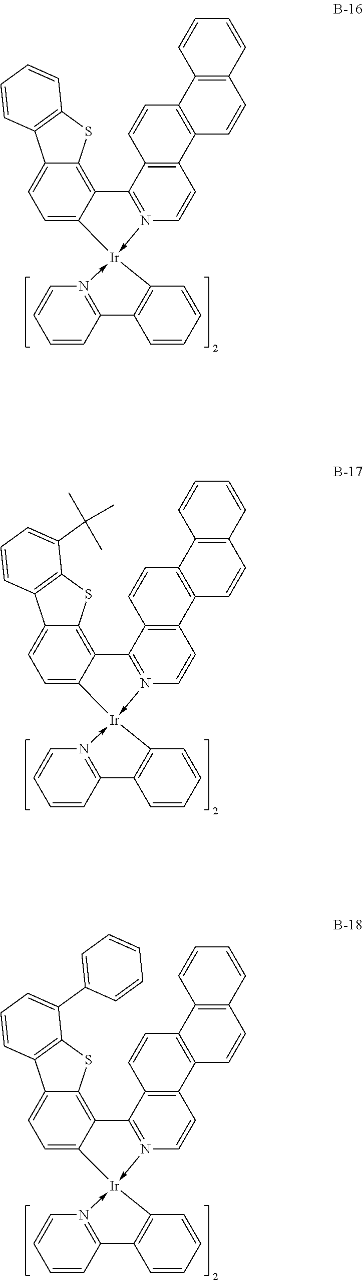

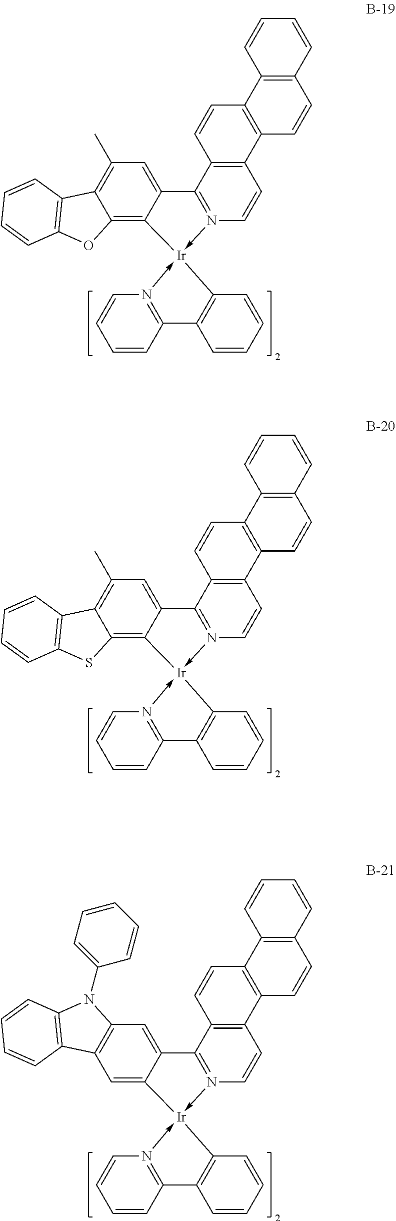

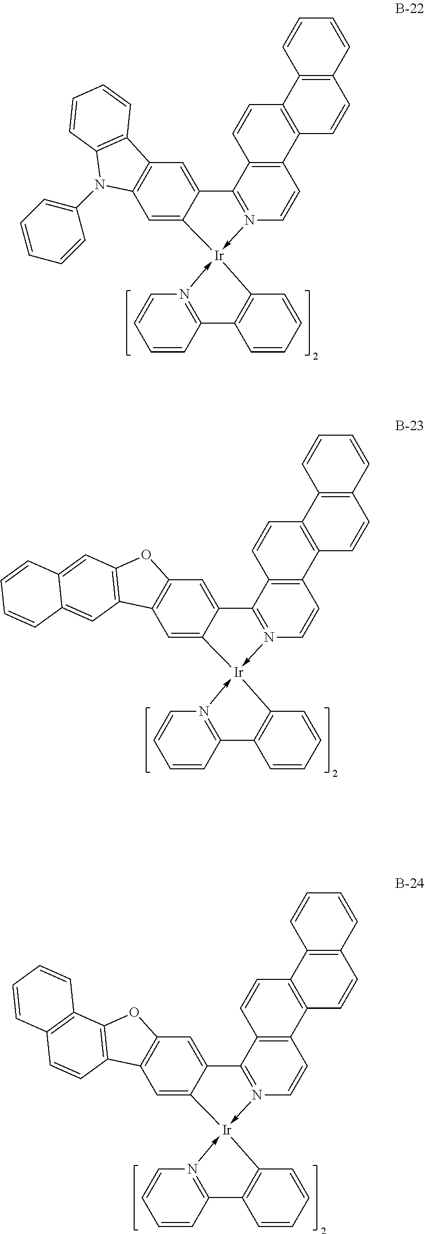

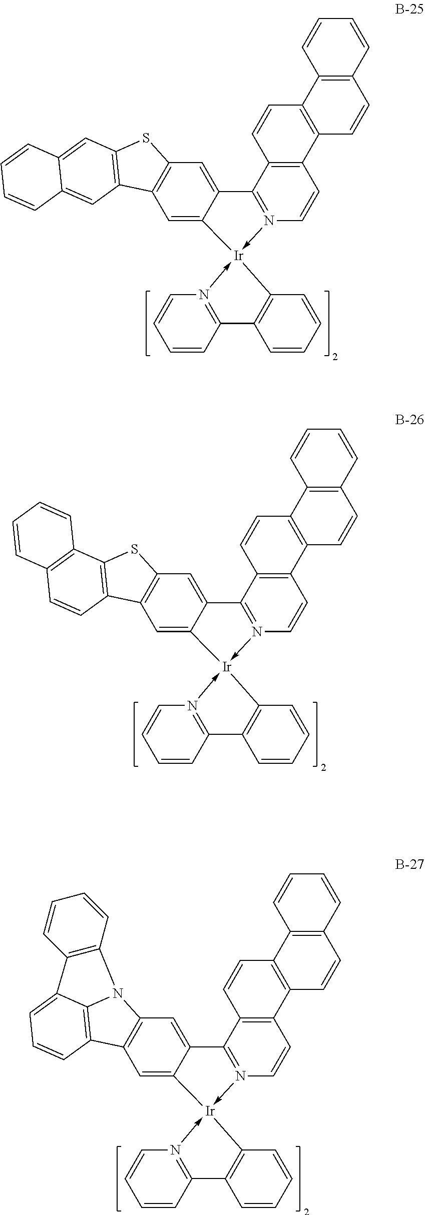

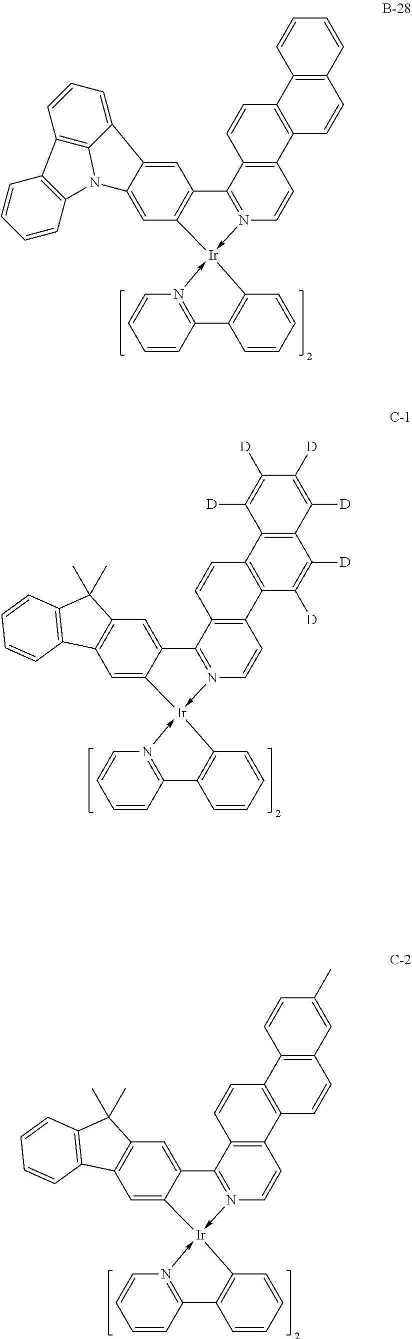

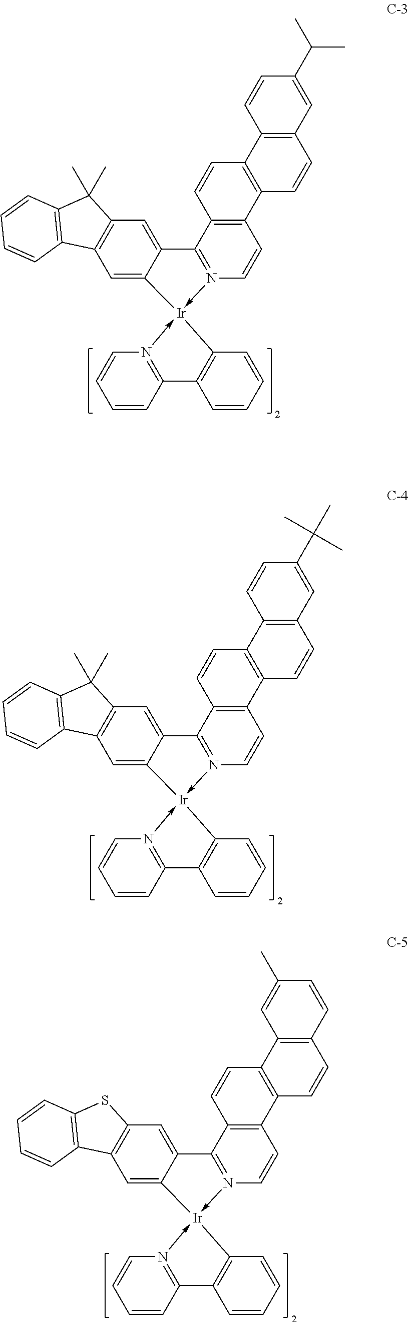

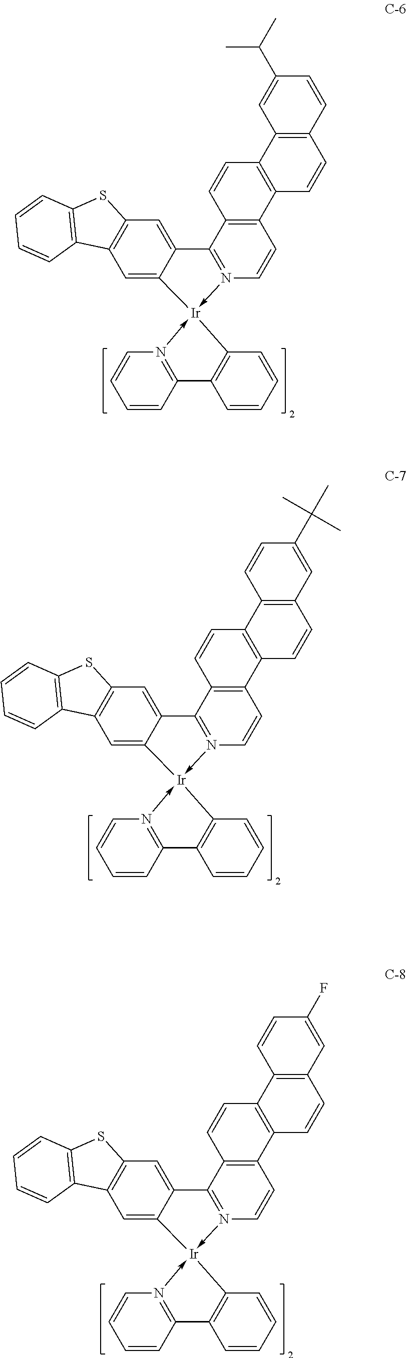

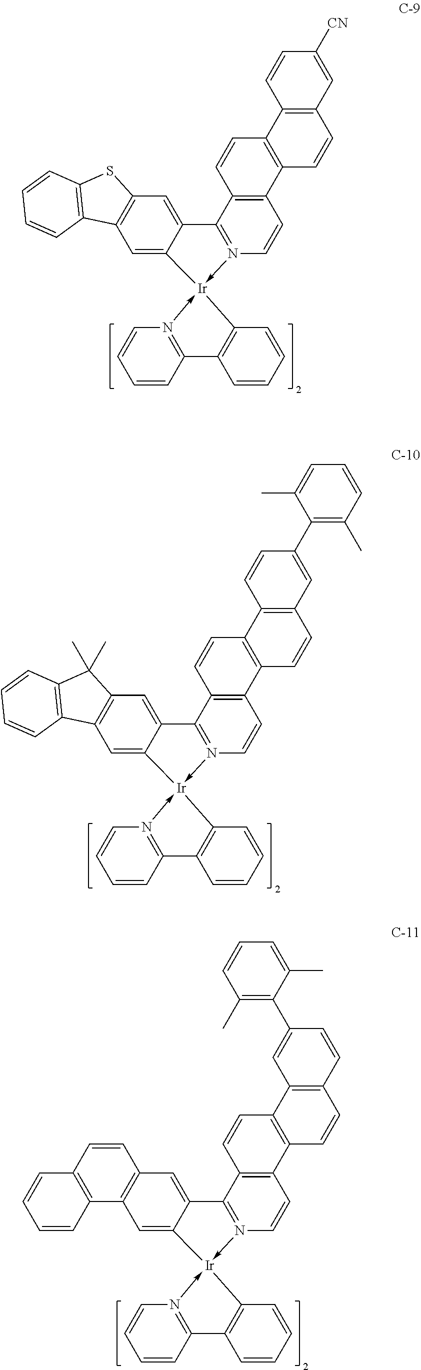

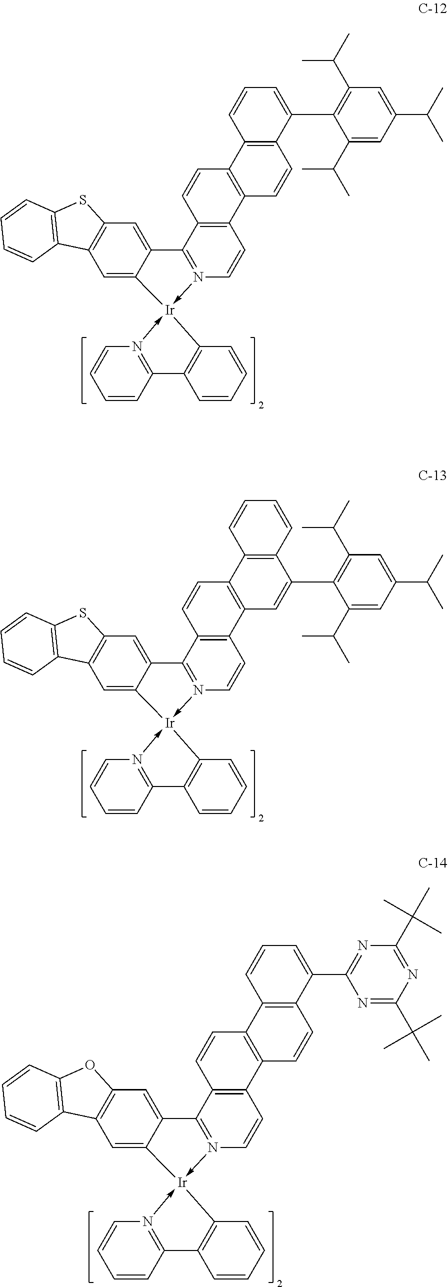

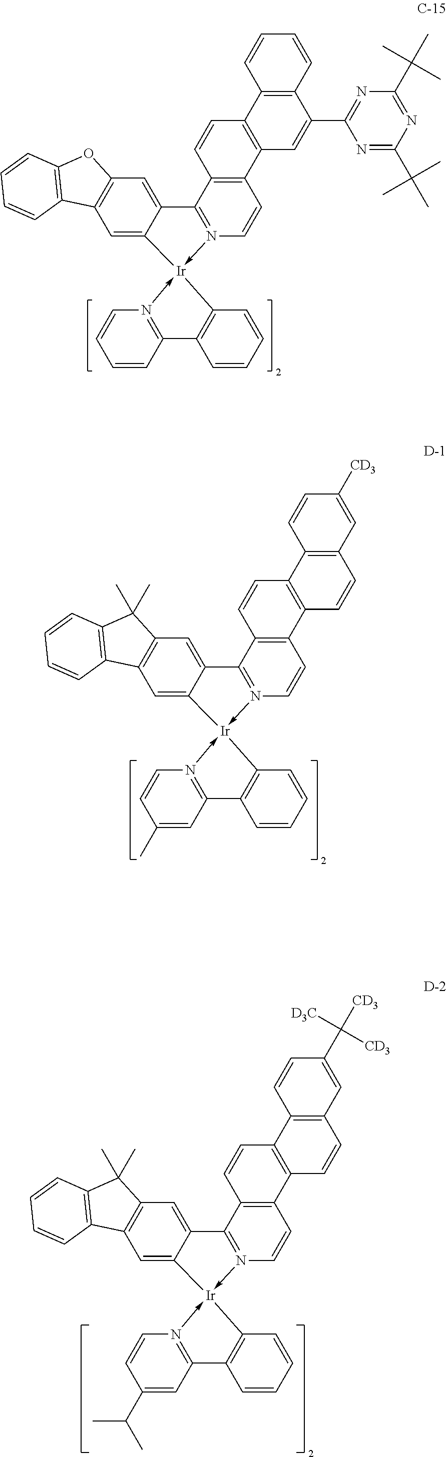

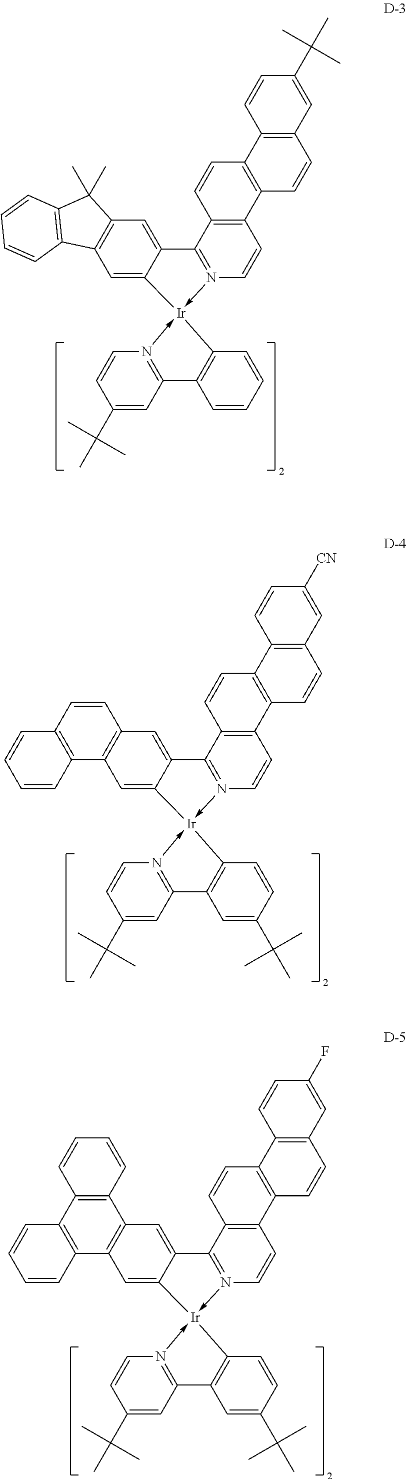

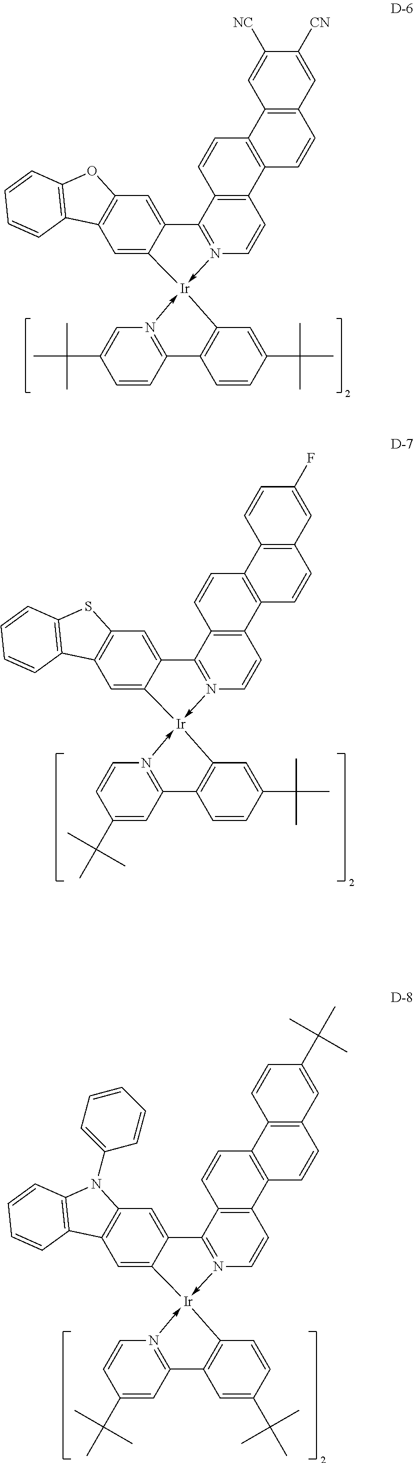

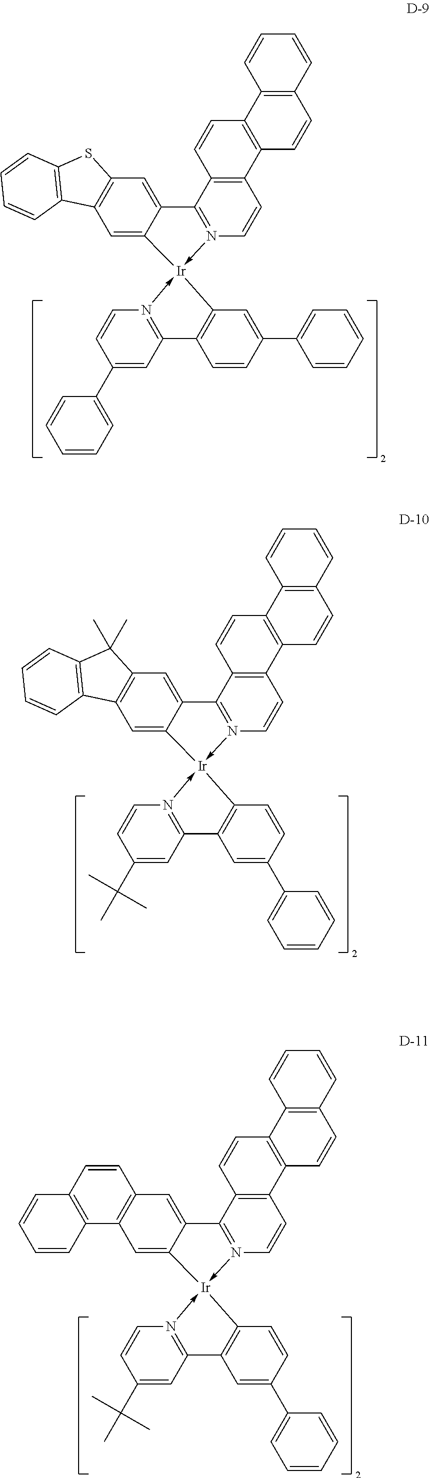

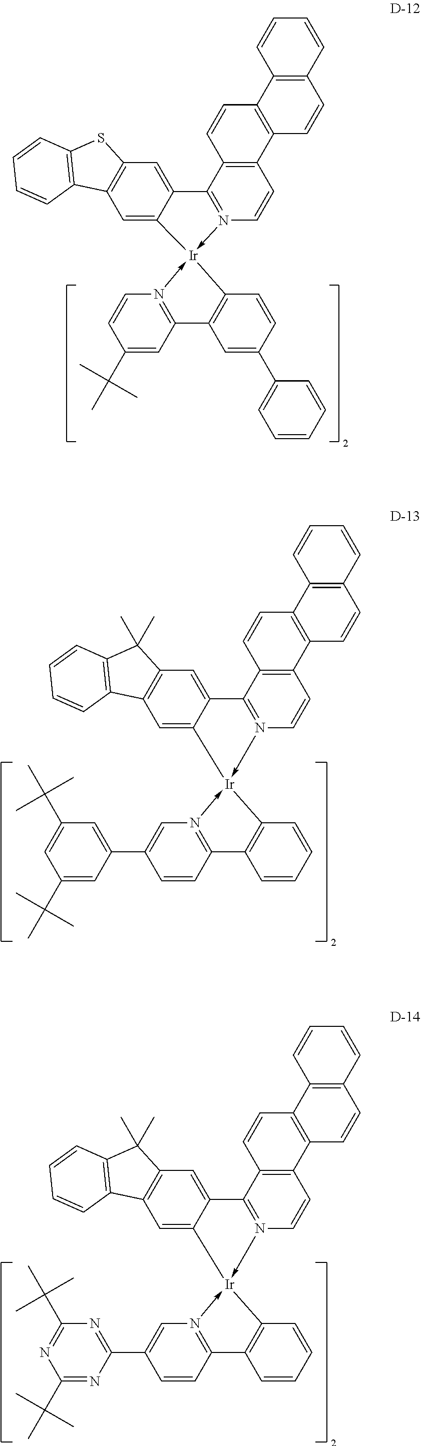

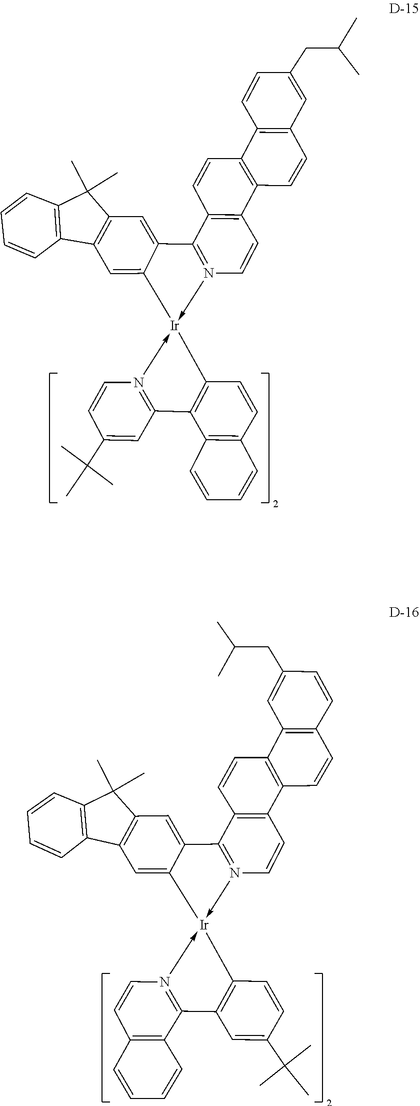

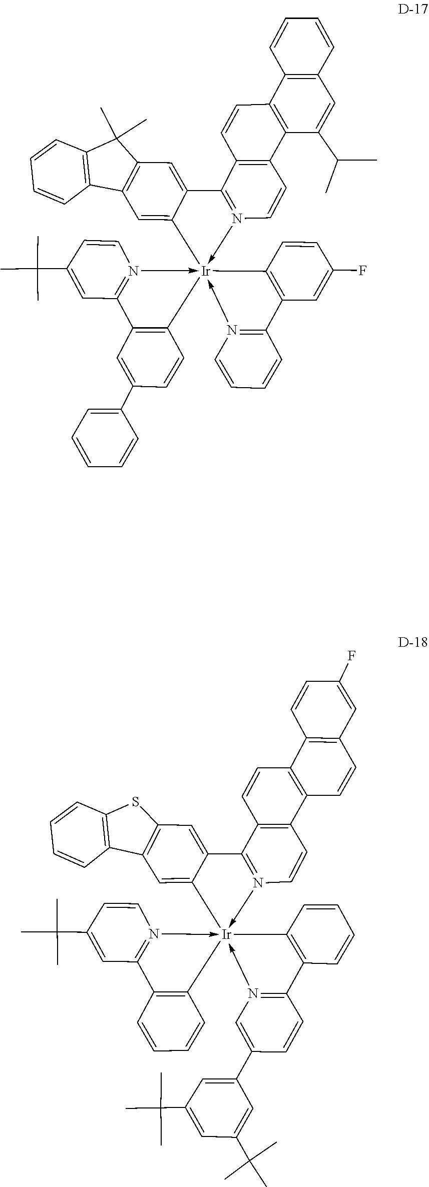

The compounds belonging to the group A are compounds in which the ring A, which is a substituted or unsubstituted tricyclic or polycyclic fused ring, is an aryl group. Because the ring A is composed of a stable aryl group, the compounds belonging to the group A have much higher thermal stability. Thus, when used in an organic light-emitting element, the group A is a compound group with much higher durability performance.

The compounds belonging to the group B are compounds in which the ring A, which is a substituted or unsubstituted tricyclic or polycyclic fused ring, is a heterocyclic group. Because the ring A is composed of the heterocyclic group, the compounds belonging to the group B can have various phosphorescence spectrum peak wavelengths due to the electronic effects of their heteroatoms. Thus, when used in an organic light-emitting element, the group B is a compound group that can achieve a desired color purity.

The compounds belonging to the group C are compounds with at least a substituent on the naphtho[2,1-f]isoquinoline skeleton. The compounds belonging to the group C have a wide range of phosphorescence characteristics and sublimability. Thus, when used in an organic light-emitting element, the group C is a compound group with high color purity and much higher durability performance.

The compounds belonging to the group D are compounds with at least a substituent on the ligand L₂. The compounds belonging to the group D can suppress aggregation and improve sublimability. Thus, when used in an organic light-emitting element, the group D is a compound group with high color purity and much higher durability performance.

### [Organic Light-Emitting Element]

An organic light-emitting element according to the present disclosure includes a pair of electrodes and an organic compound layer between the pair of electrodes, and the organic compound layer contains an organic compound according to the present disclosure. The organic compound layer can include a light-emitting layer, and the light-emitting layer can contain an organic compound according to the present disclosure or contain an organic compound according to the present disclosure as a first organic compound and also a second organic compound.

A specific element structure of an organic light-emitting element according to the present disclosure may be a multilayer element structure including an electrode layer and an organic compound layer shown in the following (a) to (f) sequentially stacked on a substrate. In any of the element structures, the organic compound layer always includes a light-emitting layer containing a light-emitting material.
(a) positive electrode/light-emitting layer/negative electrode
(b) positive electrode/hole transport layer/light-emitting layer/electron transport layer/negative electrode
(c) positive electrode/hole transport layer/light-emitting layer/electron transport layer/electron injection layer/negative electrode
(d) positive electrode/hole injection layer/hole transport layer/light-emitting layer/electron transport layer/negative electrode
(e) positive electrode/hole injection layer/hole transport layer/light-emitting layer/electron transport layer/electron injection layer/negative electrode
(f) positive electrode/hole transport layer/electron-blocking layer/light-emitting layer/hole-blocking layer/electron transport layer/negative electrode

However, these element structure examples are only very basic element structures, and the element structure is not limited to these structures. Various layer structures are possible; for example, an insulating layer, an adhesive layer, or an interference layer is formed at an interface between an electrode and an organic compound layer, an electron transport layer or a hole transport layer is composed of two layers with different ionization potentials, or a light-emitting layer is composed of two layers formed of different light-emitting materials.

The light-emitting layer may be of monolayer or multilayer. The term “multilayer”, as used herein, refers to a laminate of a light-emitting layer and another light-emitting layer. For example, it may be possible to stack a light-emitting layer containing an organic compound according to the present disclosure as a guest molecule and containing a host molecule and another light-emitting layer that emits light of a color different from the color of light emitted from the light-emitting layer. In such a case, the emission color may be white or a neutral color.

Among the element structures (a) to (f), the structure (f) has both an electron-blocking layer and a hole-blocking layer. Thus, the electron-blocking layer and the hole-blocking layer in (f) can securely confine carriers of both holes and electrons in the light-emitting layer. Thus, the organic light-emitting element has no carrier leakage and high light emission efficiency.

The mode (element form) of extracting light from the light-emitting layer may be a so-called bottom emission mode of extracting light from an electrode on the substrate side or a so-called top emission mode of extracting light from the side opposite the substrate side. The mode may also be a double-sided extraction mode of extracting light from the substrate side and from the side opposite to the substrate side.

In an organic light-emitting element according to the present disclosure, an organic compound according to the present disclosure can be contained in the light-emitting layer of the organic compound layer. At this time, the use of a compound contained in the light-emitting layer depends on the concentration of the compound in the light-emitting layer. More specifically, the compound is divided into a main component and an auxiliary component depending on the concentration of the compound in the light-emitting layer.

A compound serving as a main component is a compound with the maximum mass ratio (concentration) among the compound group contained in the light-emitting layer and is also referred to as a host. The host is a compound that is present as a matrix around the light-emitting material in the light-emitting layer and that is mainly responsible for carrier transport to the light-emitting material and excitation energy supply to the light-emitting material.

A compound serving as an auxiliary component is a compound other than the main component and can be referred to as a guest (dopant), a light-emitting assist material, or a charge injection material depending on the function of the compound. The guest, which is an auxiliary component, is a compound (light-emitting material) responsible for main light emission in the light-emitting layer. The light-emitting assist material, which is an auxiliary component, is a compound that assists the light emission of the guest and that has a lower mass ratio (concentration) than the host in the light-emitting layer. The light-emitting assist material is also referred to as a second host because of its function.

The concentration of the host is preferably 50% by weight or more and 99% by weight or less, more preferably 70% by weight or more and 99% by weight or less, based on the total amount of the constituent materials of the light-emitting layer. The concentration of the guest is 0.01% by mass or more and less than 50% by mass, preferably 0.1% by mass or more and 20% by mass or less, based on the total amount of the constituent materials of the light-emitting layer. From the perspective of reducing concentration quenching, the concentration of the guest is particularly preferably 10% by mass or less. The concentration of the light-emitting assist material is 0.1% by mass or more and less than 50% by mass, preferably 1% by mass or more and less than 50% by mass, based on the total amount of the constituent materials of the light-emitting layer.

The guest may be uniformly contained or may have a concentration gradient throughout a layer in which the host serves as a matrix. Alternatively, the guest may be partially contained in a specific region in the layer, and a light-emitting layer may have a region containing only the host and no guest.

In the present disclosure, an organic compound according to the present disclosure can be contained as a guest in the light-emitting layer. Thus, the light-emitting layer may contain the second organic compound as a host and may further contain a third organic compound (second host) for the purpose of assisting the transfer of an exciton or a carrier.

### (1) First Organic Compound

The first organic compound can be a guest and can be an organic compound according to the present disclosure.

### (2) Second Organic Compound

The second organic compound can be a host. The host material is, for example, an aromatic hydrocarbon compound or a derivative thereof, a carbazole derivative, an azine derivative, a xanthone derivative, a dibenzofuran derivative, a dibenzothiophene derivative, an organoaluminum complex, such as tris(8-quinolinolato)aluminum, an organoberyllium complex, or the like.

In particular, a material with a carbazole skeleton, a material with a triphenylene ring as a skeleton, and a material with a dibenzothiophene skeleton can be used. This is because these materials have high electron-donating ability and electron-withdrawing ability, and the highest occupied molecular orbital (HOMO) level and the lowest unoccupied molecular orbital (LUMO) level can be easily adjusted. Such a host material in combination with an organic compound according to the present disclosure can achieve a good carrier balance.

Specific examples of an organic compound used as a host material contained in the light-emitting layer include, but are not limited to, the following. Among the following specific examples, materials with a carbazole skeleton that can serve as host materials are EM32 to EM38. Materials with a triphenylene ring in the skeleton that can serve as host materials are EM10 to EM14, EM32, and EM39. Materials with a dibenzothiophene skeleton that can serve as host materials are EM13, EM14, and EM28.

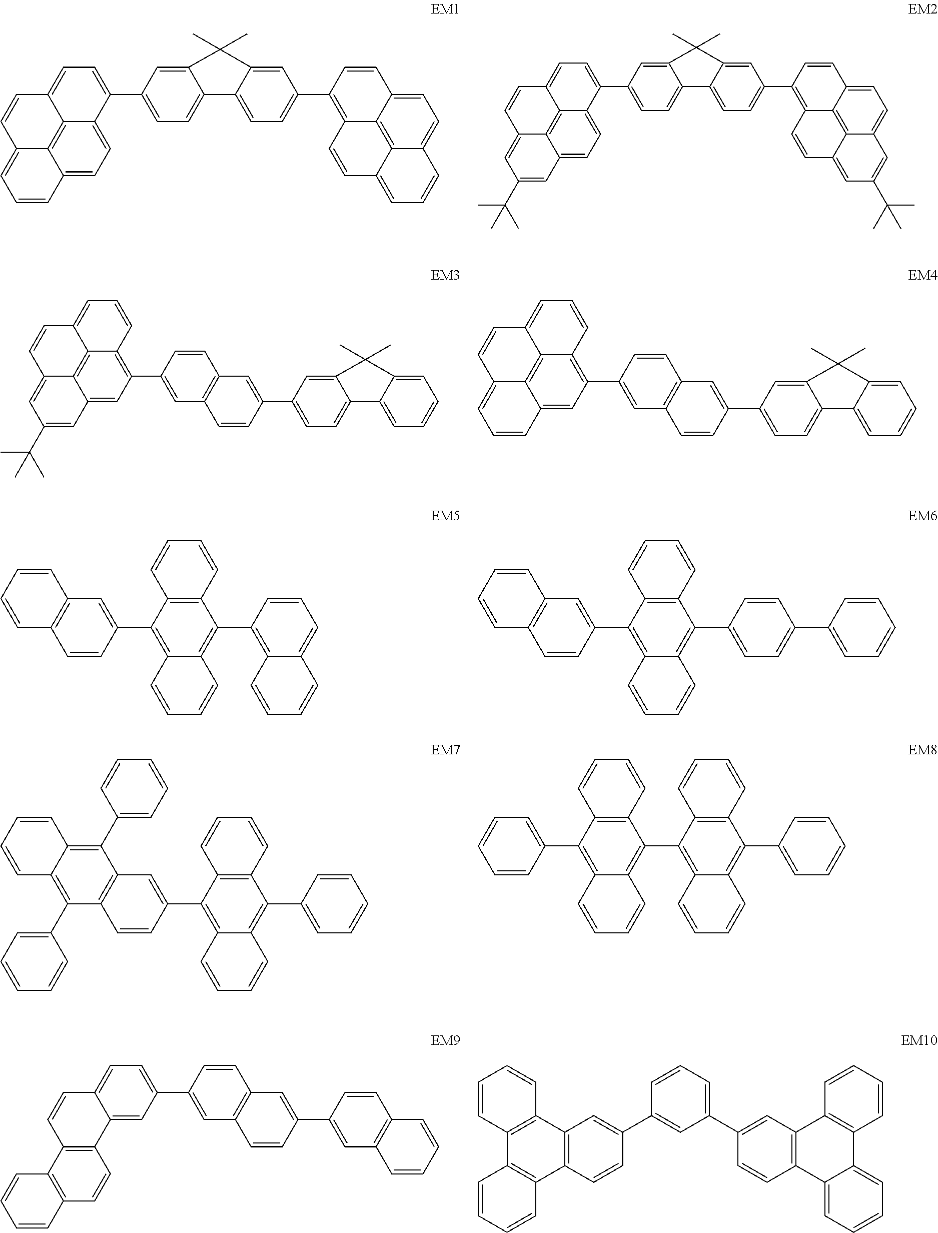

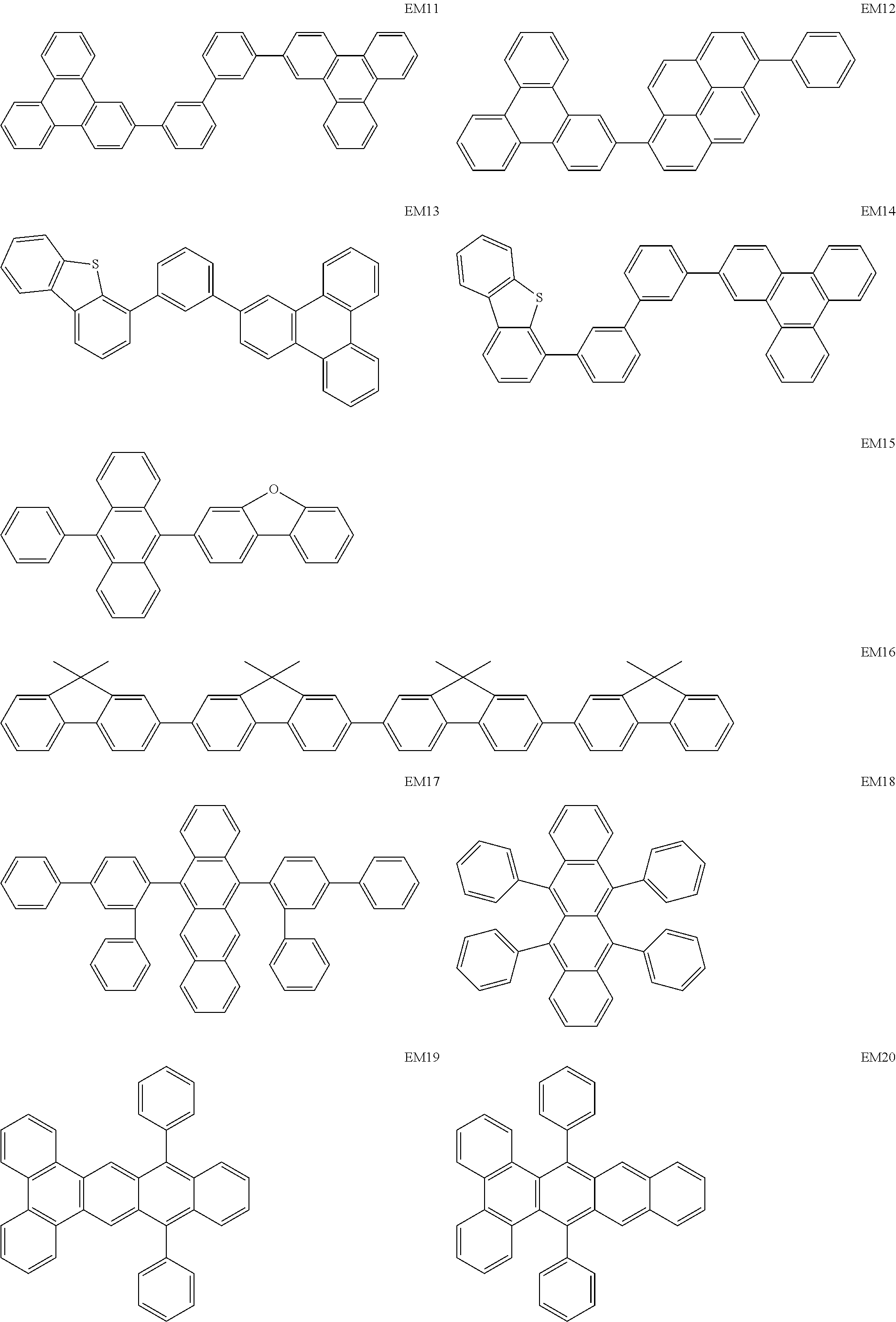

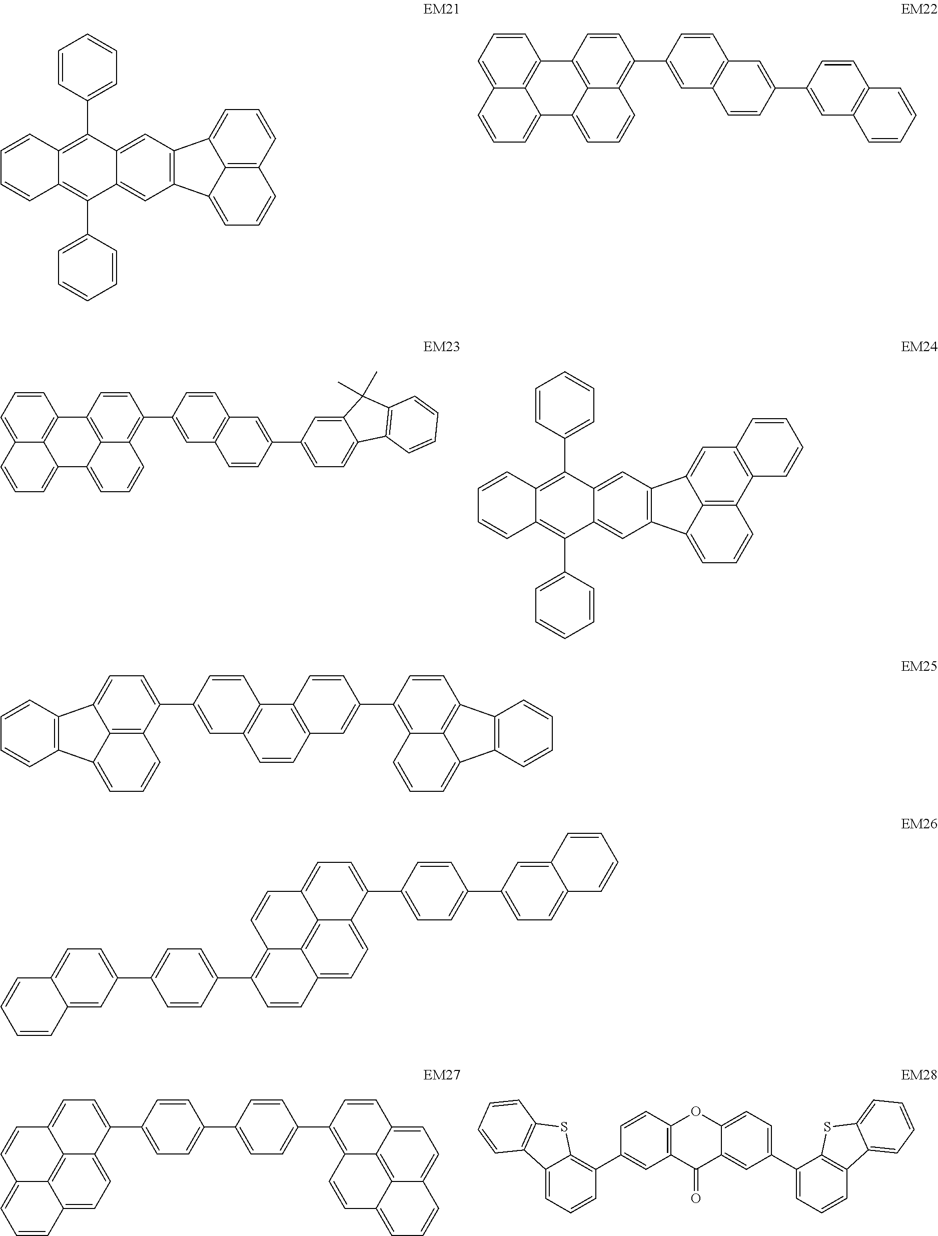

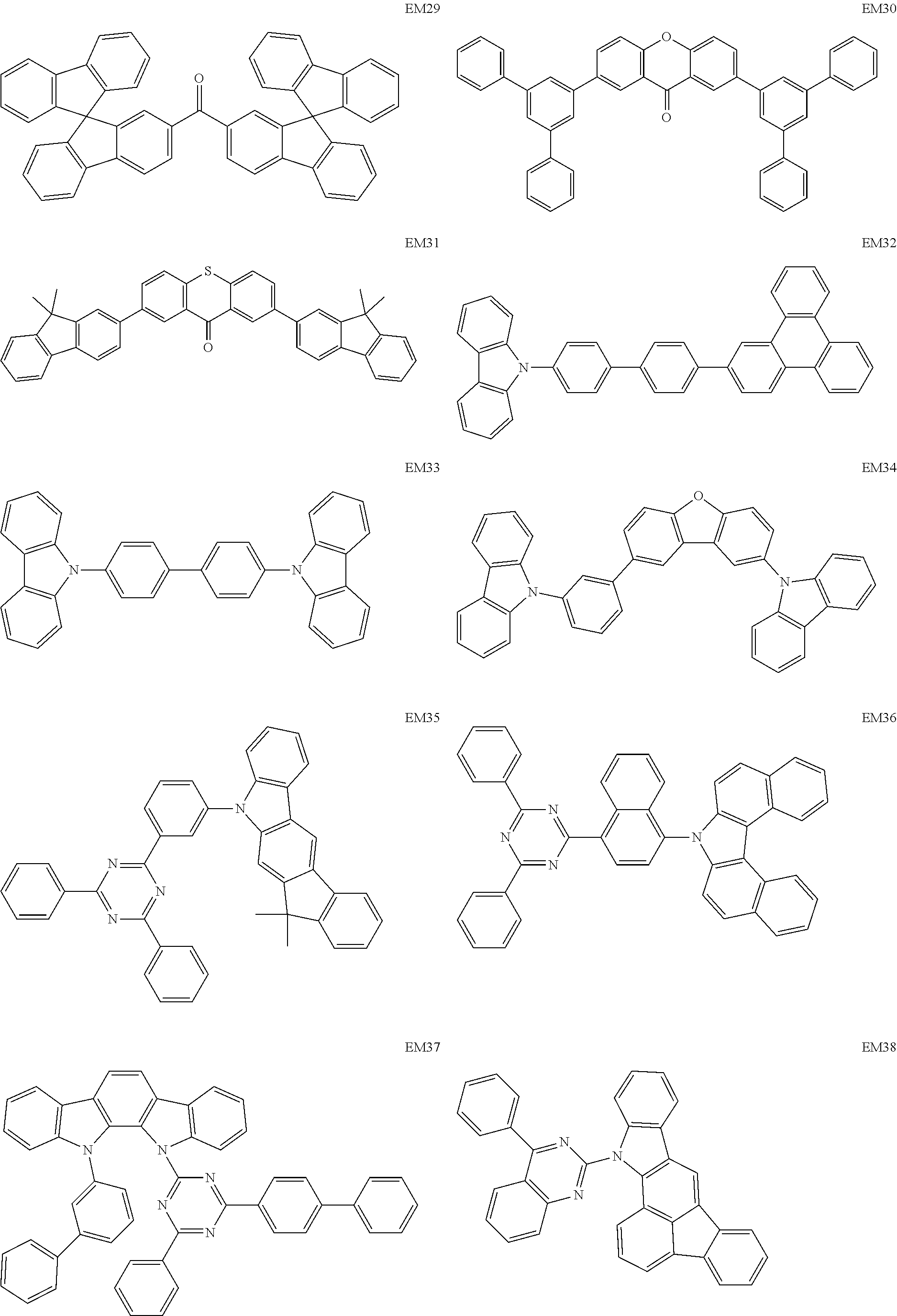

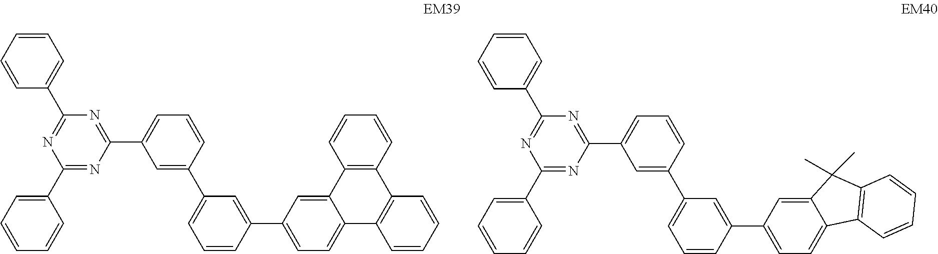

### (3) Third Organic Compound (Second Host, Light-Emitting Assist Material)

A third organic compound may be contained as a second light-emitting layer host or a light-emitting assist material contained in a light-emitting layer in an organic light-emitting element according to the present disclosure. The third organic compound may be a host material or a phosphorescent organometallic complex listed as a specific example of the second organic compound.

Specific examples of the phosphorescent organometallic complex used for the light-emitting assist material include an iridium complex, a platinum complex, a rhenium complex, a copper complex, a europium complex, a ruthenium complex, and the like.

From the perspective of emission quantum yield, the light-emitting assist material can be an organometallic complex represented by the following general formula (2):

M(L)ₘ(L′)ₙ (2)
wherein M is selected from iridium and platinum.

L and L′ each denote a different bidentate ligand. When a plurality of Ls or L's are present, they may be the same or different.

m is selected from an integer of 1 or more and 3 or less, and n is selected from an integer of 0 or more and 2 or less. When M denotes iridium, m+n is 3, and when M denotes platinum, m+n is 2.

The substructure M(L)ₘ is represented by the following general formula (2-1), and the substructure M(L′)ₙ is represented by the following general formula (2-2).

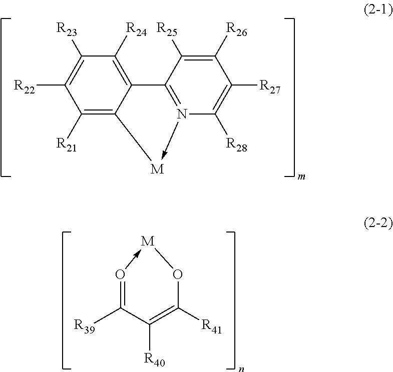

R₂₁ to R₂₈ in the general formula (2-1) and R₃₉ to R₄₁ in the general formula (2-2) are each independently selected from a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heterocyclic group, a substituted or unsubstituted amino group, a substituted or unsubstituted aryloxy group, a substituted or unsubstituted heteroaryloxy group, and a cyano group. In R₂₁ to R₂₈ and R₃₉ to R₄₁, adjacent substituents Rs may be bonded together to form a ring.

The halogen atom is, for example, but not limited to, fluorine, chlorine, bromine, iodine, or the like. In particular, a fluorine atom can be used.

The alkyl group is, for example, but not limited to, a methyl group, an ethyl group, a n-propyl group, an iso-propyl group, a n-butyl group, a tert-butyl group, a sec-butyl group, an octyl group, a cyclohexyl group, a 1-adamantyl group, a 2-adamantyl group, or the like.

The alkoxy group is, for example, but not limited to, a methoxy group, an ethoxy group, a propoxy group, a 2-ethyl-octyloxy group, a benzyloxy group, or the like.

The silyl group is, for example, but not limited to, a trimethylsilyl group, a triphenylsilyl group, or the like.

The aryl group is, for example, but not limited to, a phenyl group, a naphthyl group, an indenyl group, a biphenyl group, a terphenyl group, a fluorenyl group, a phenanthryl group, a fluoranthenyl group, a triphenylenyl group, or the like.

The heterocyclic group is, for example, but not limited to, a pyridyl group, a pyrimidyl group, a pyrazyl group, a triazolyl group, an oxazolyl group, an oxadiazolyl group, a thiazolyl group, a thiadiazolyl group, a carbazolyl group, an acridinyl group, a phenanthrolyl group, a dibenzofuranyl group, a dibenzothiophenyl group, or the like. The heterocyclic group can be a heteroaryl group or a group bonded through a carbon atom.

The amino group is, for example, but not limited to, an N-methylamino group, an N-ethylamino group, an N,N-dimethylamino group, an N,N-diethylamino group, an N-methyl-N-ethylamino group, an N-benzylamino group, an N-methyl-N-benzylamino group, an N,N-dibenzylamino group, an anilino group, an N,N-diphenylamino group, an N,N-dinaphthylamino group, an N,N-difluorenylamino group, an N-phenyl-N-tolylamino group, an N,N-ditolylamino group, an N-methyl-N-phenylamino group, an N,N-dianisolylamino group, an N-mesityl-N-phenylamino group, an N,N-dimesitylamino group, an N-phenyl-N-(4-tert-butylphenyl)amino group, an N-phenyl-N-(4-trifluoromethylphenyl)amino group, an N-piperidyl group, a carbazolyl group, or the like.

The aryloxy group and the heteroaryloxy group are, but not limited to, a phenoxy group, a thienyloxy group, or the like.

An additional optional substituent of the alkyl group, the alkoxy group, the silyl group, the aryl group, the heterocyclic group, the amino group, the aryloxy group, and the heteroaryloxy group is, for example, but not limited to, a deuterium atom; a halogen atom, such as fluorine, chlorine, bromine, or iodine; an alkyl group, such as a methyl group, an ethyl group, a n-propyl group, an iso-propyl group, a n-butyl group, or a tert-butyl group; an alkoxy group, such as a methoxy group, an ethoxy group, or a propoxy group; an amino group, such as a dimethylamino group, a diethylamino group, a dibenzylamino group, a diphenylamino group, or a ditolylamino group; an aryloxy group, such as a phenoxy group; an aromatic hydrocarbon group, such as a phenyl group or a biphenyl group; a heterocyclic group, such as a pyridyl group or a pyrrolyl group; or a cyano group, a hydroxy group, a thiol group, or the like.

Adjacent substituents R₂₁ to R₂₈, in particular, adjacent substituents R₂₁ to R₂₄ or adjacent substituents R₂₅ to R₂₈ may be bonded together and form a ring. The phrase “adjacent substituents R₂₁ to R₂₈ are bonded together and form a ring” means that a ring formed by bonding R₂₁ and R₂₂, R₂₂ and R₂₃, or R₂₃ and R₂₄ together and a benzene ring to which R₂₁ to R₂₄ are bonded form a fused ring, or that a ring formed by bonding R₂₅ and R₂₆, R₂₆ and R₂₇, or R₂₇ and R₂₈ together and a pyridine ring to which R₂₅ to R₂₈ are bonded form a fused ring. The ring formed by bonding adjacent substituents R₂₁ to R₂₈ together may be an aromatic ring.

In the organometallic complex represented by the general formula (2), the substructure M(L)ₘ can have a tricyclic or polycyclic fused ring. This is because the tricyclic or polycyclic fused-ring skeleton improve planarity, promotes energy transfer from a host molecule, and improves efficiency and durability. The tricyclic or polycyclic fused ring is, for example, but not limited to, a phenanthrene ring, a triphenylene ring, a benzofluorene ring, a dibenzofuran ring, a dibenzothiophene ring, a benzonaphthofuran ring, a benzonaphthothiophene ring, a benzoisoquinoline ring, a naphthoisoquinoline ring, or the like.

In the general formula (2-1), at least one of R₂₂, R₂₃, R₂₆, and R₂₇ can be a substituted or unsubstituted aryl group or a substituted or unsubstituted heterocyclic group. This is because the planarity of the organometallic complex is improved as described above.

The general formulae of the substructure M(L)ₘ represented by the general formula (2-1) are shown below, but the invention is not limited thereto. In these general formulae, a coordinate bond is indicated by a straight line, a dotted line, or an arrow.

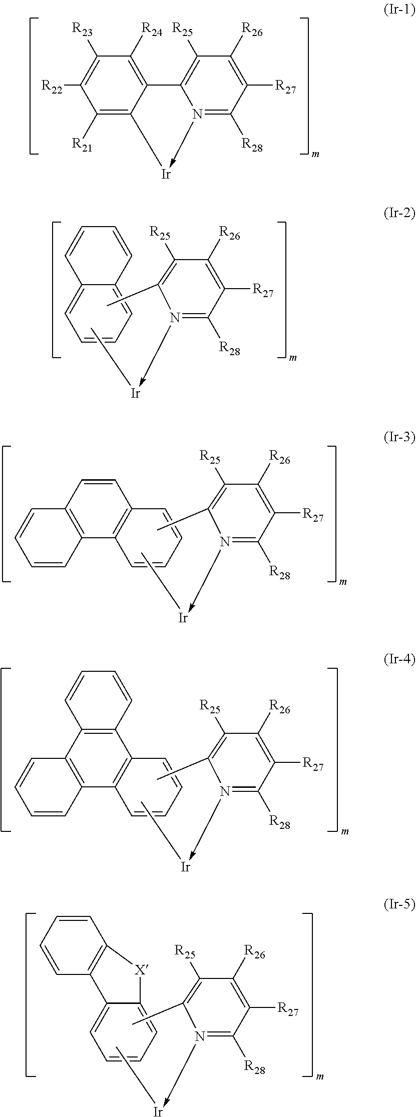

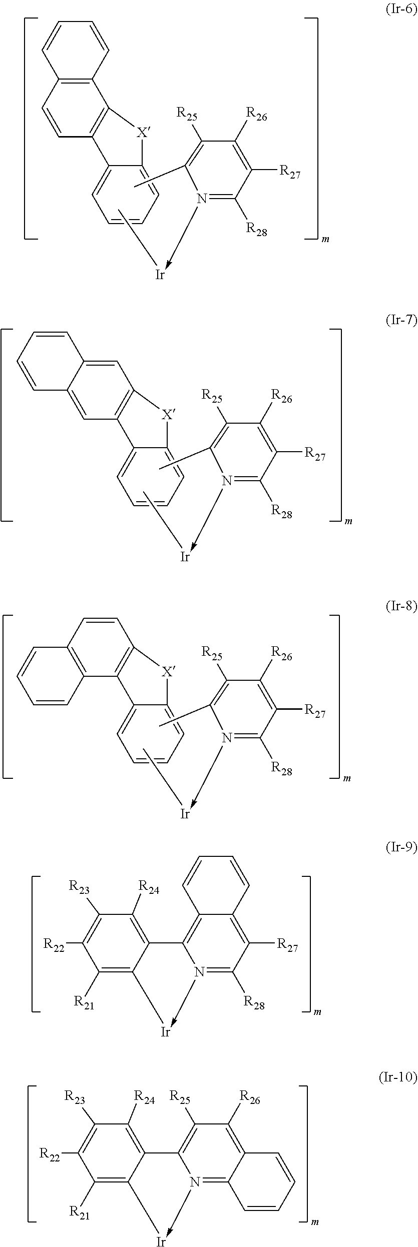

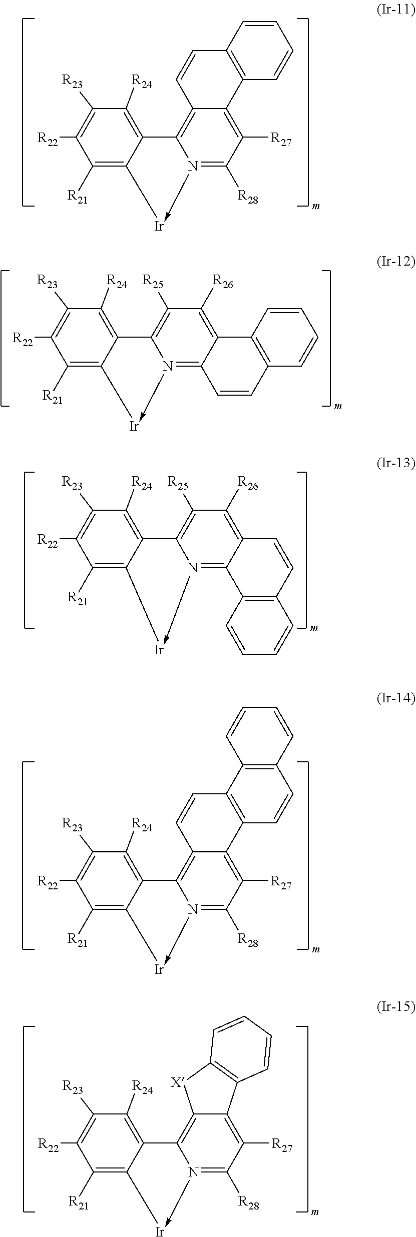

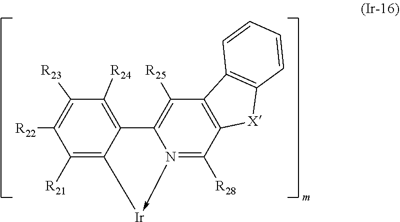

In the general formulae (Ir-5) to (Ir-8), (Ir-15), and (Ir-16), X′ is selected from an oxygen atom, a sulfur atom, a substituted or unsubstituted carbon atom, and a substituted or unsubstituted nitrogen atom.

In the general formulae (Ir-2) to (Ir-8), adjacent substituents R₂₁ to R₂₄ are bonded together and form a ring. In the general formulae (Ir-9) to (Ir-16), adjacent substituents R₂₅ to R₂₈ are bonded together and form a ring. In the general formulae (Ir-3) to (Ir-8), at least one of R₂₁ to R₂₄ is a phenyl group or a naphthyl group and forms a ring with an adjacent group. In the general formulae (Ir-11) to (Ir-16), at least one of R₂₅ to R₂₈ is a phenyl group or a naphthyl group and forms a ring with an adjacent group. Thus, the general formulae (Ir-3) to (Ir-8) and (Ir-11) to (Ir-16) may or may not further have an aryl group or a heterocyclic group.

A metal complex with the substructure M(L)ₘ represented by one of the general formulae (Ir-1) to (Ir-16) can have a tricyclic or polycyclic fused ring as a ligand. More specifically, a metal complex can have the substructure M(L)ₘ represented by one of the general formulae (Ir-3) to (Ir-8) and (Ir-11) to (Ir-16). Specific examples of such a metal complex include, but are not limited to, the following.

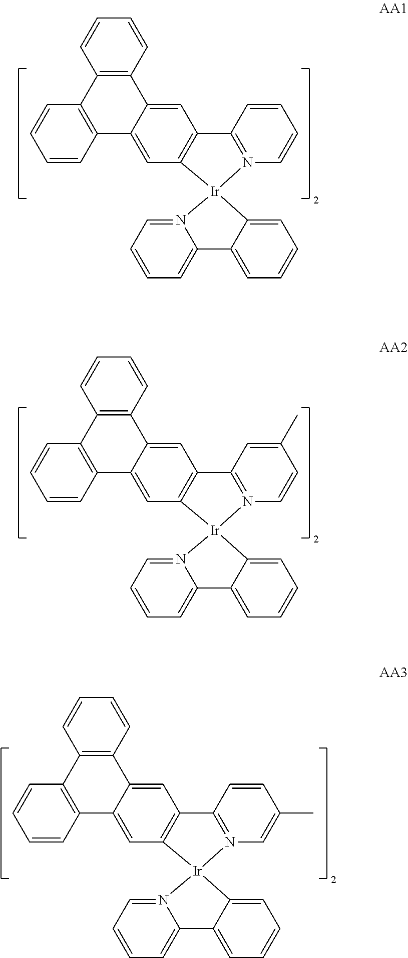

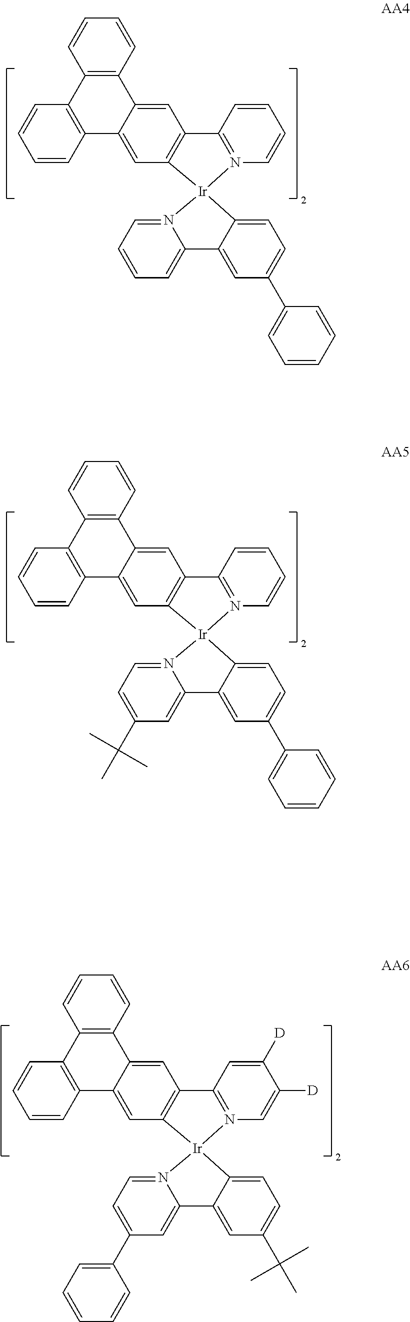

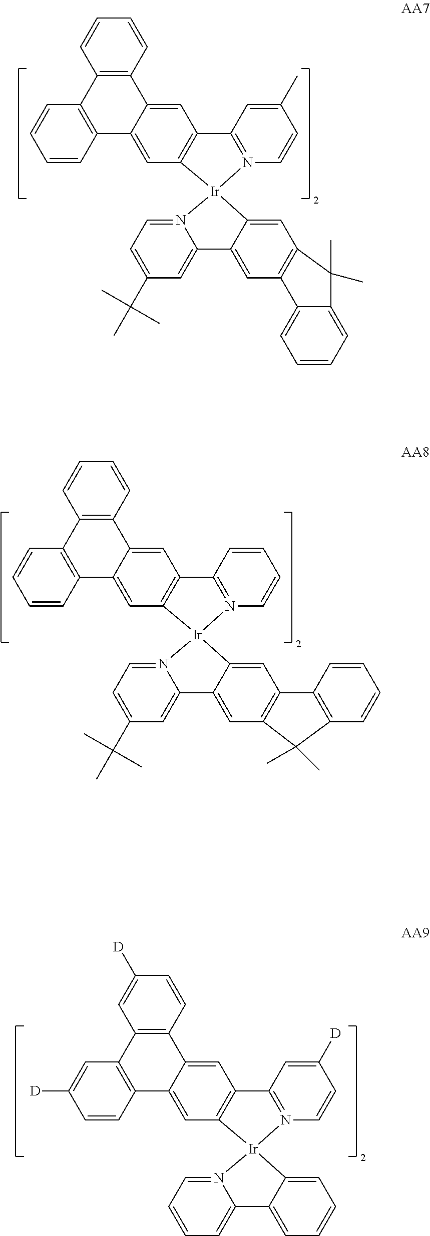

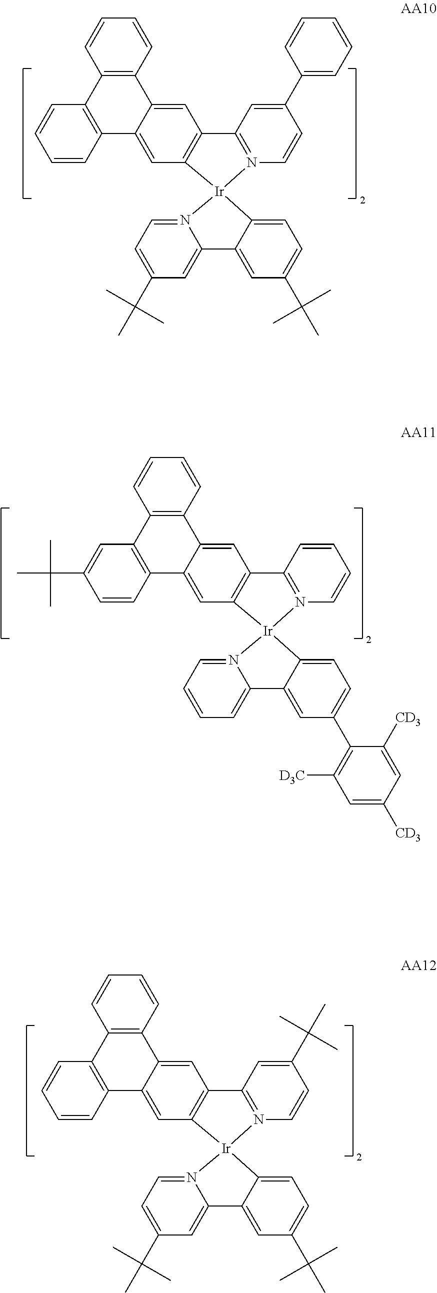

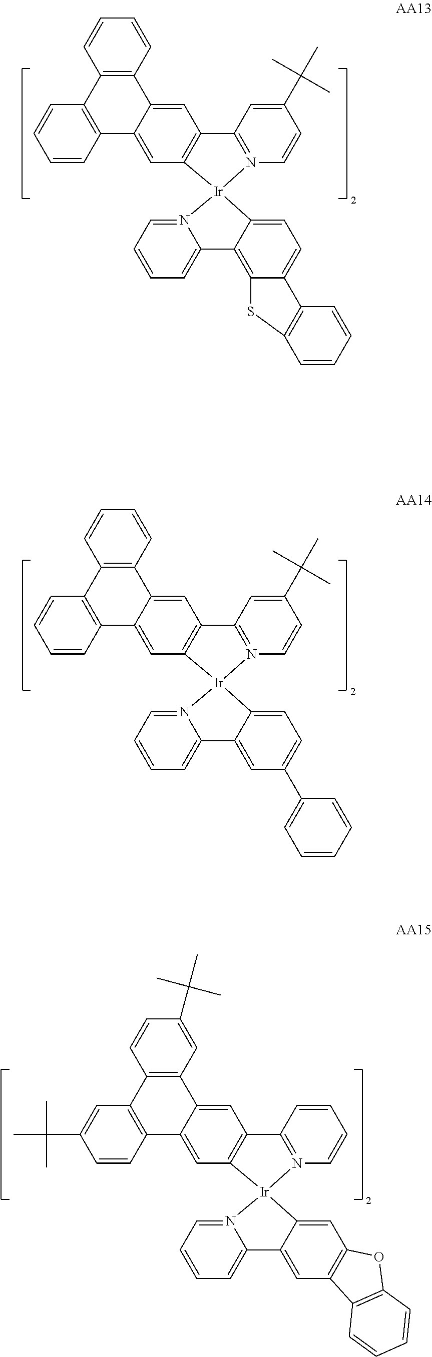

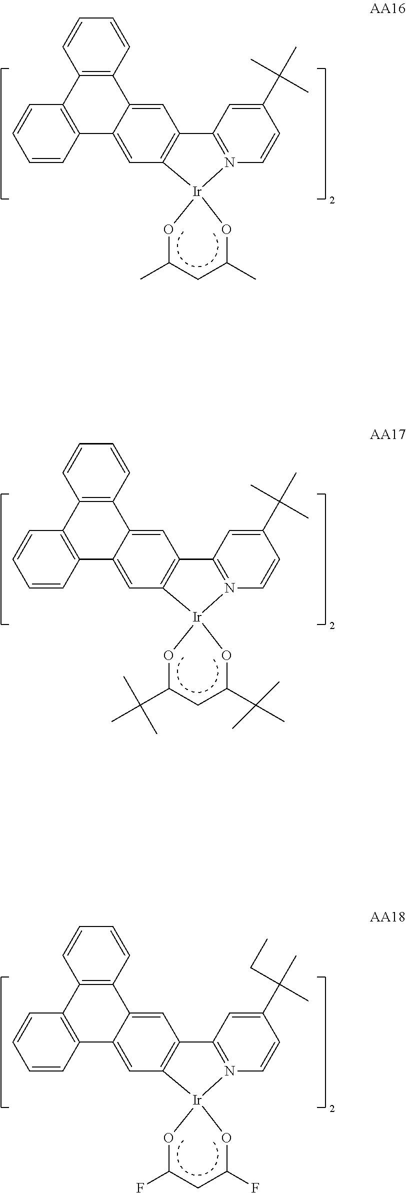

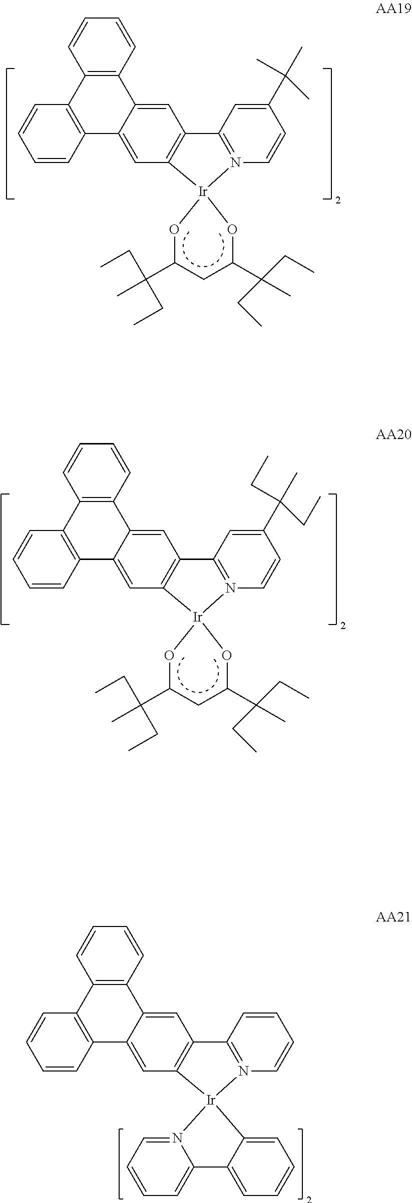

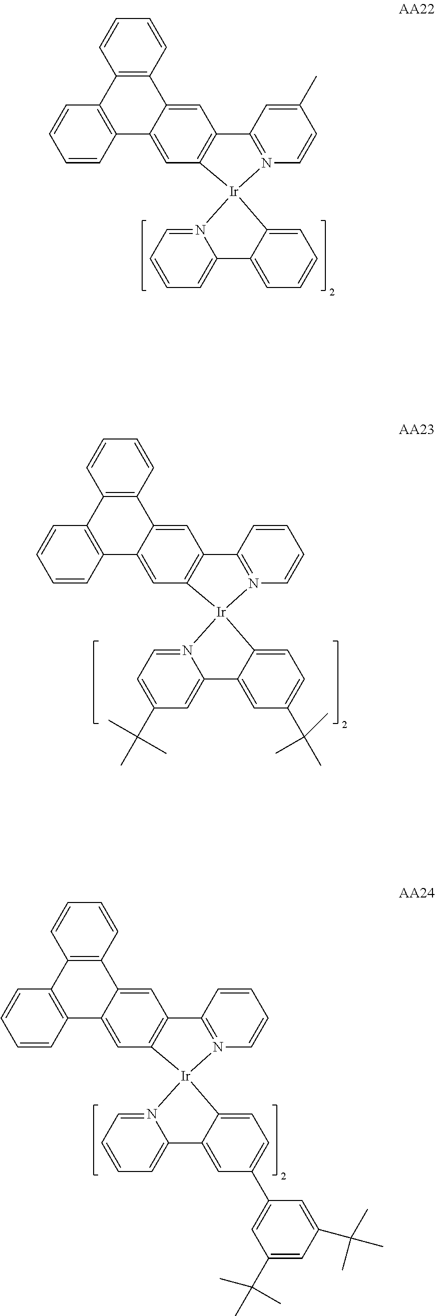

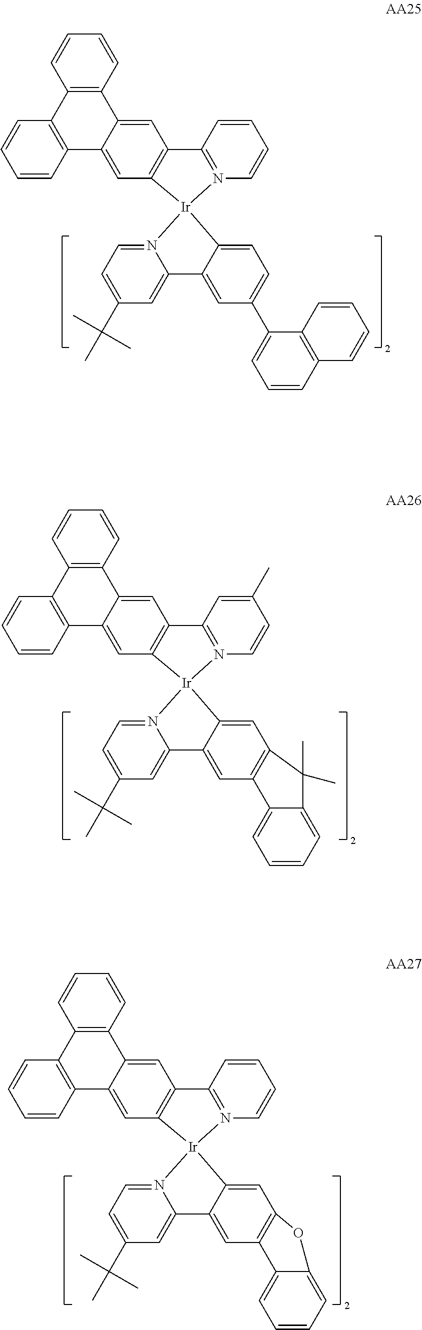

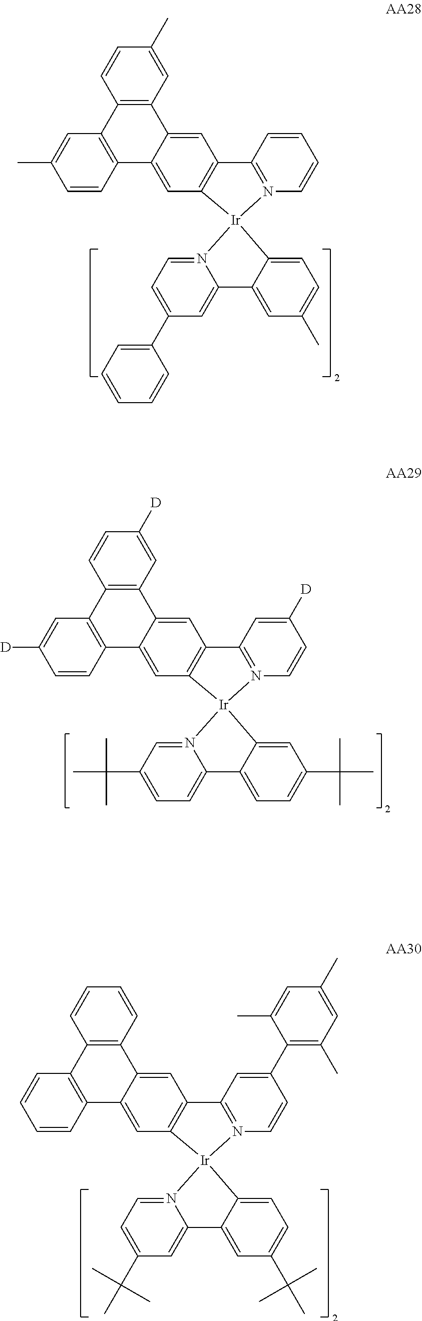

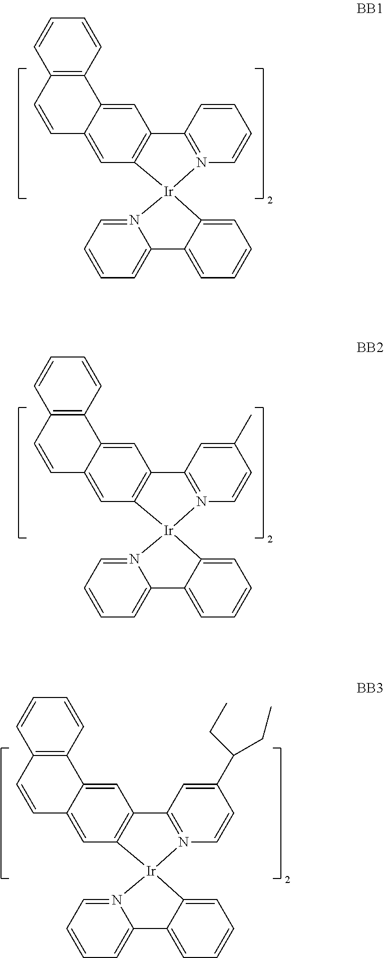

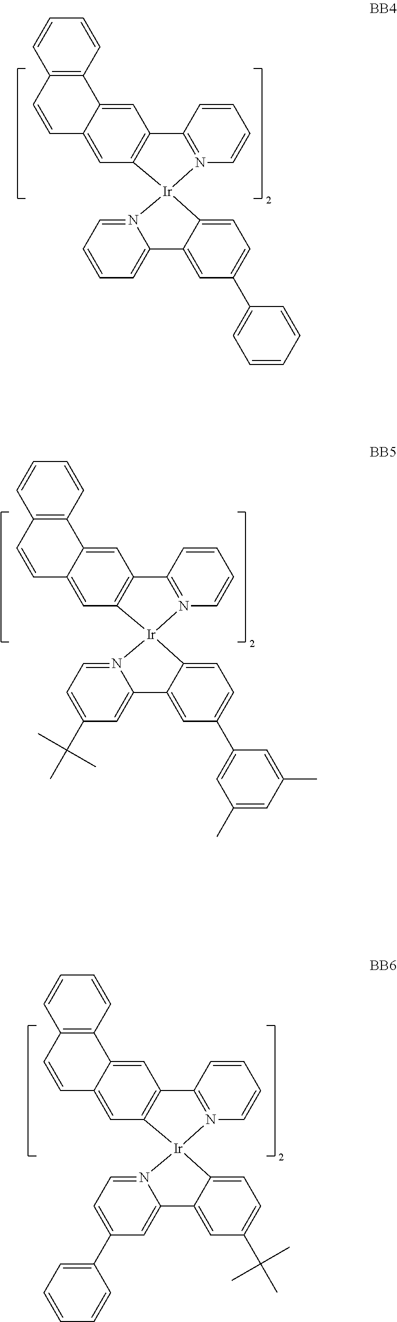

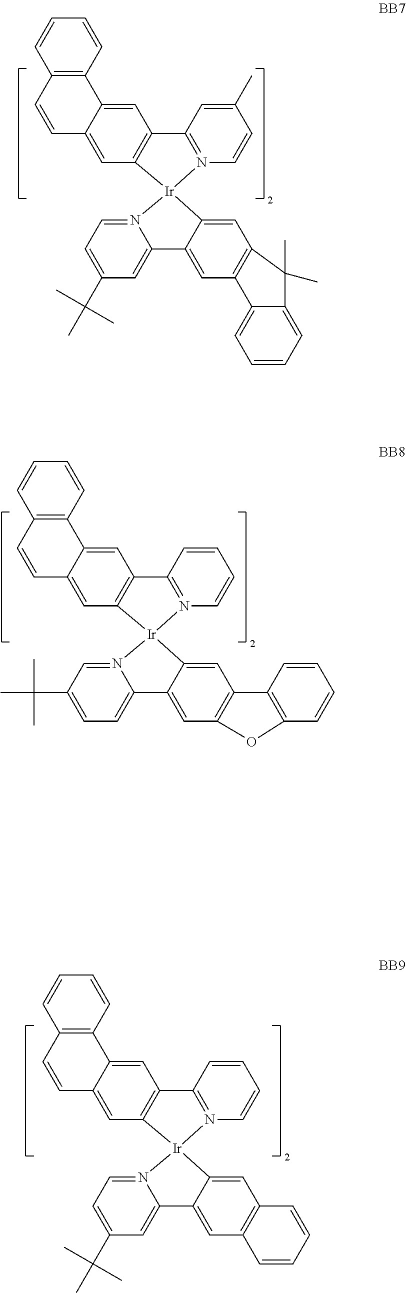

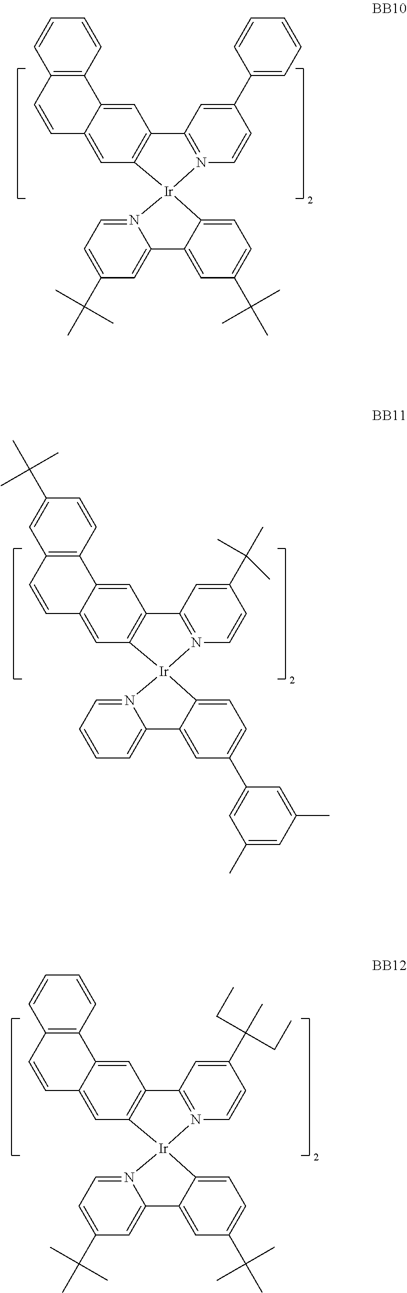

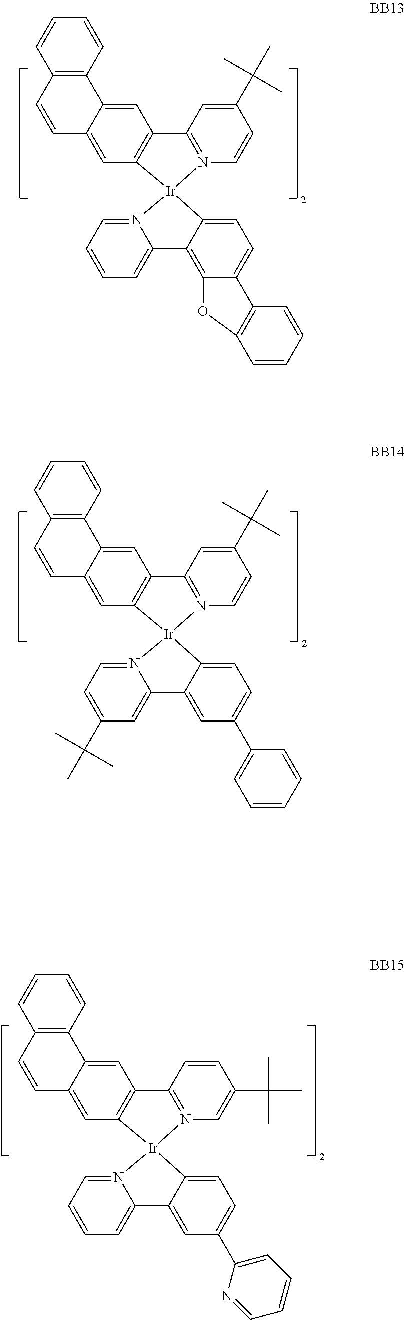

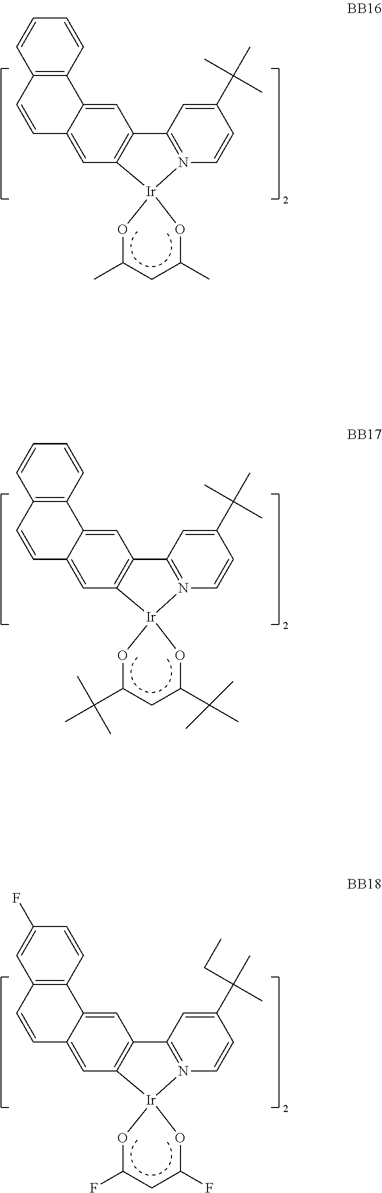

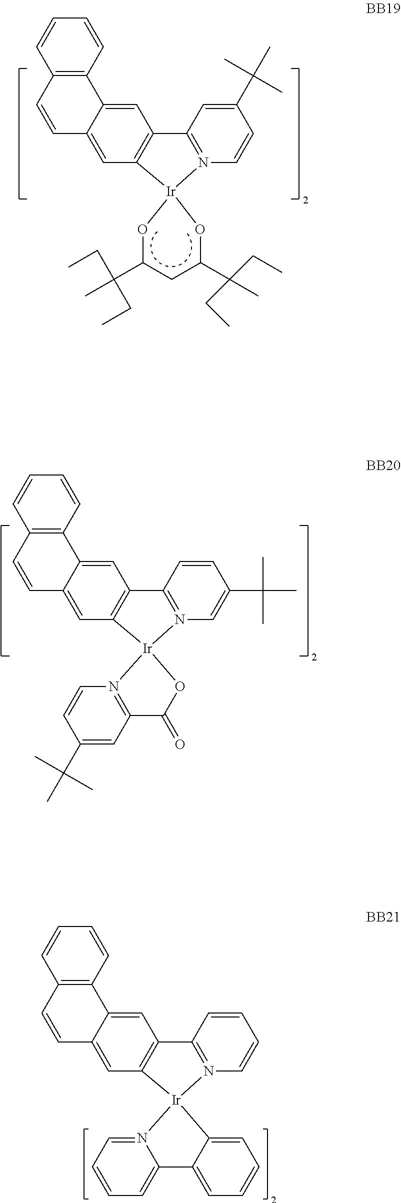

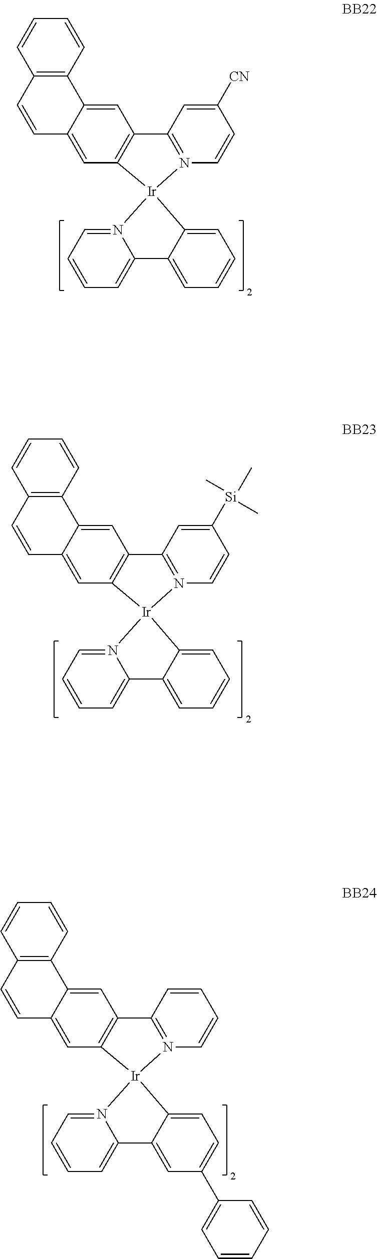

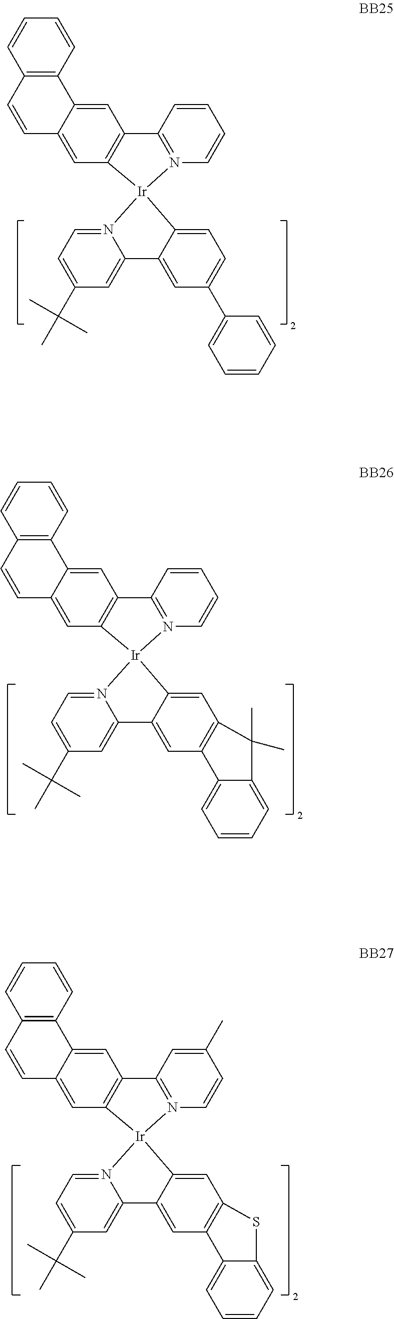

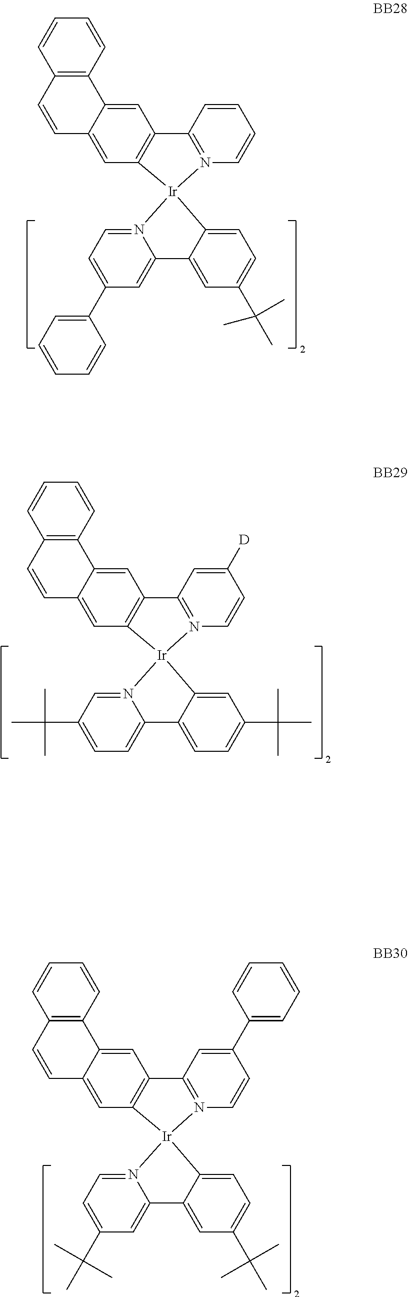

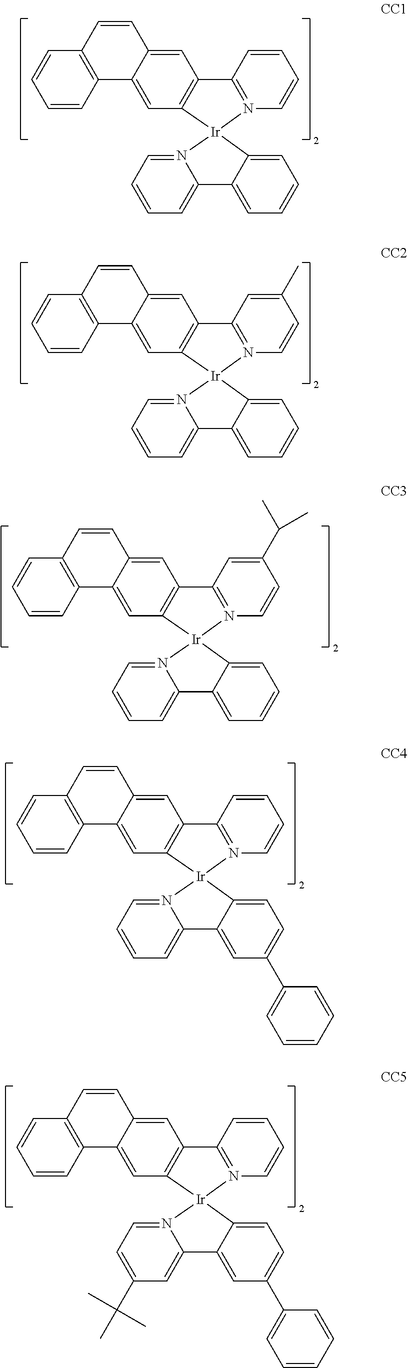

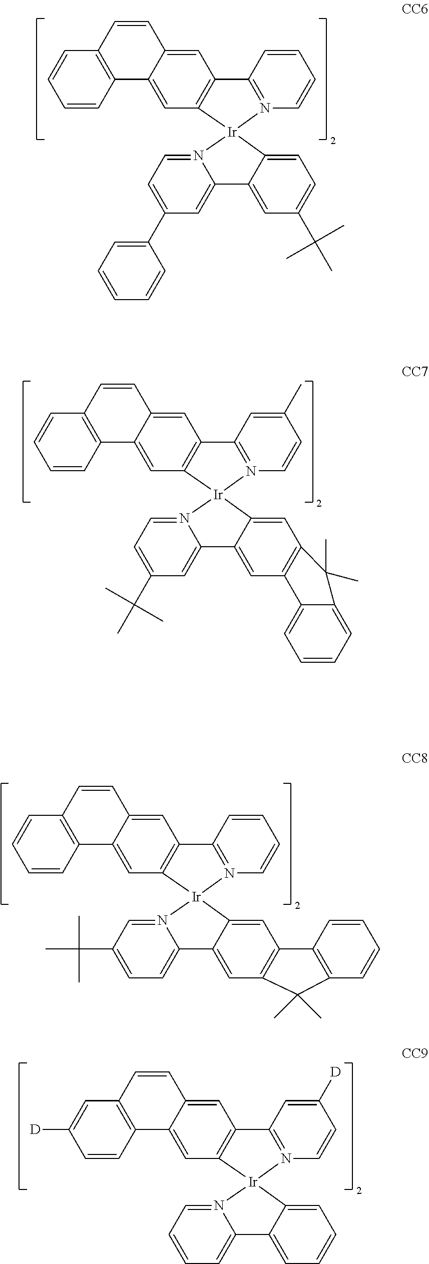

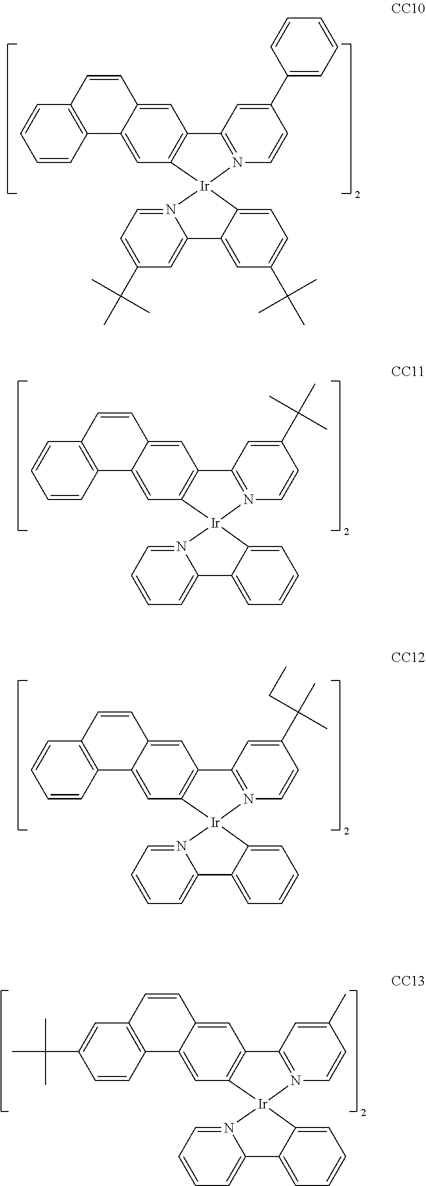

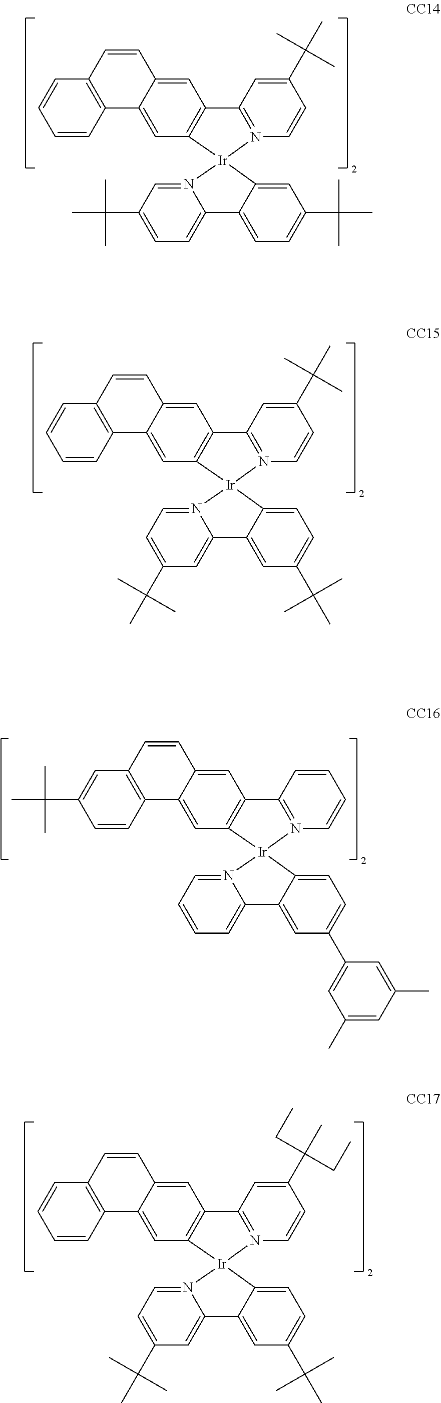

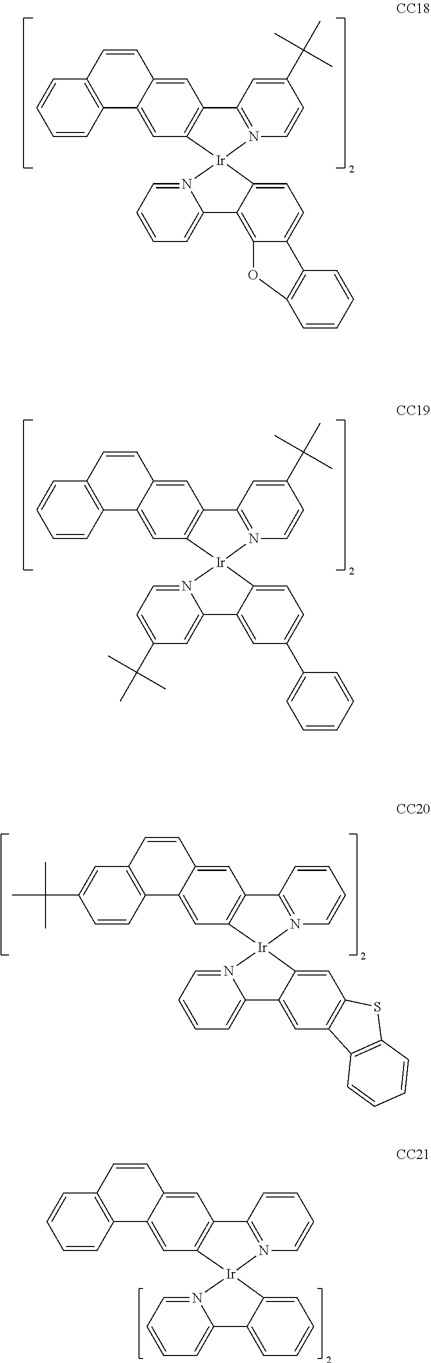

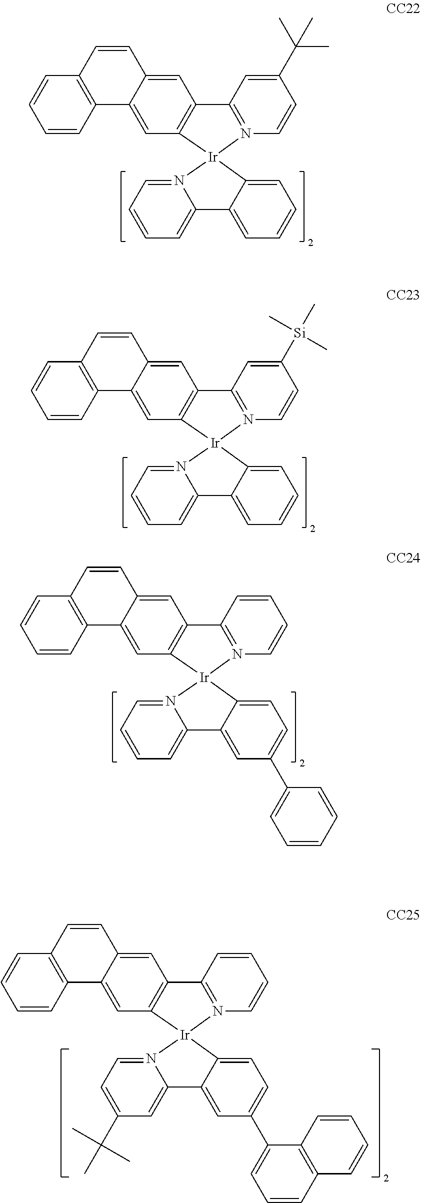

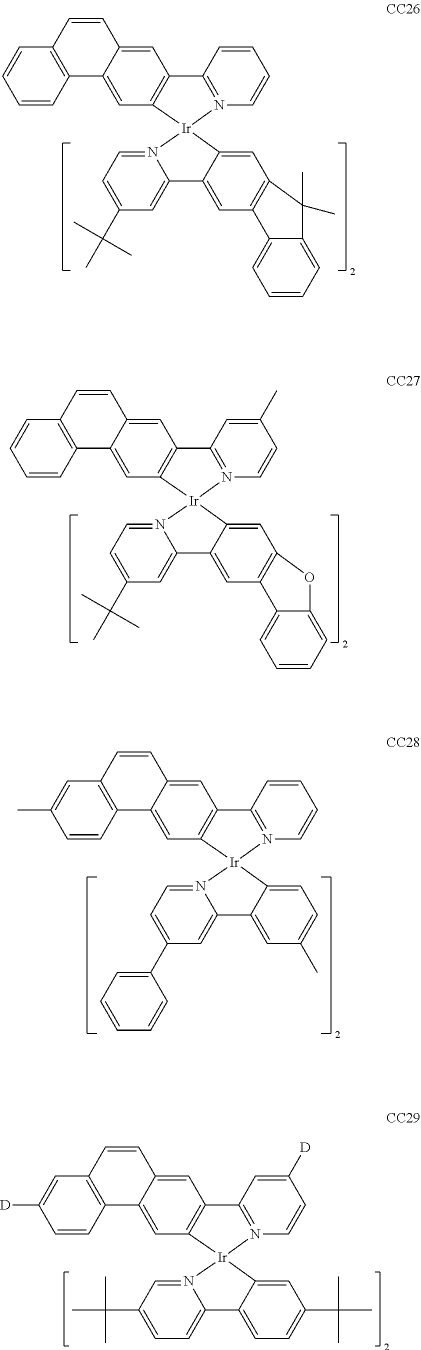

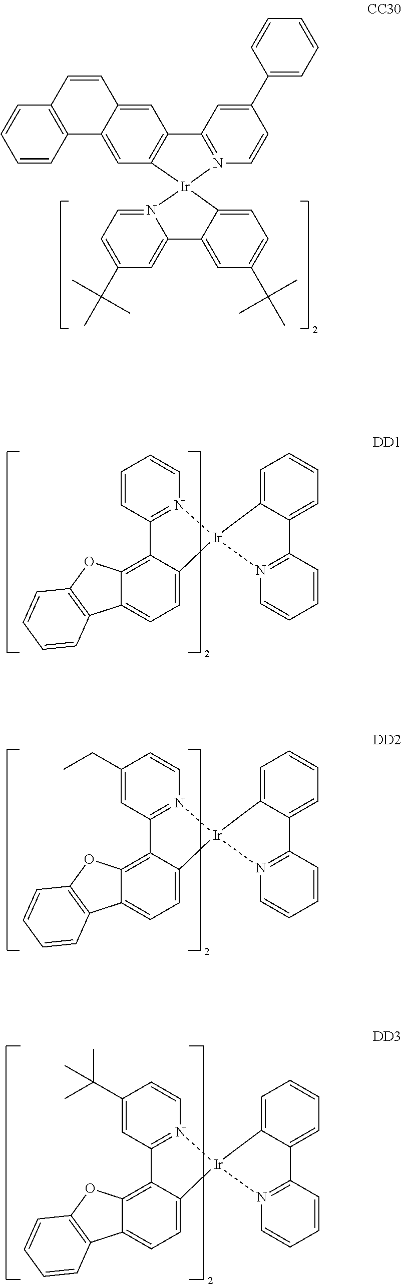

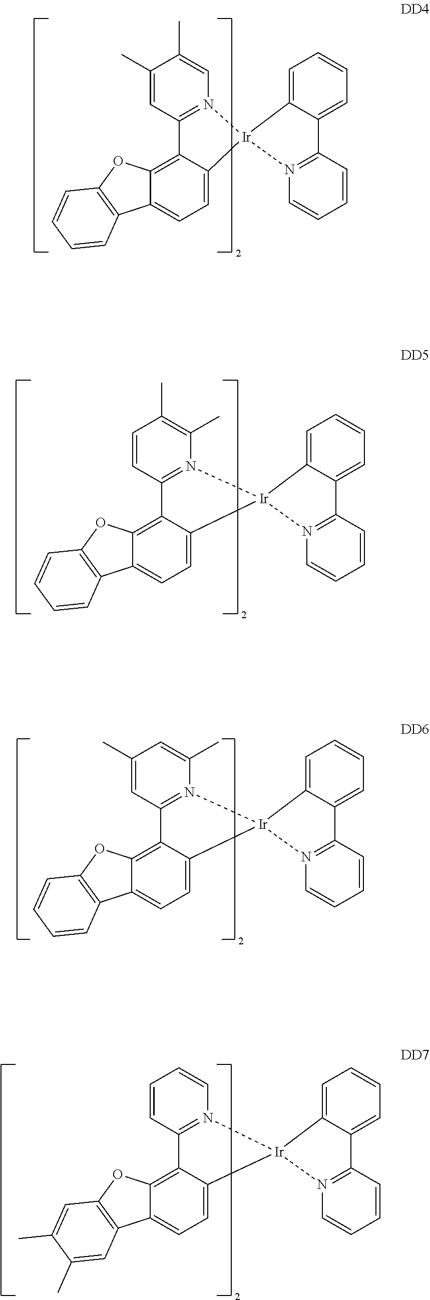

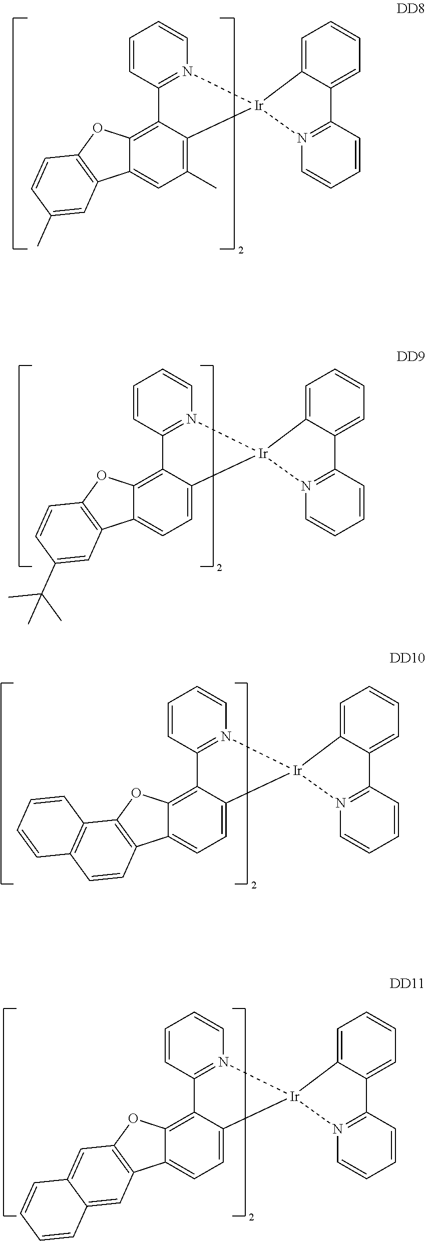

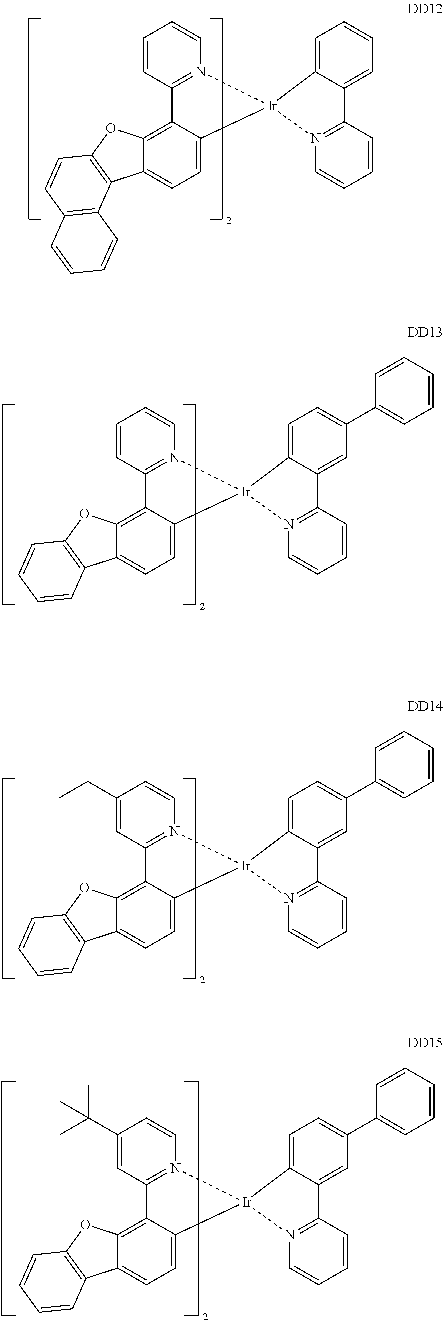

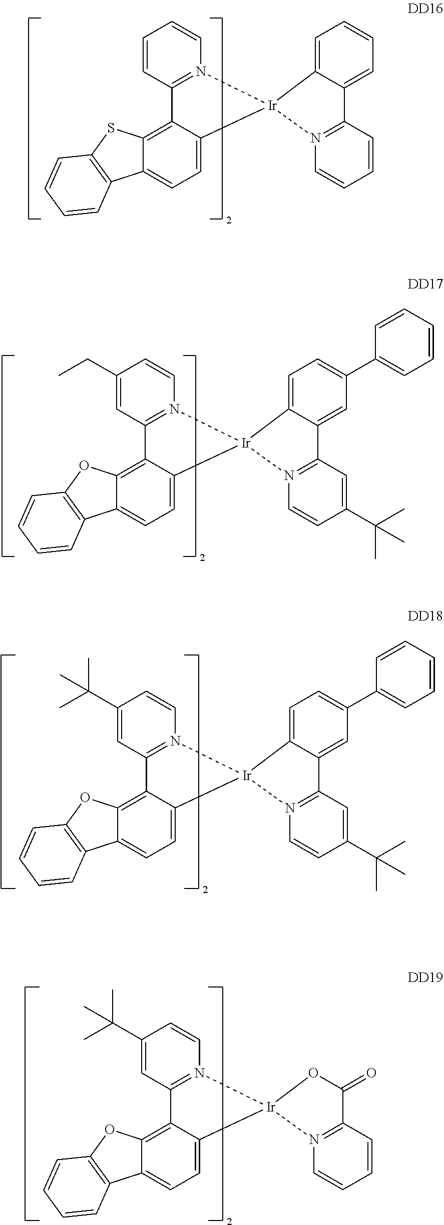

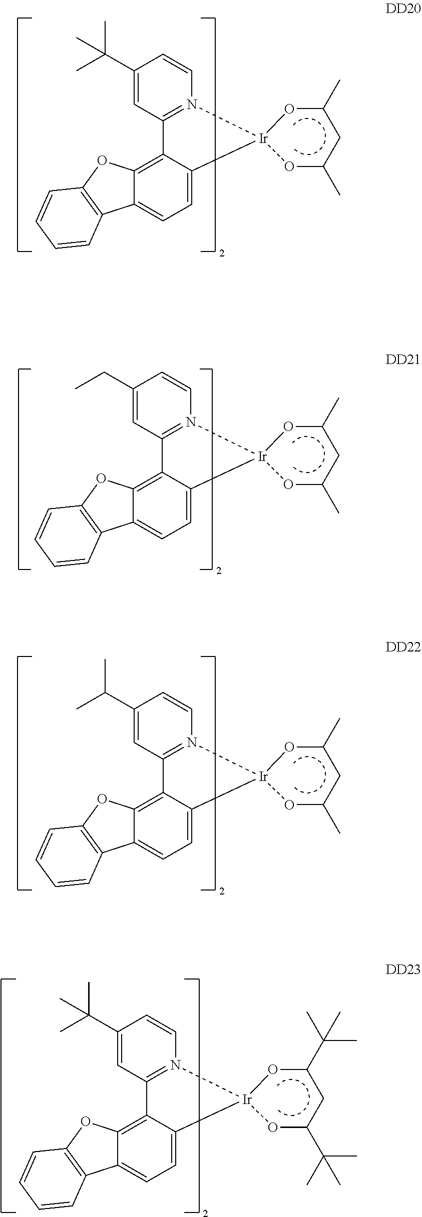

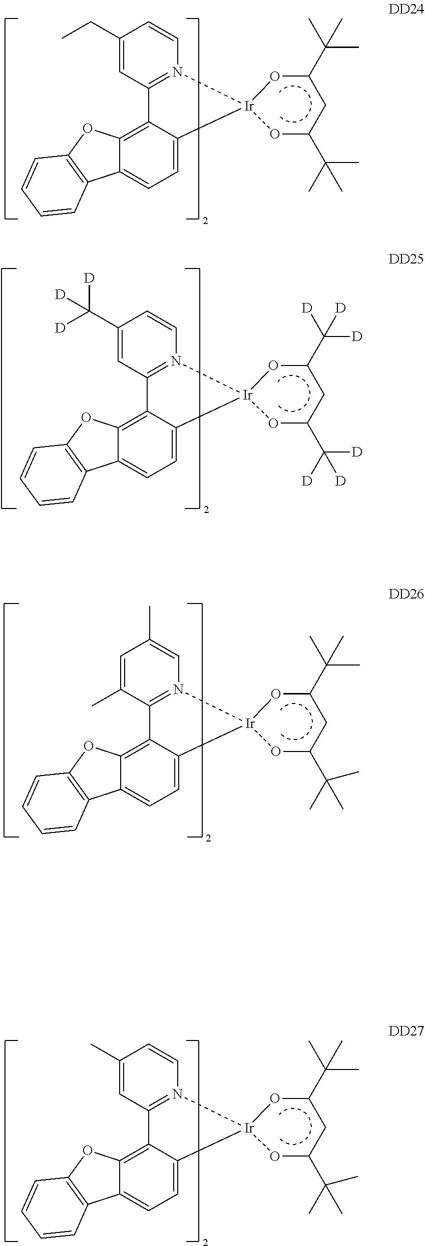

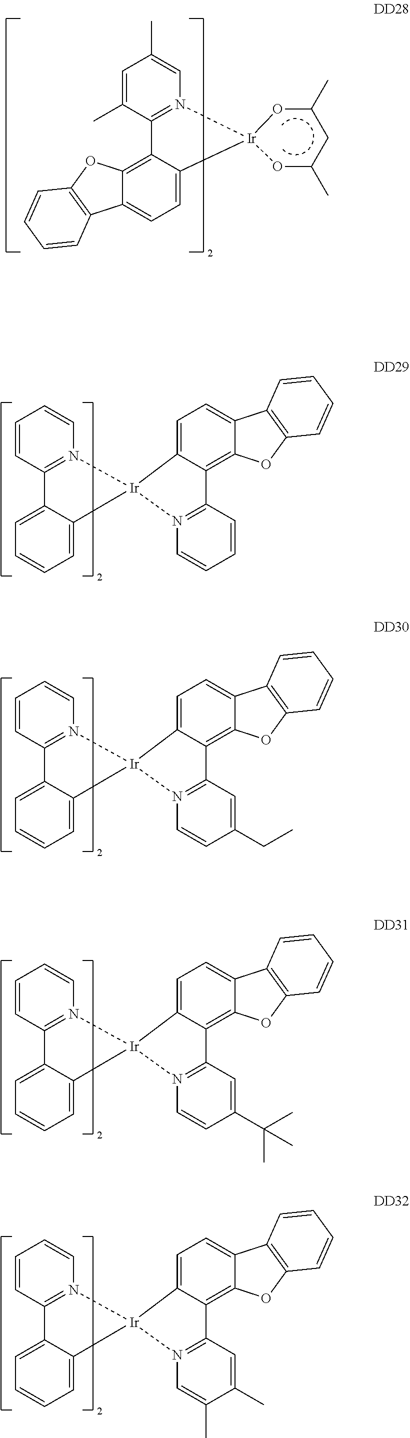

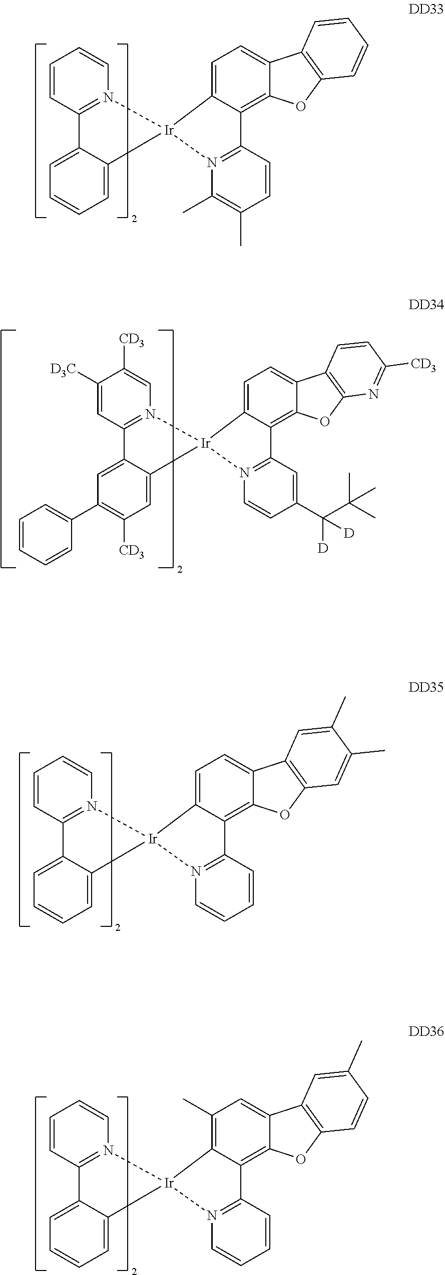

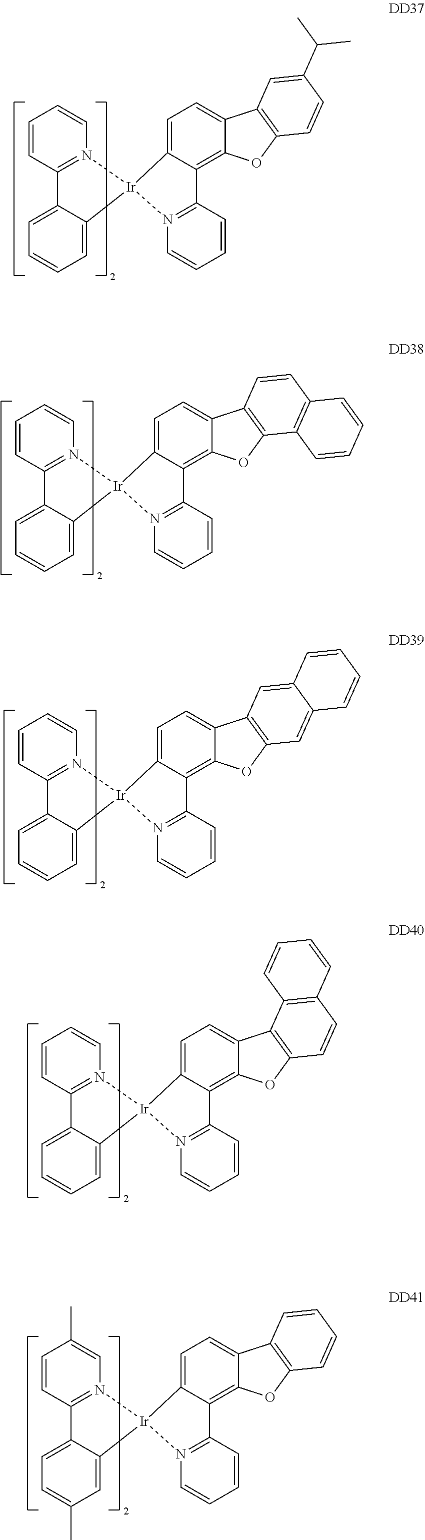

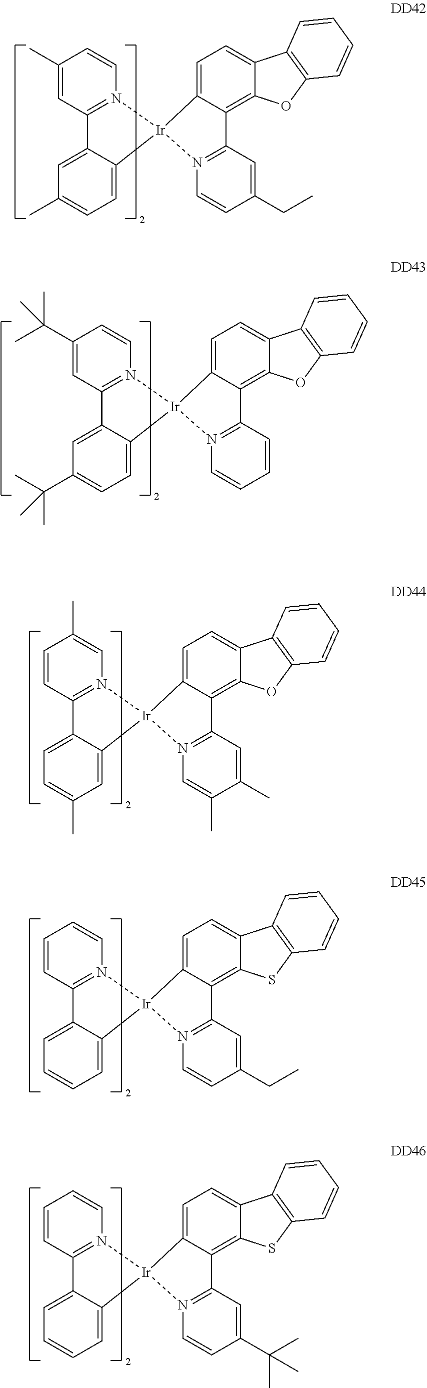

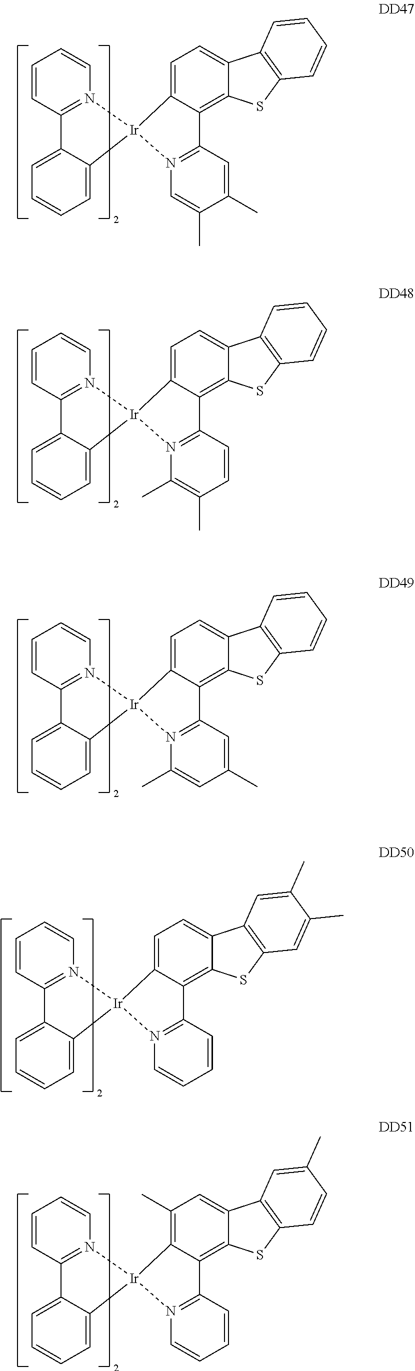

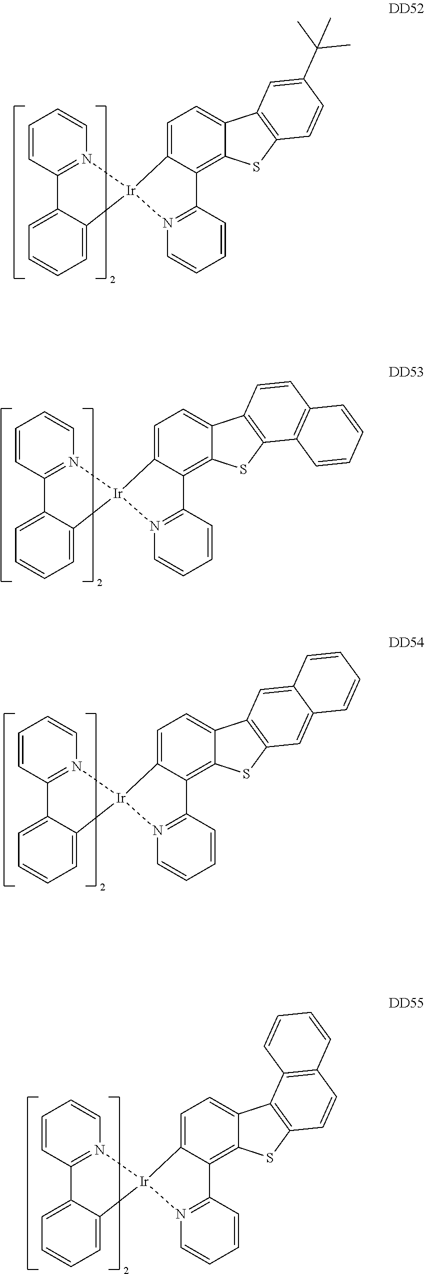

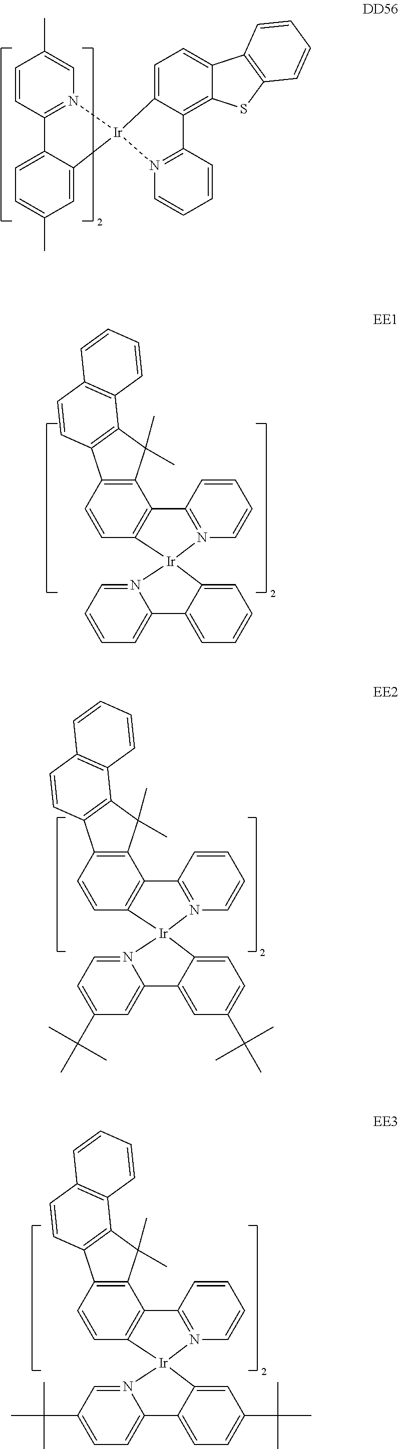

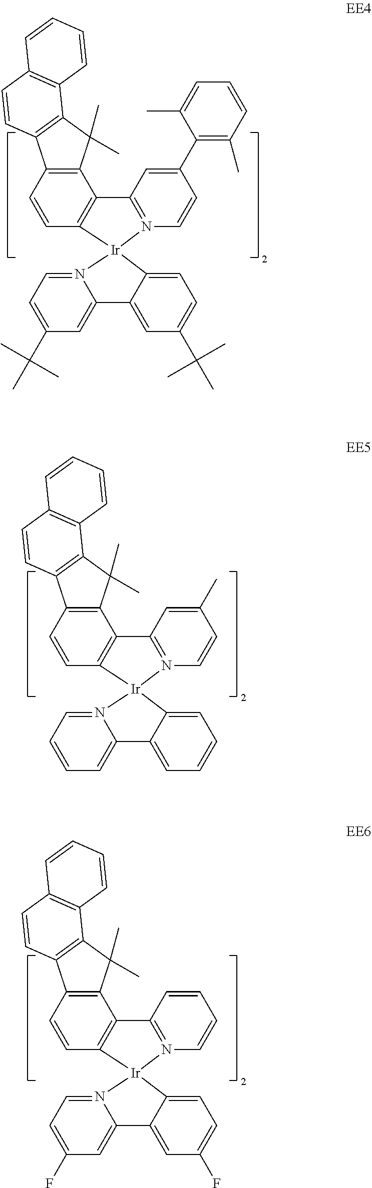

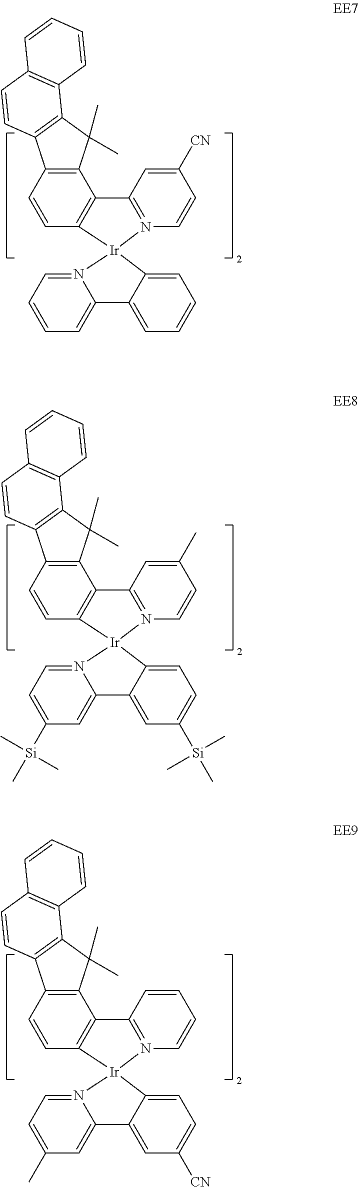

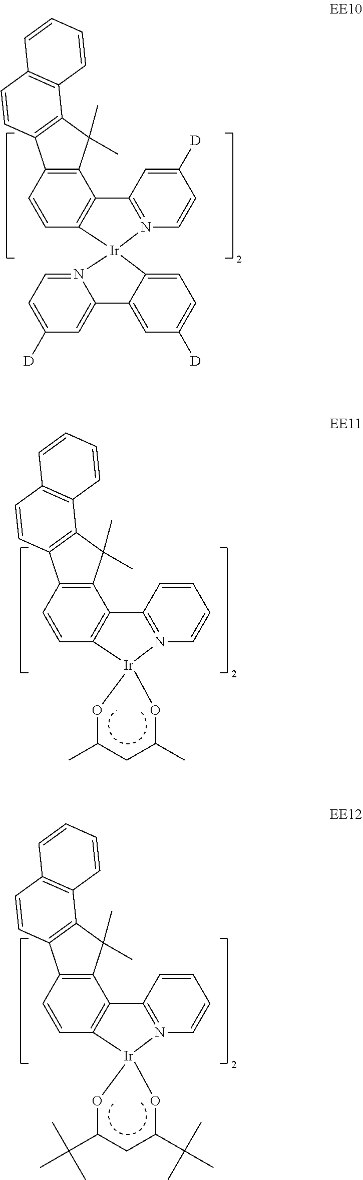

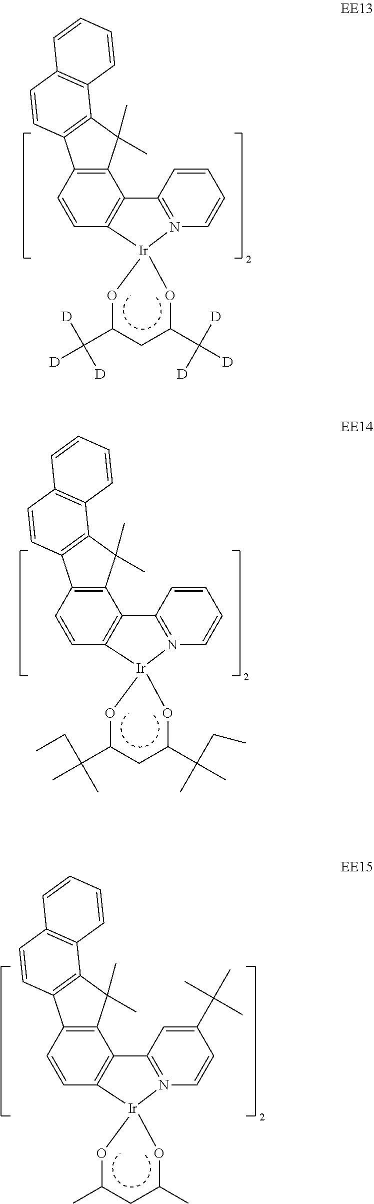

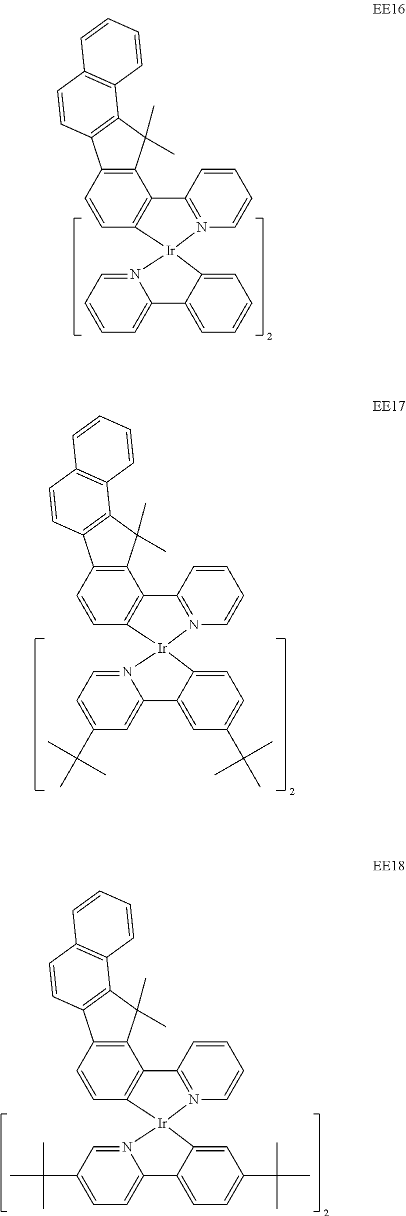

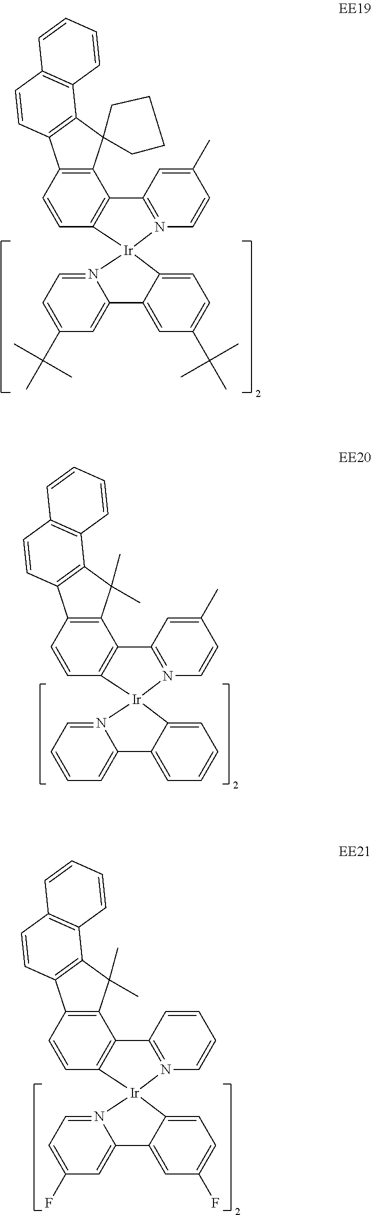

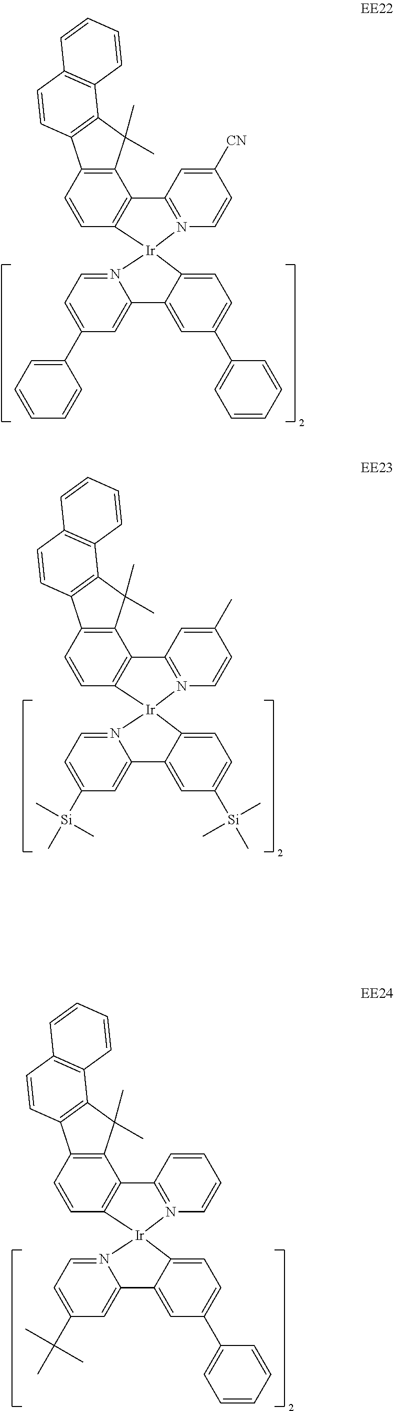

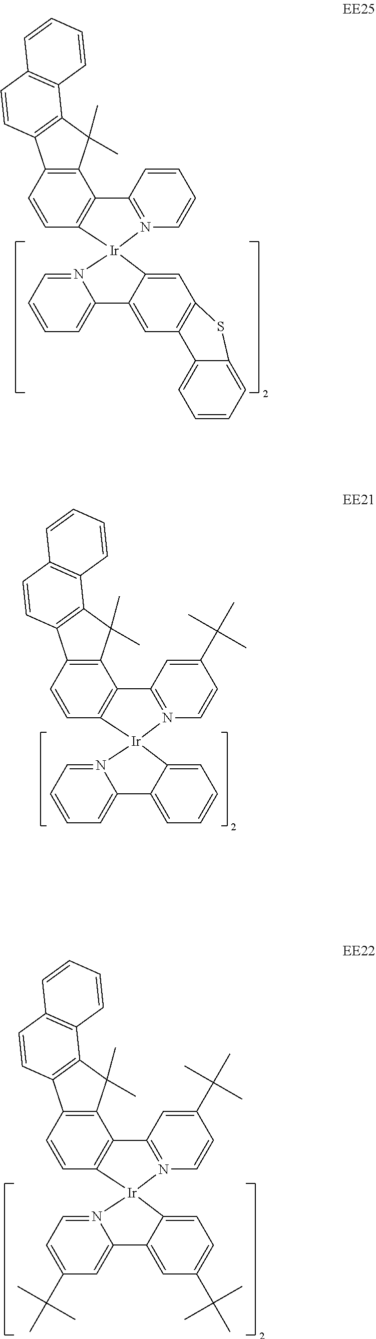

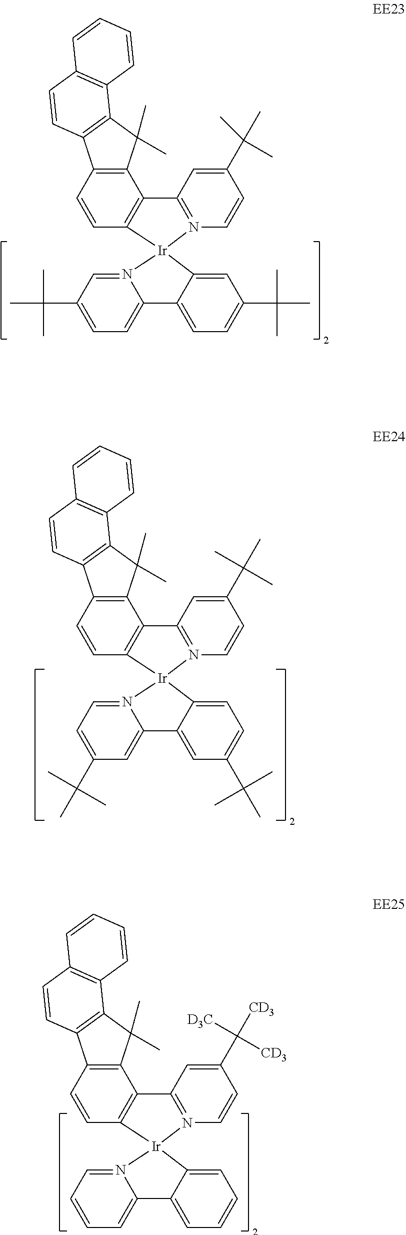

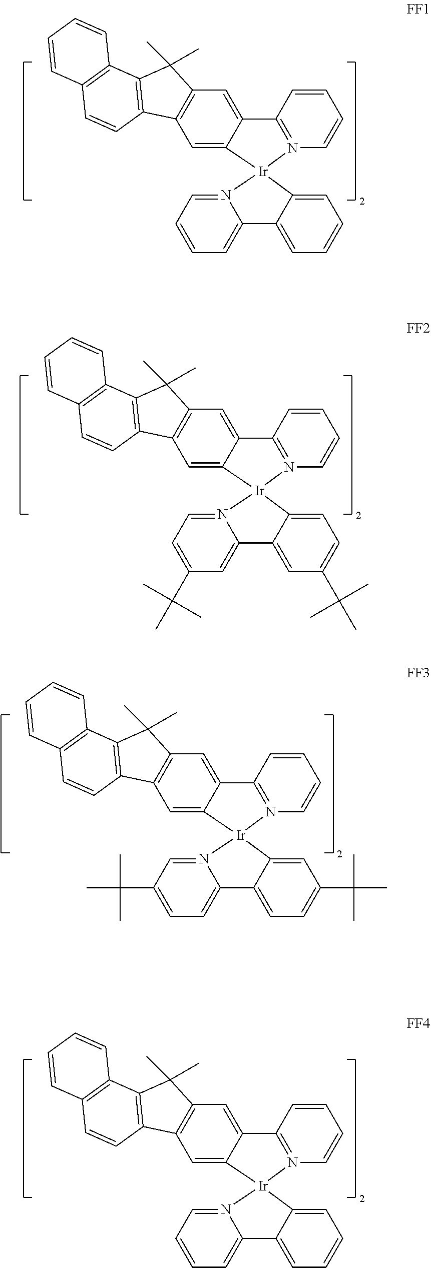

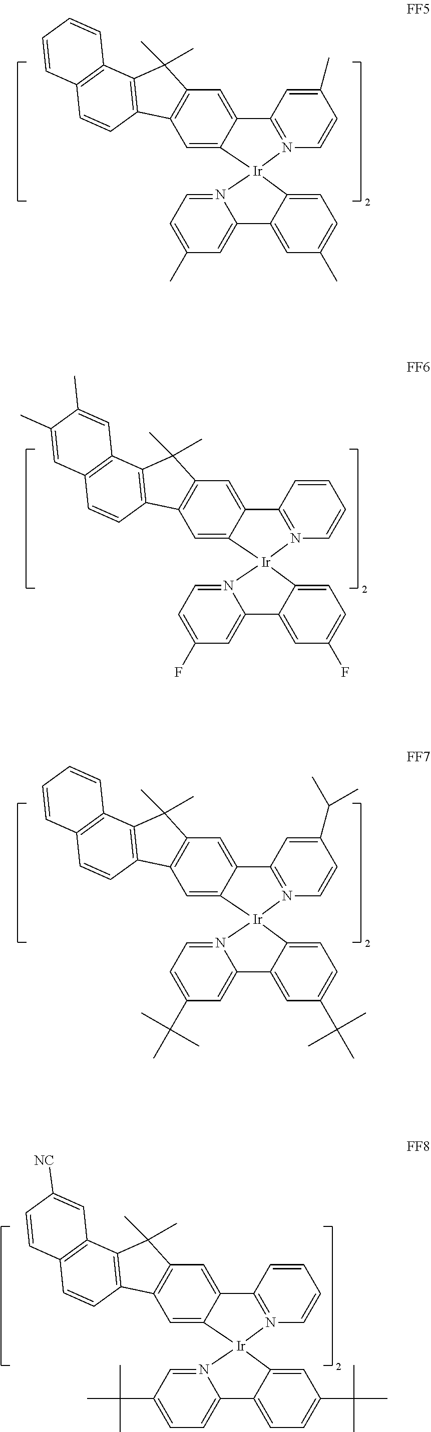

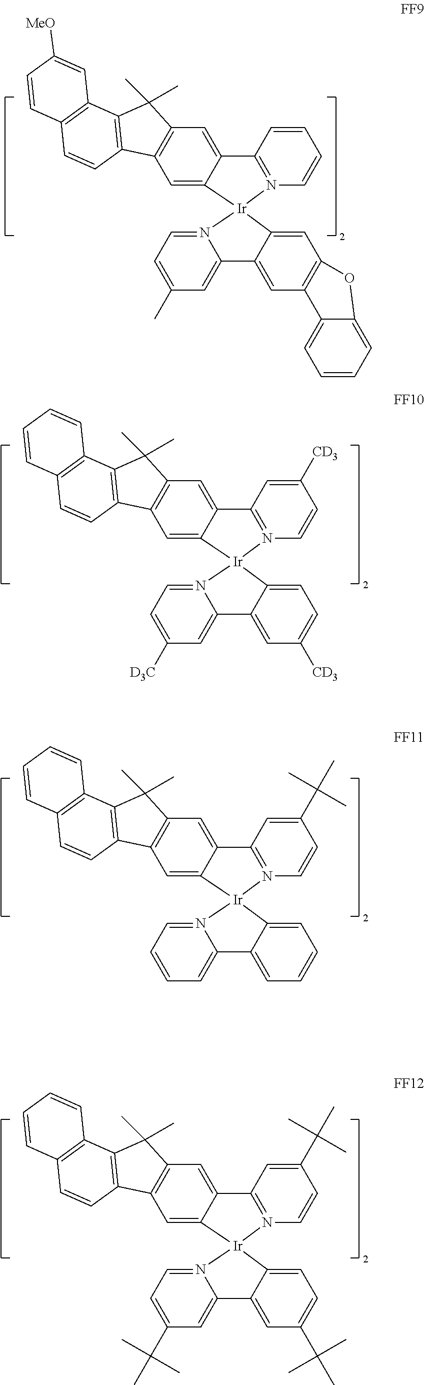

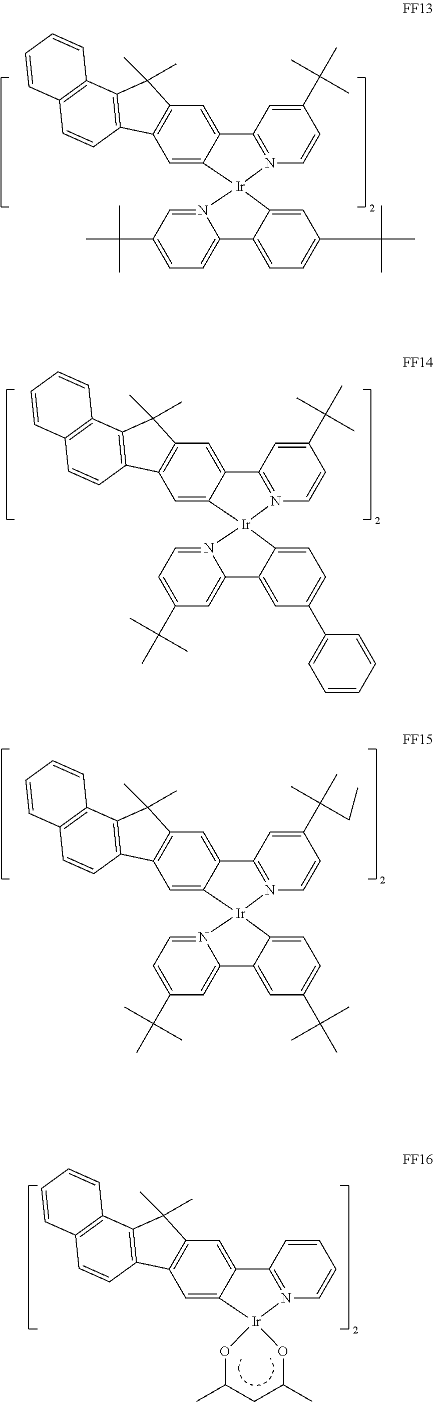

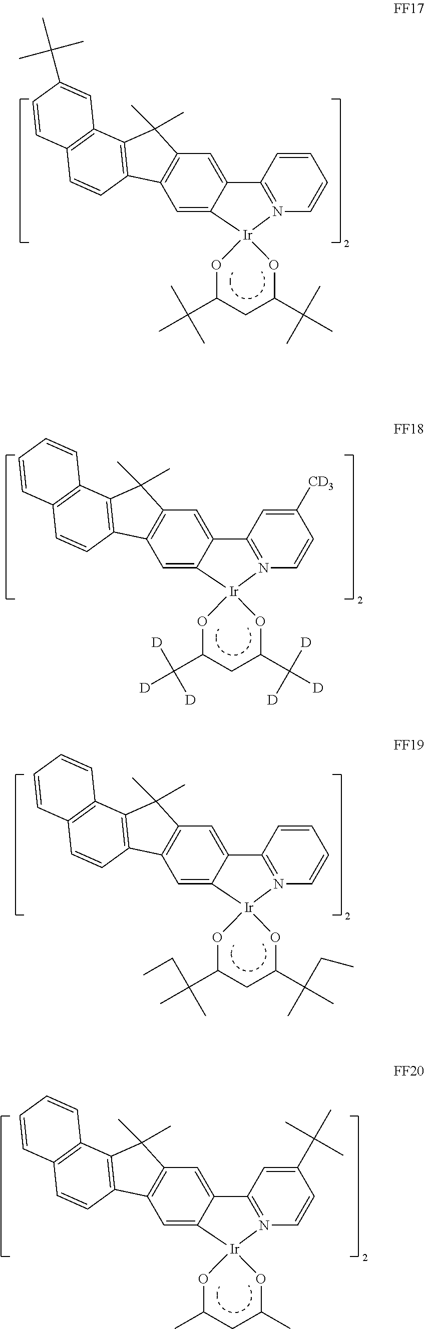

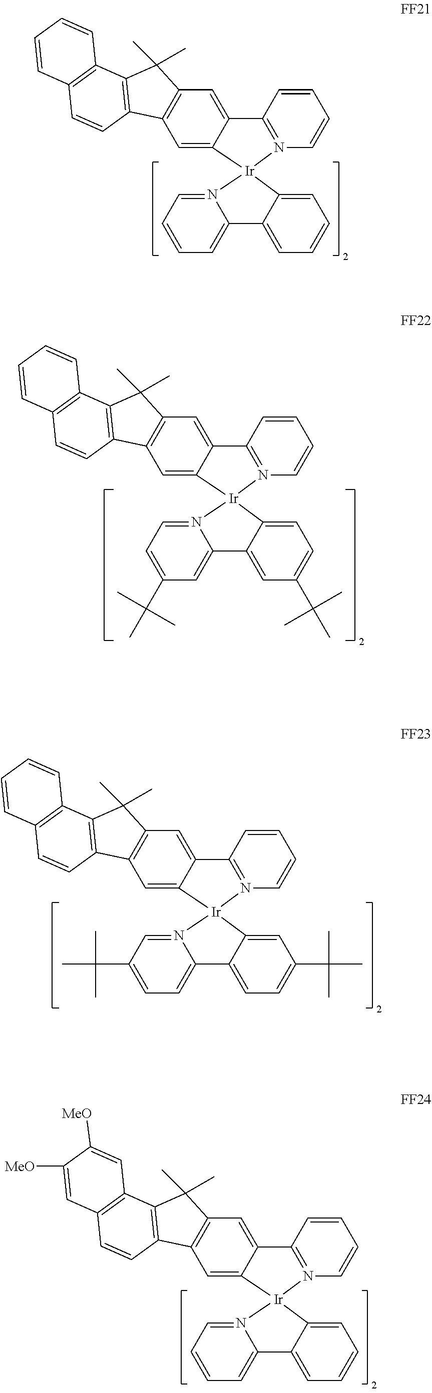

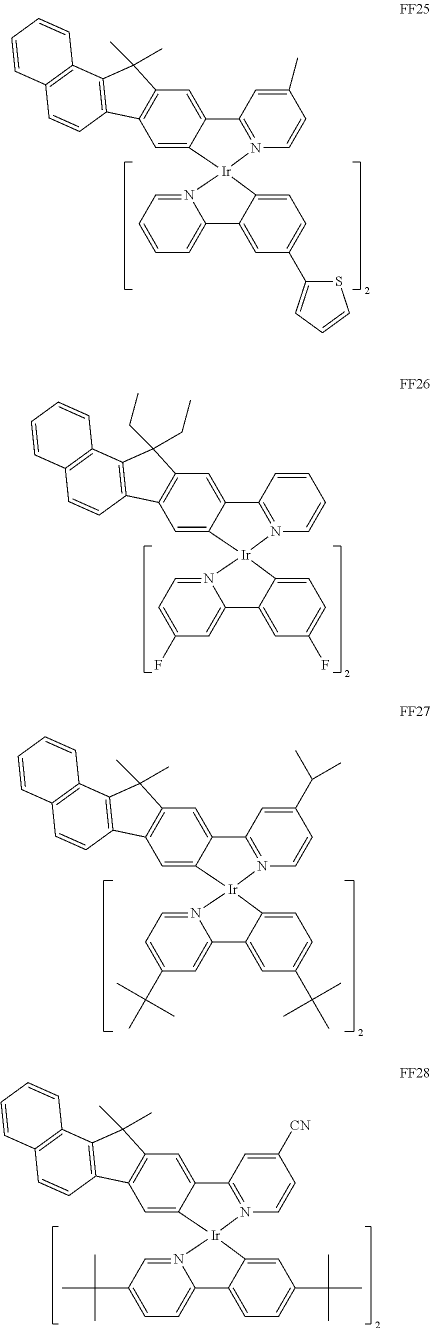

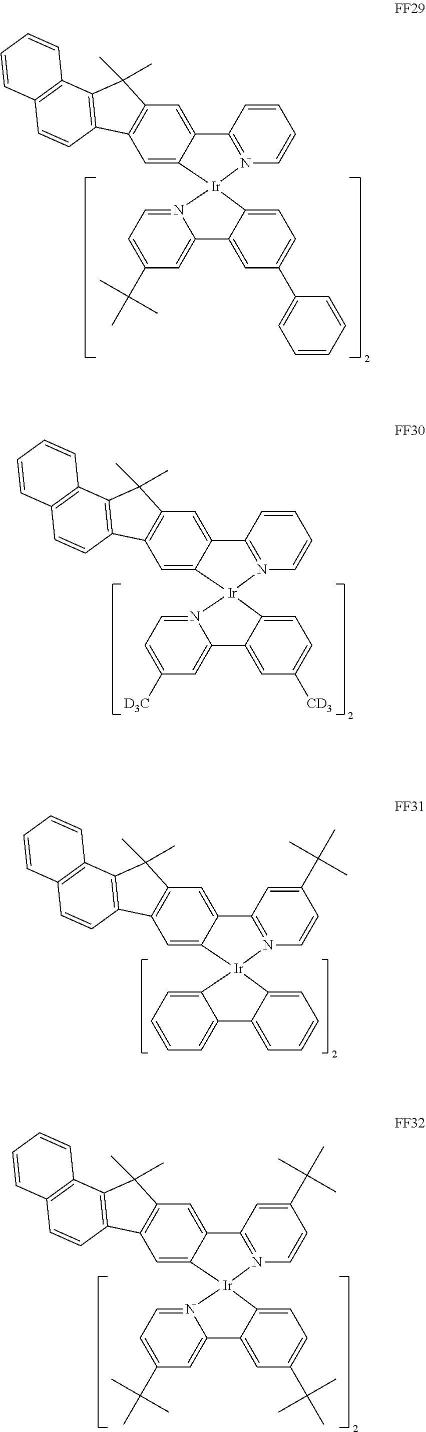

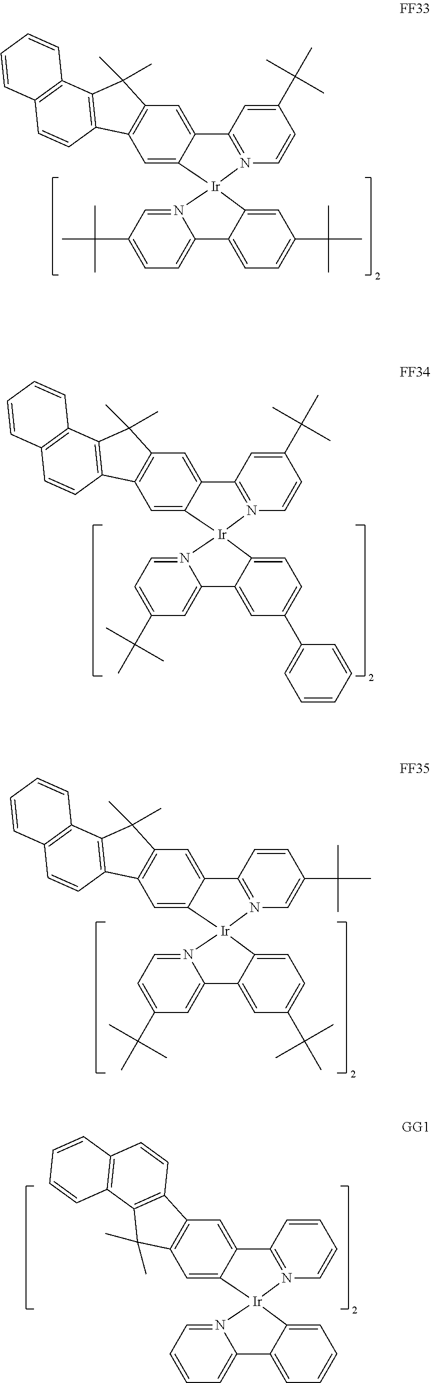

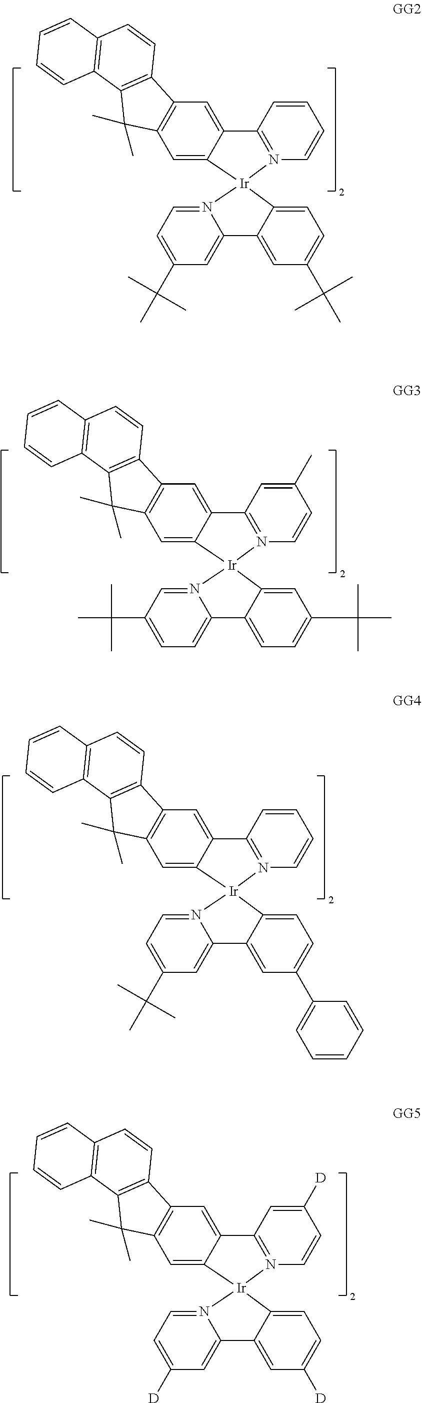

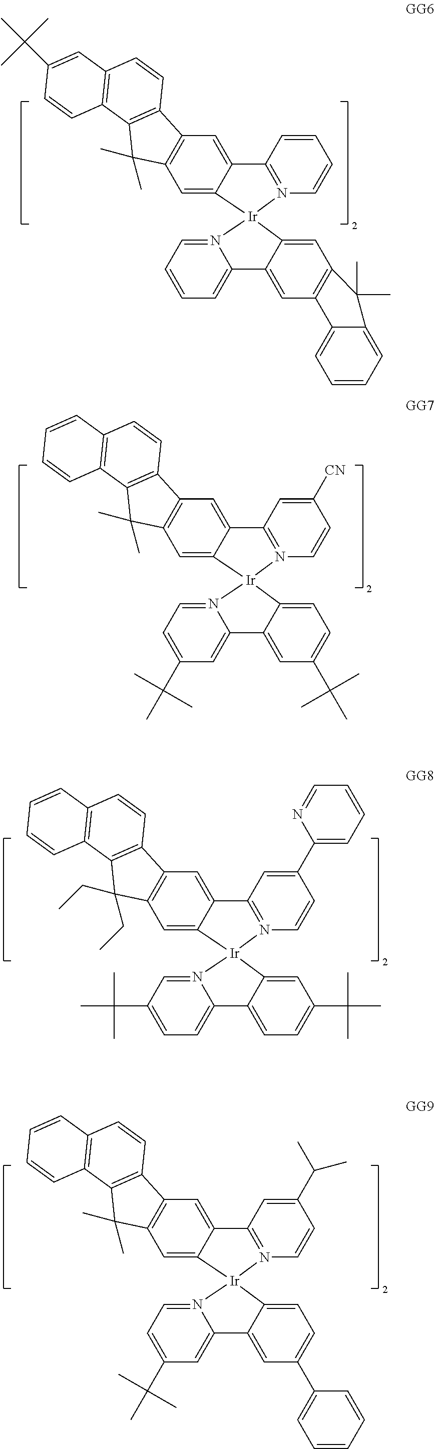

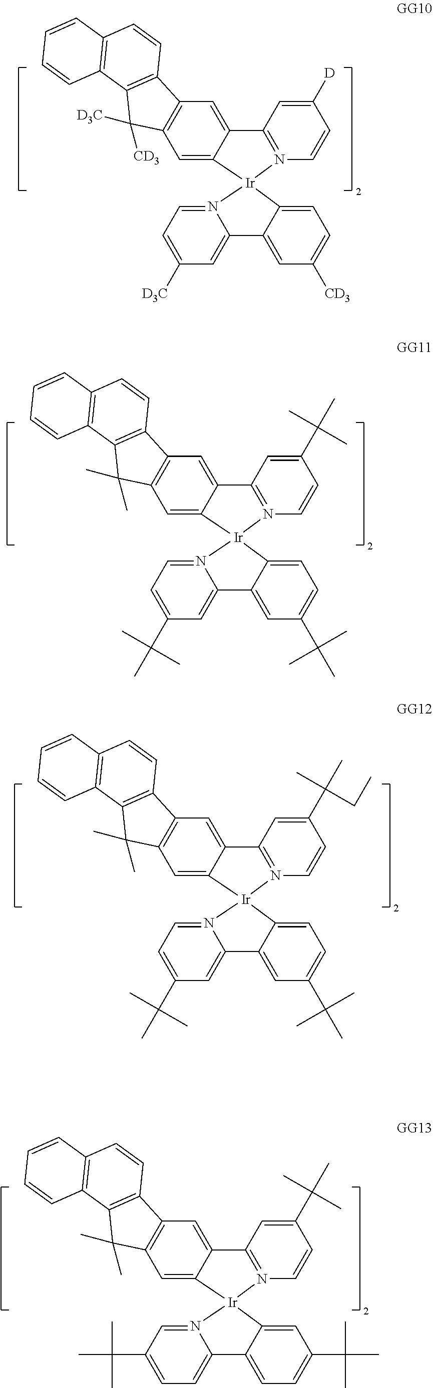

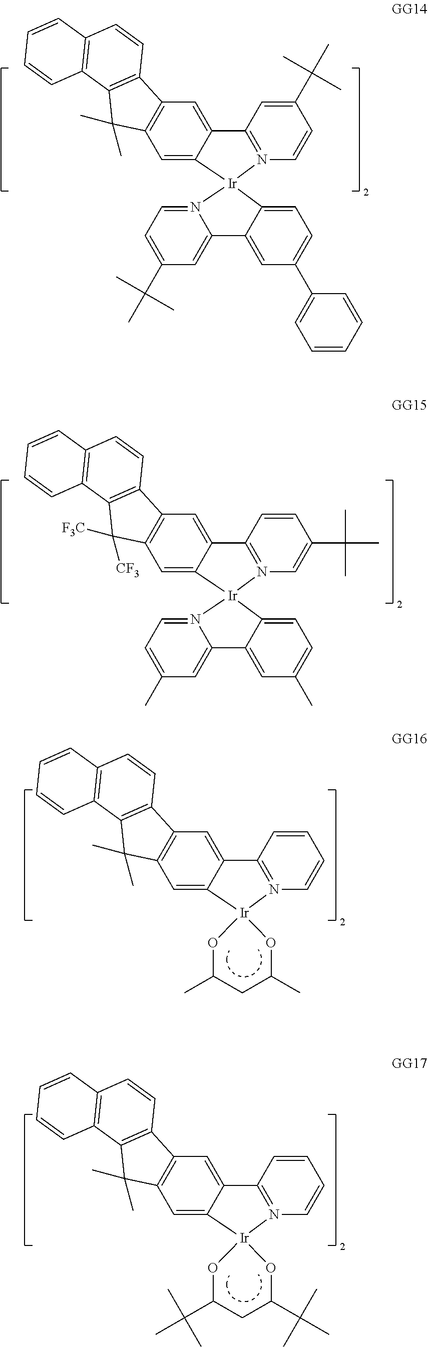

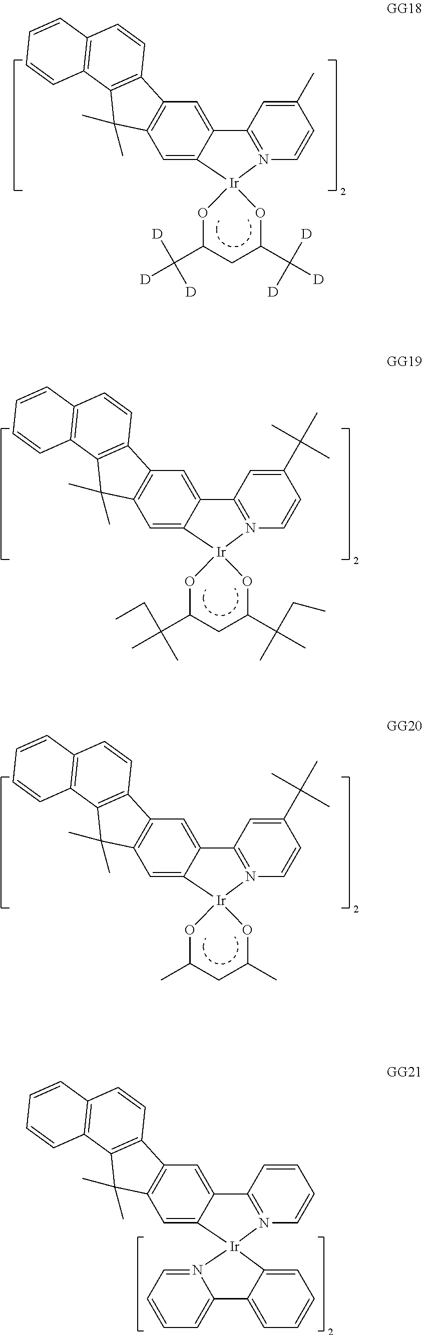

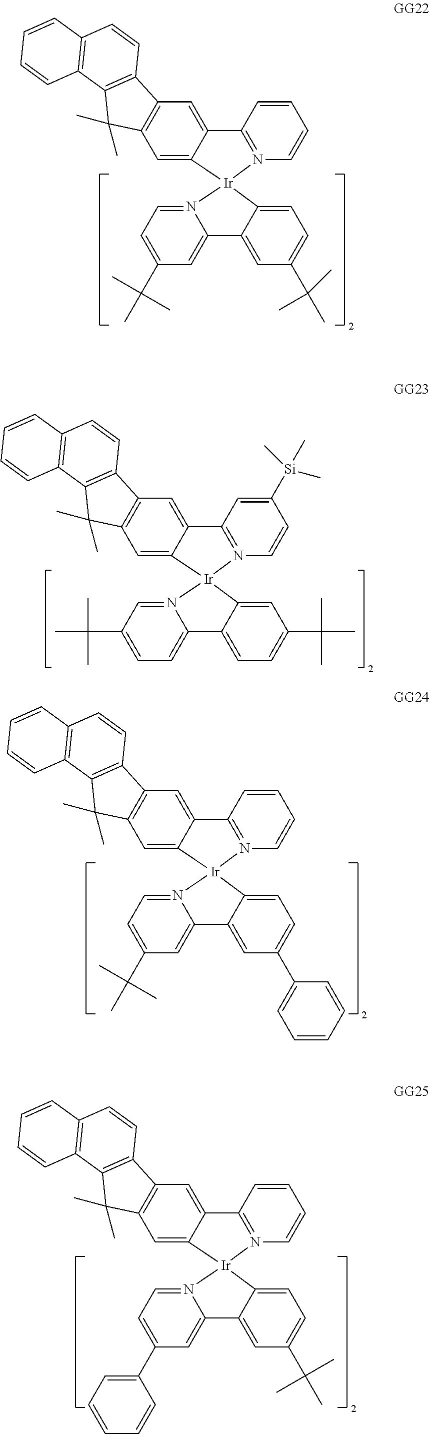

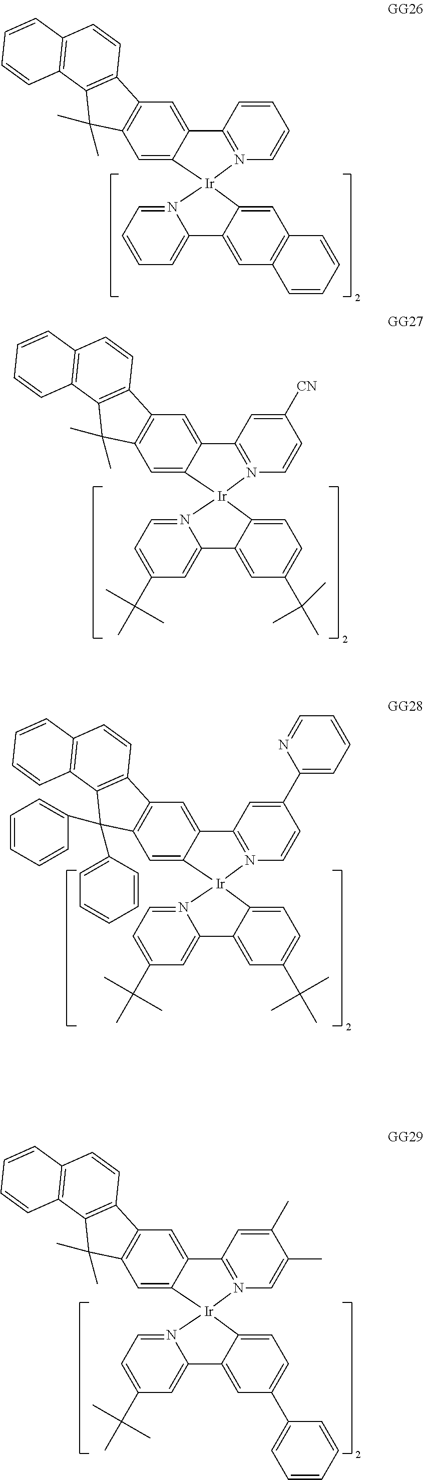

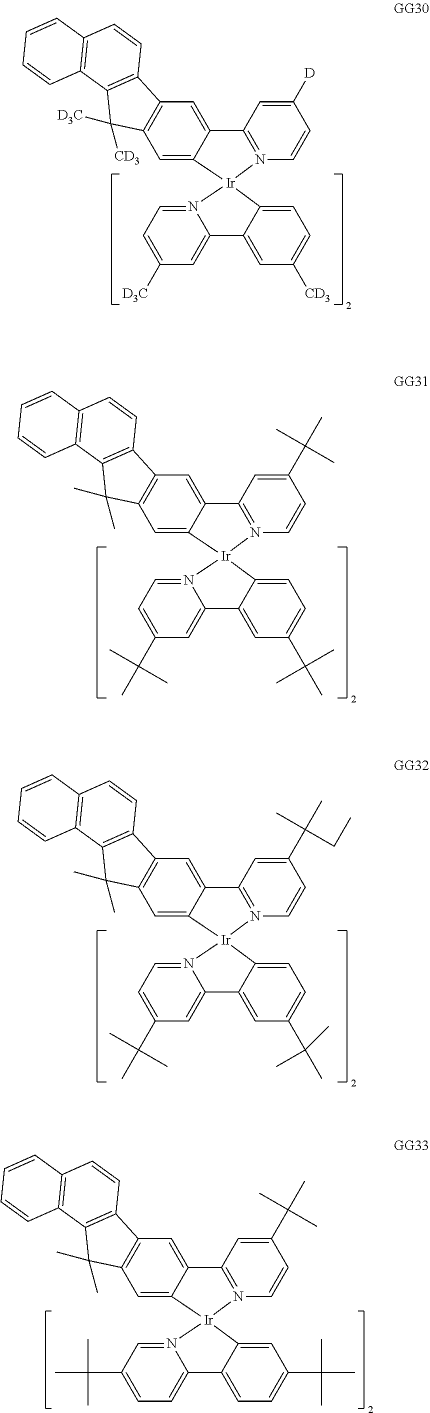

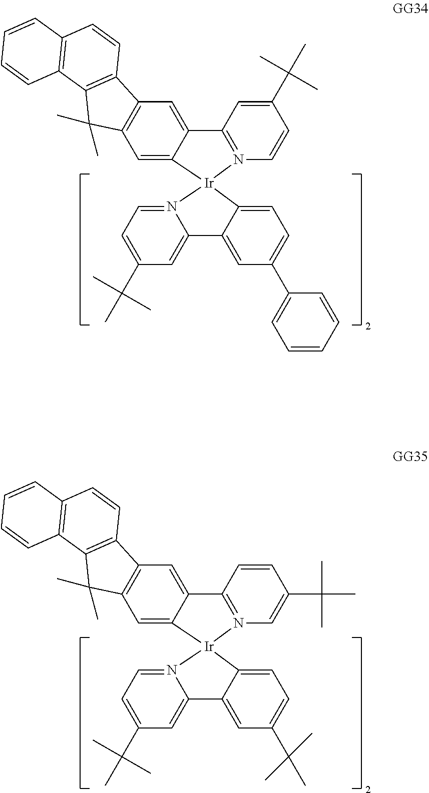

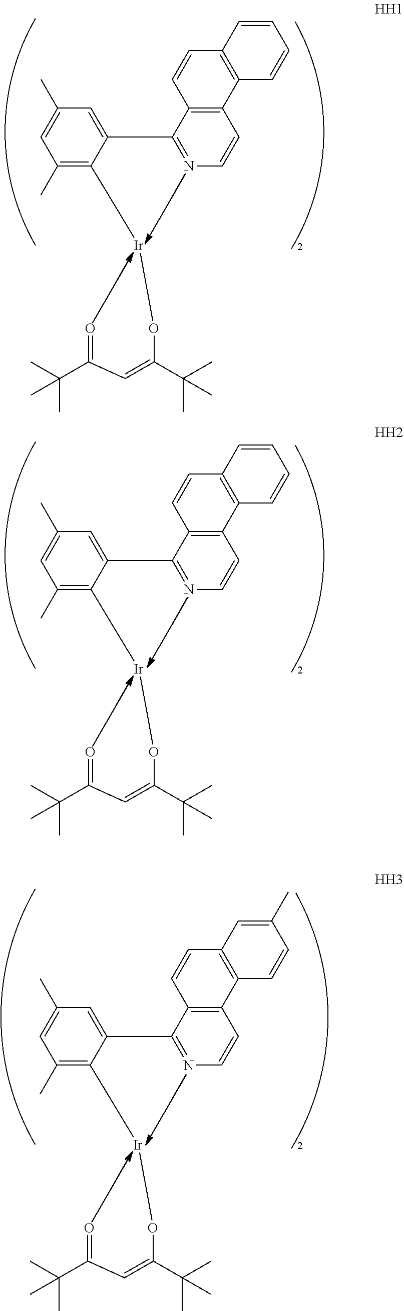

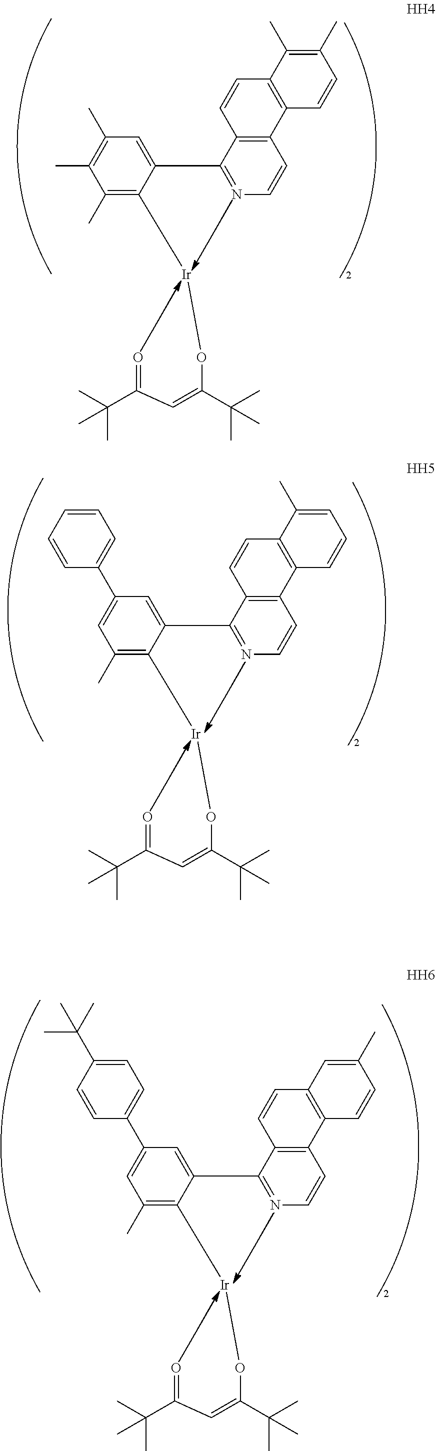

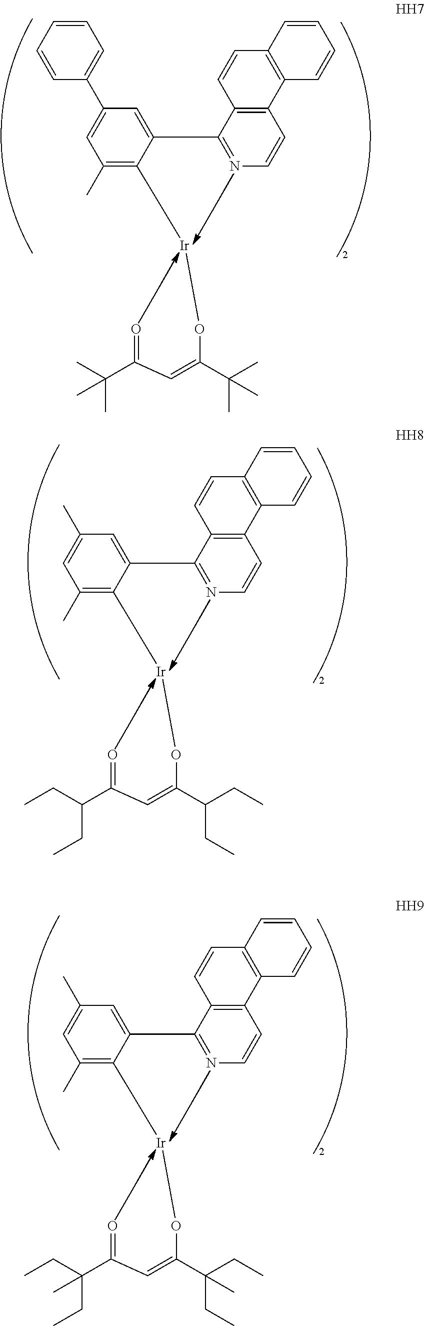

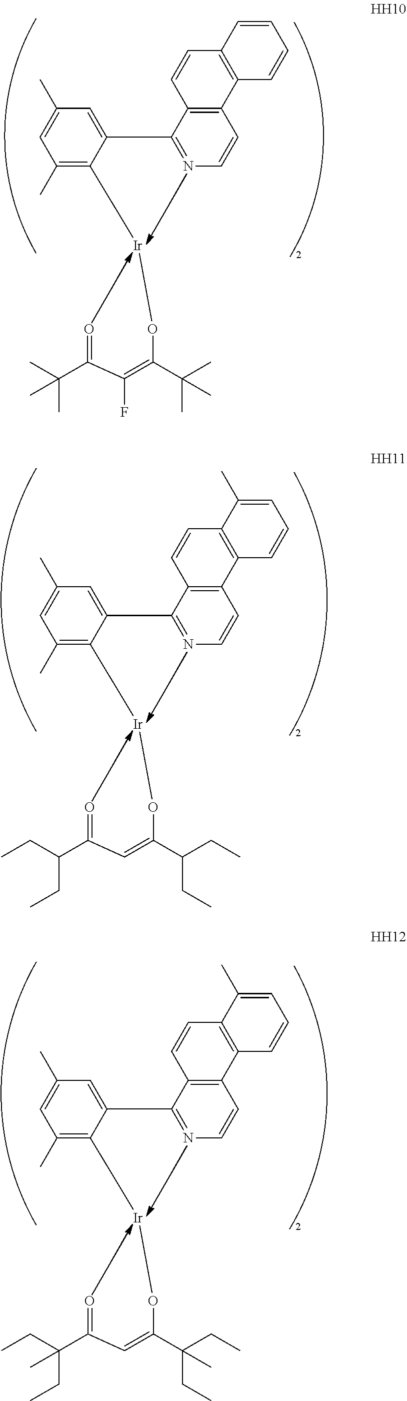

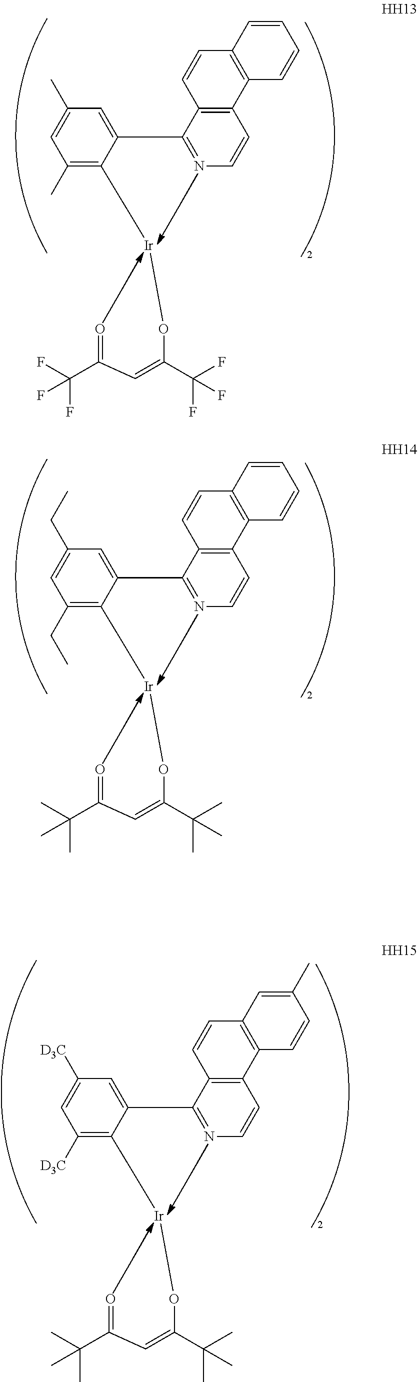

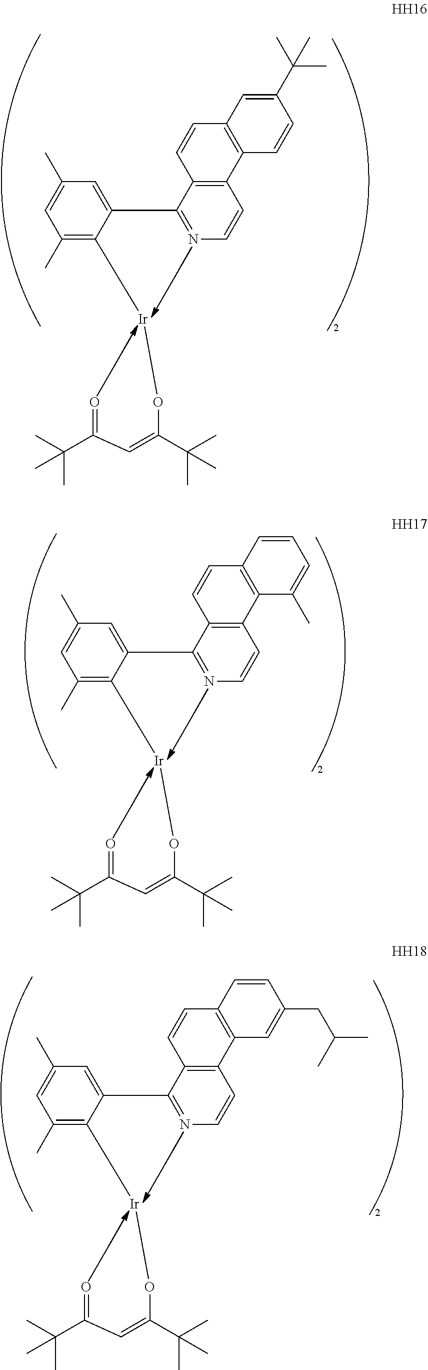

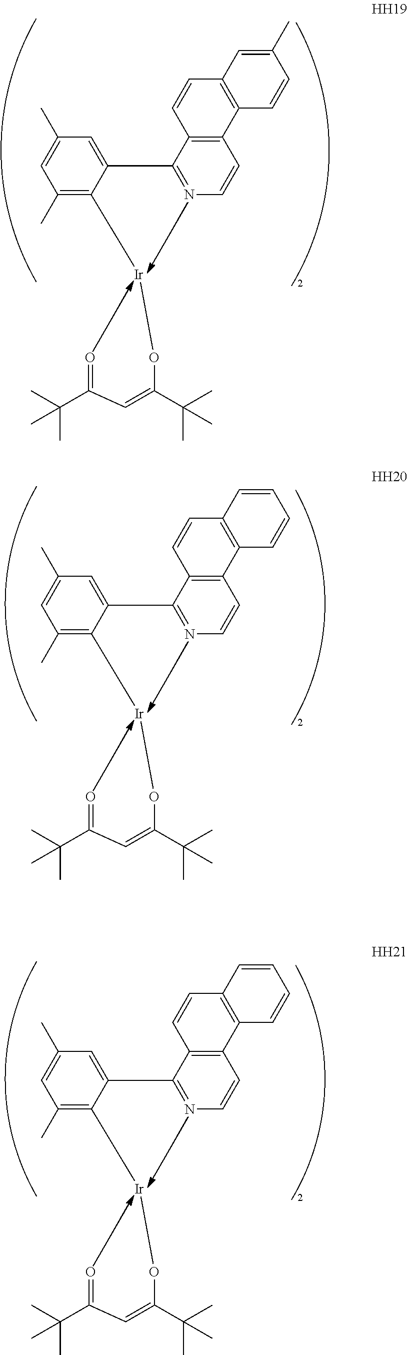

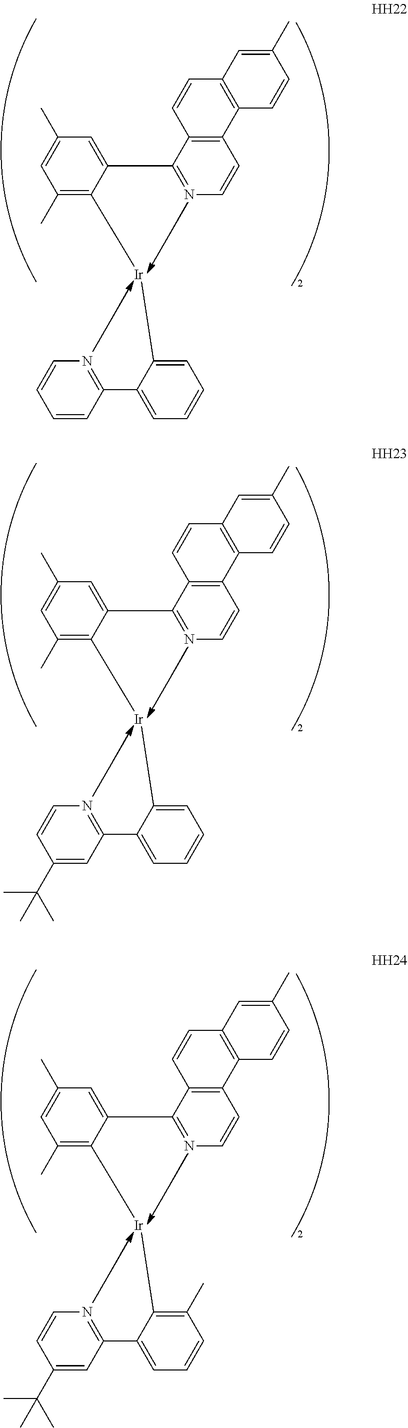

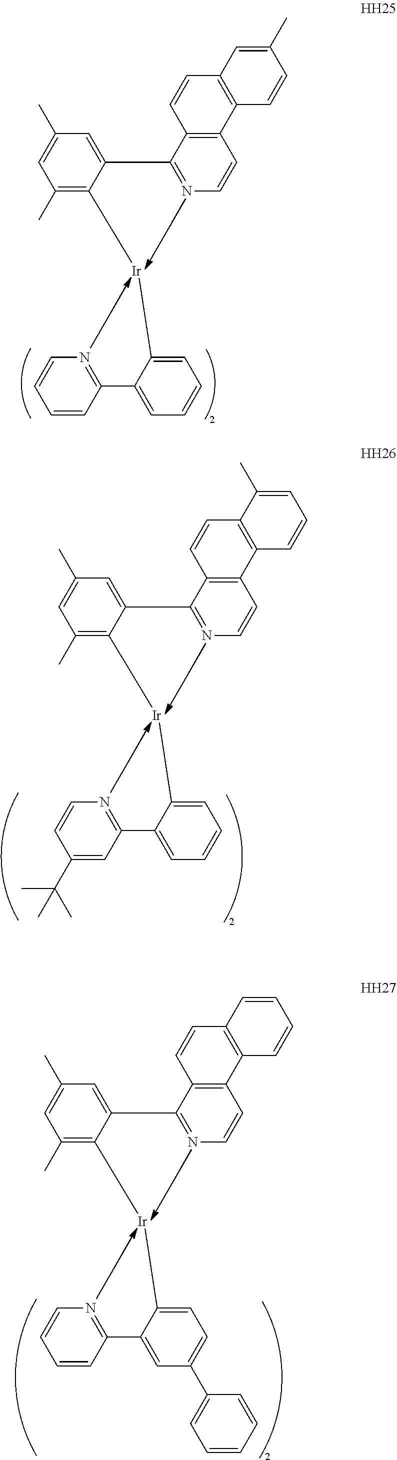

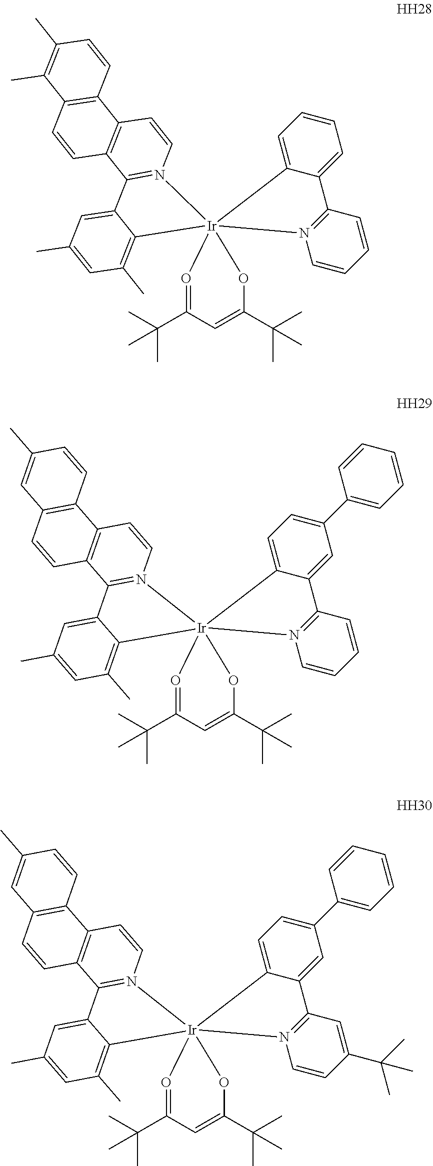

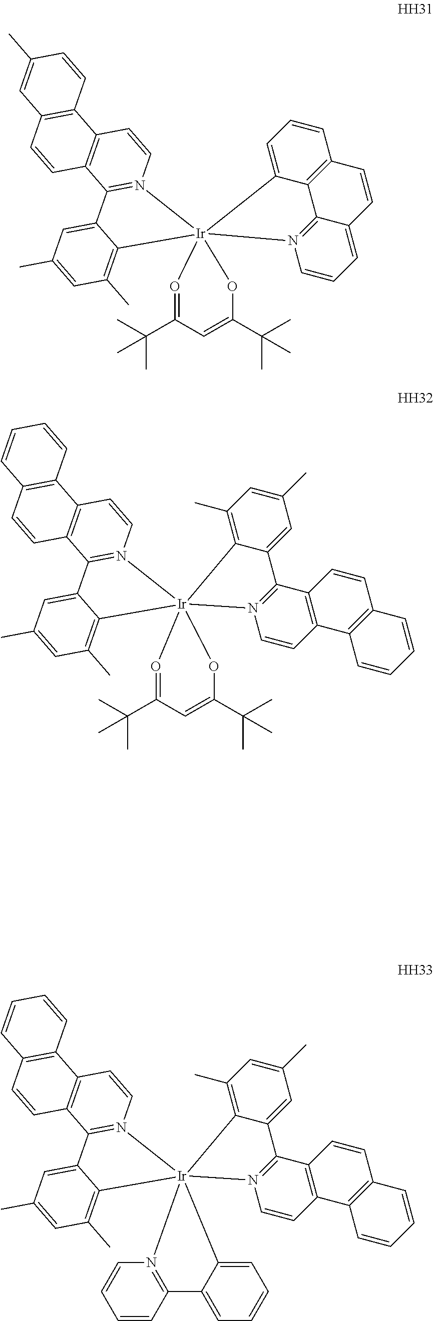

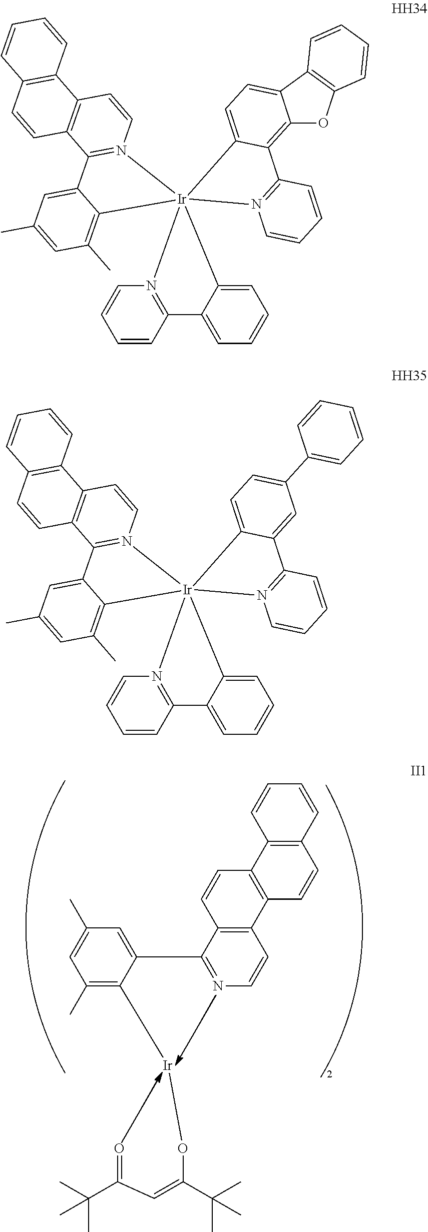

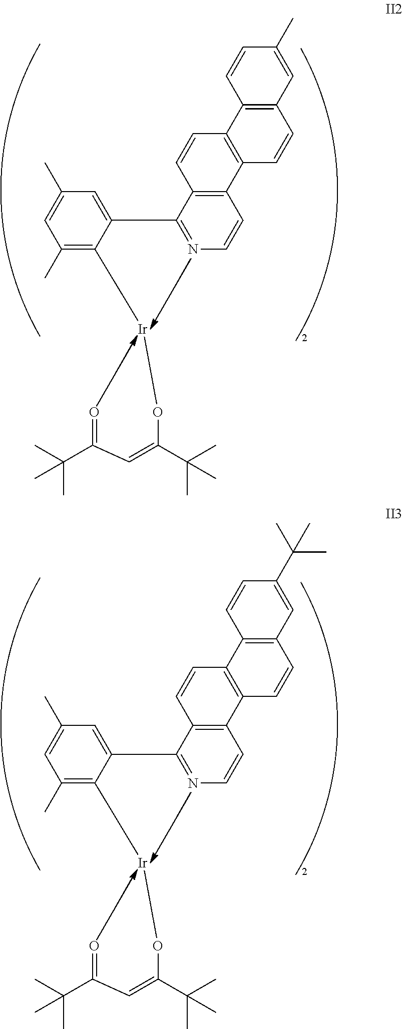

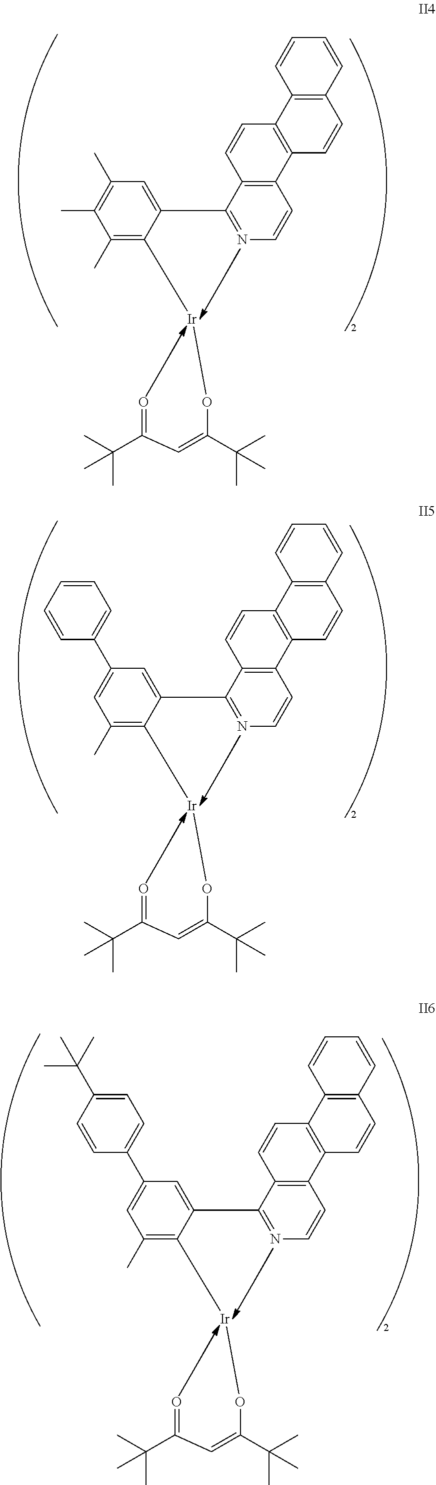

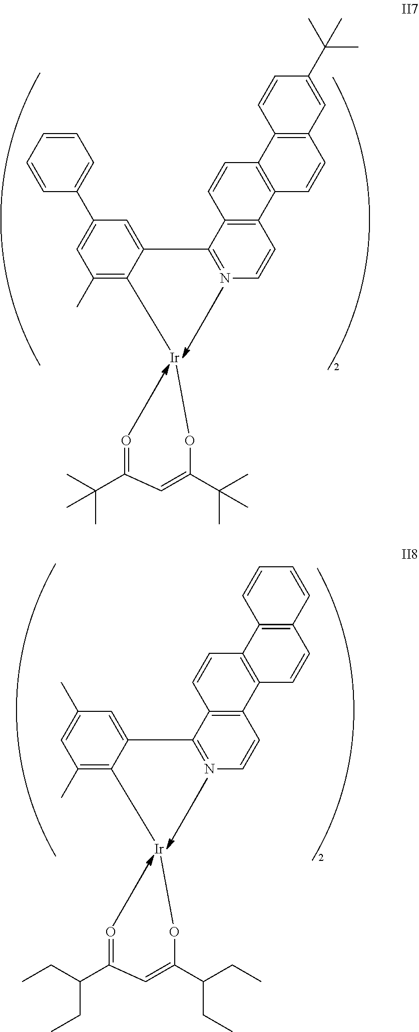

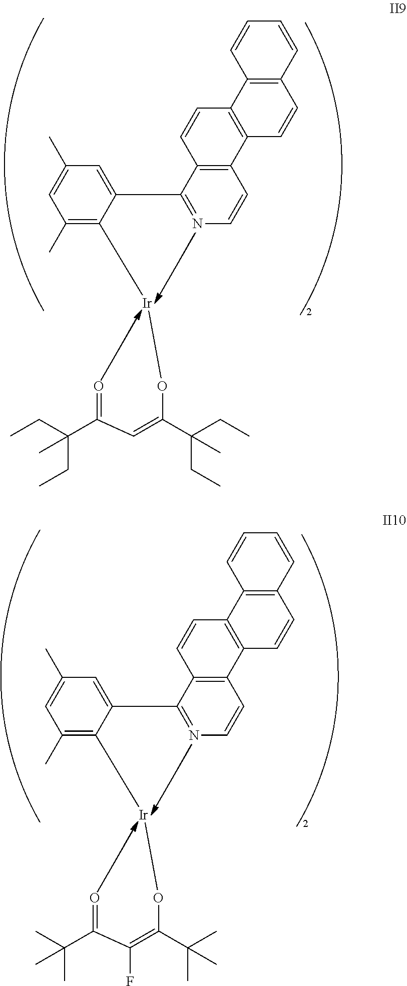

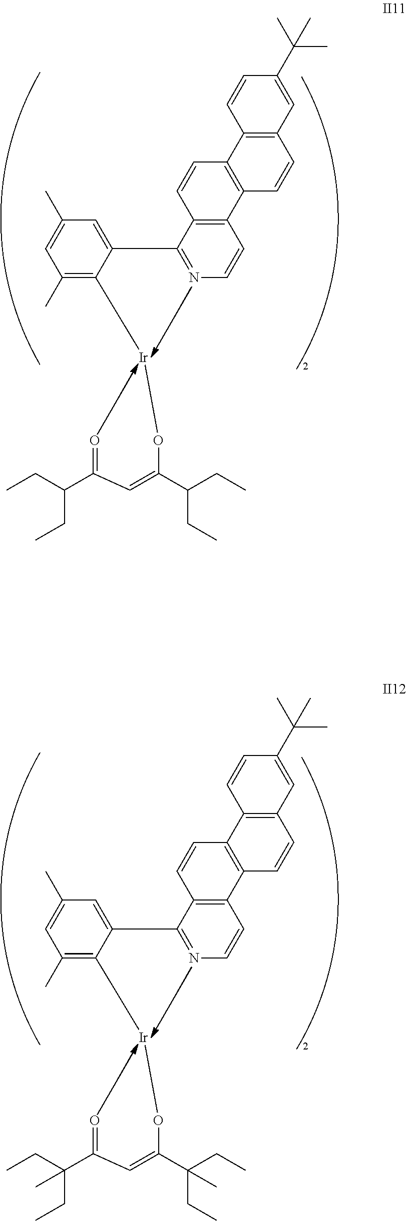

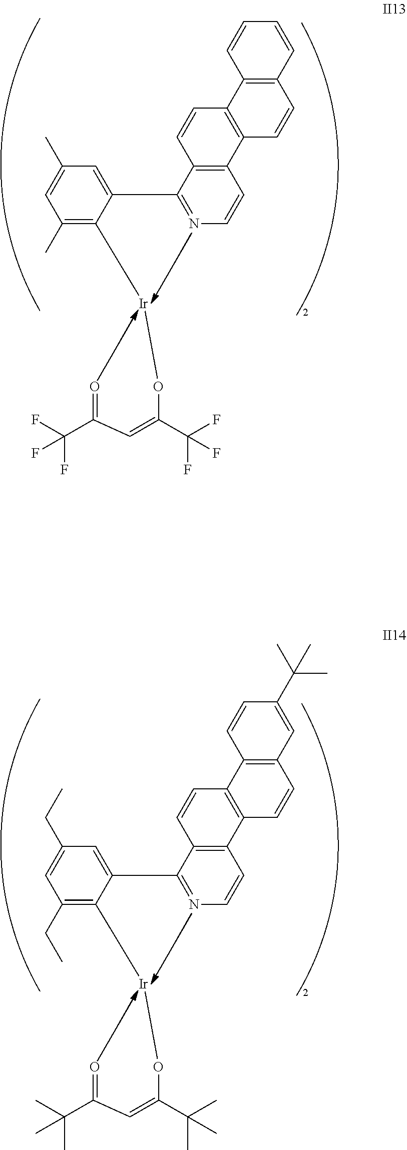

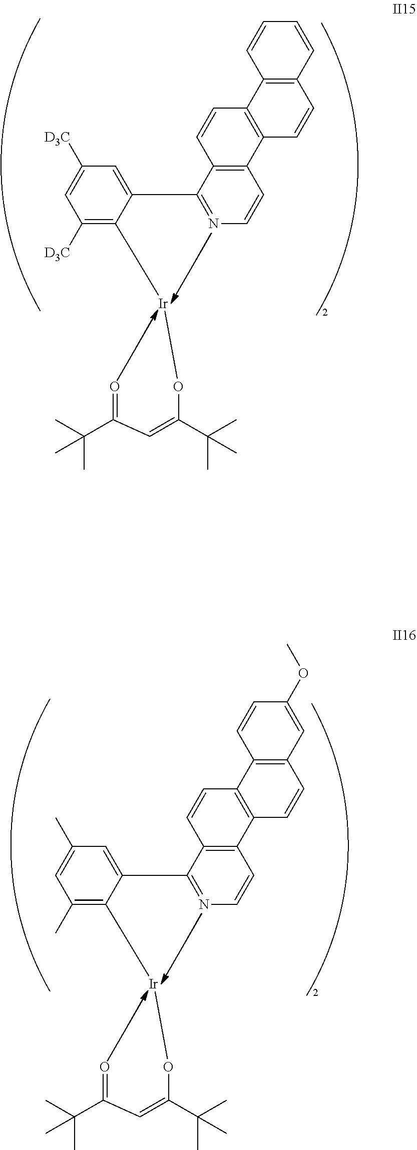

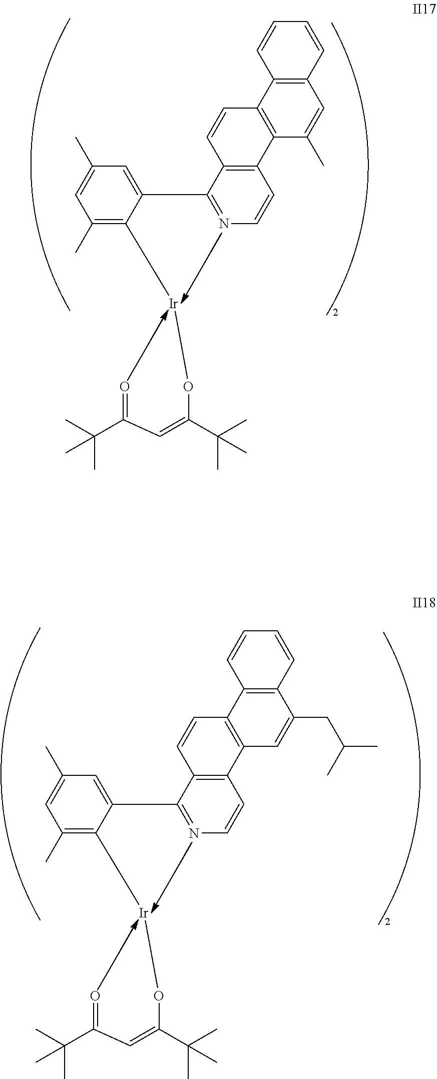

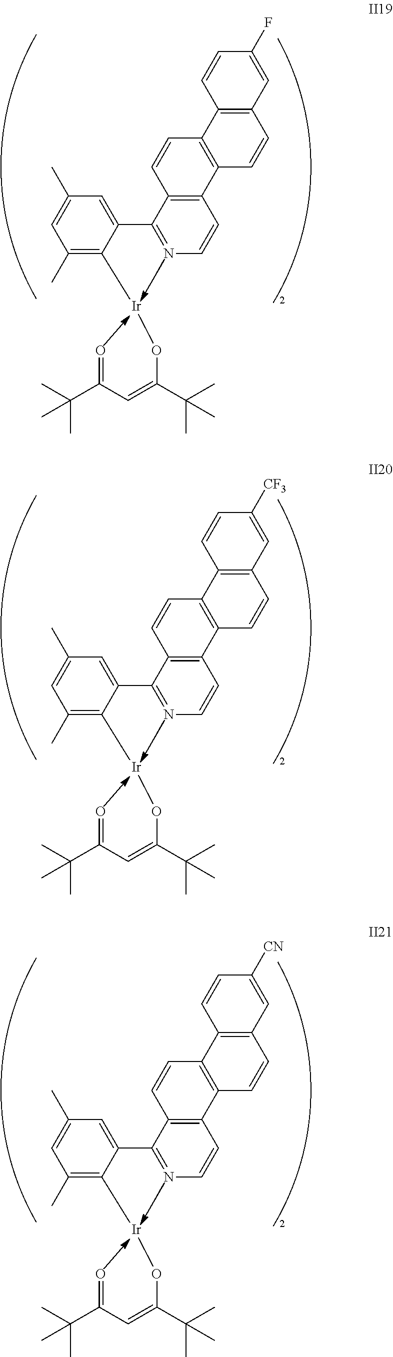

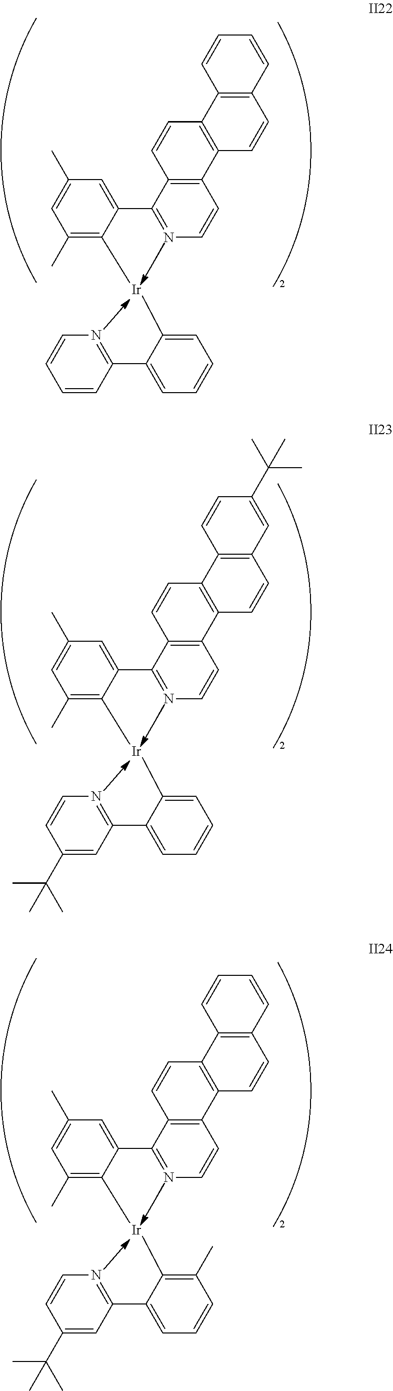

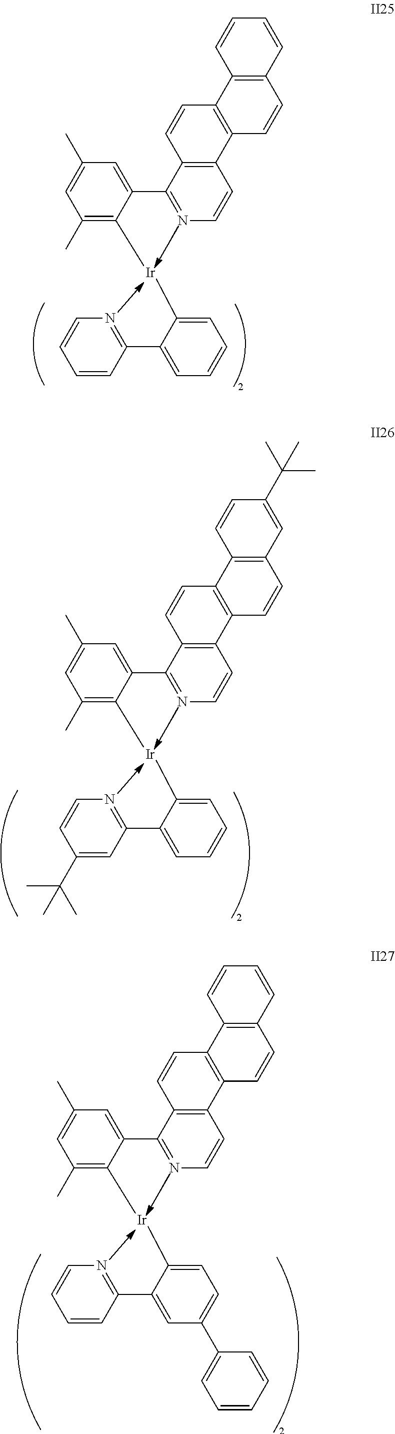

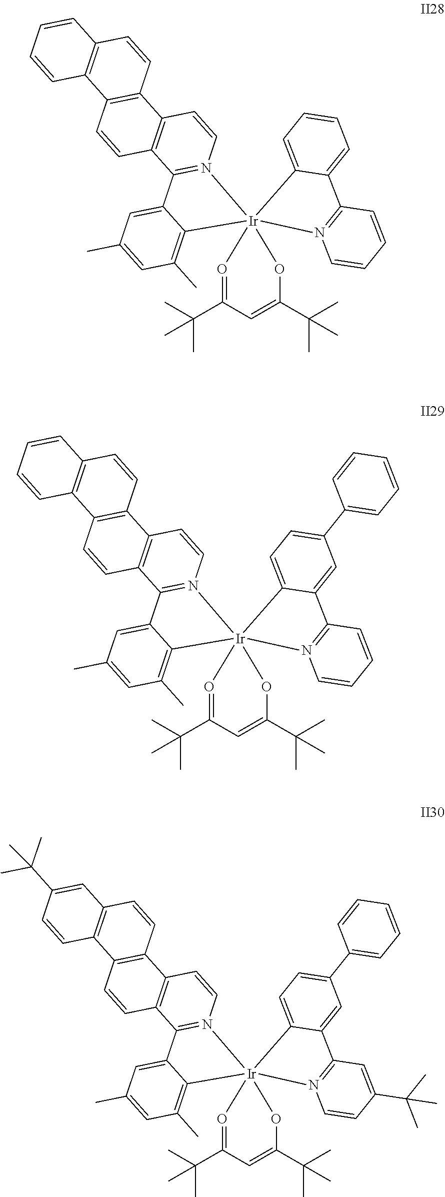

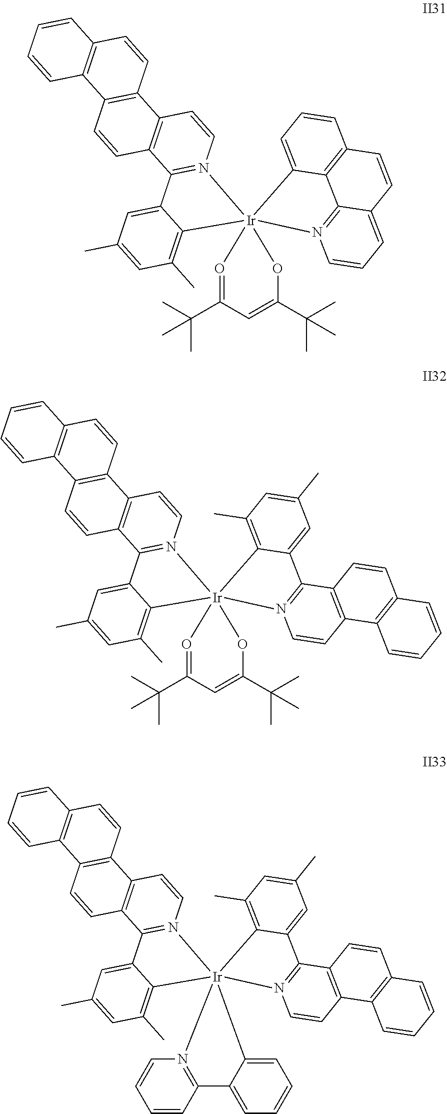

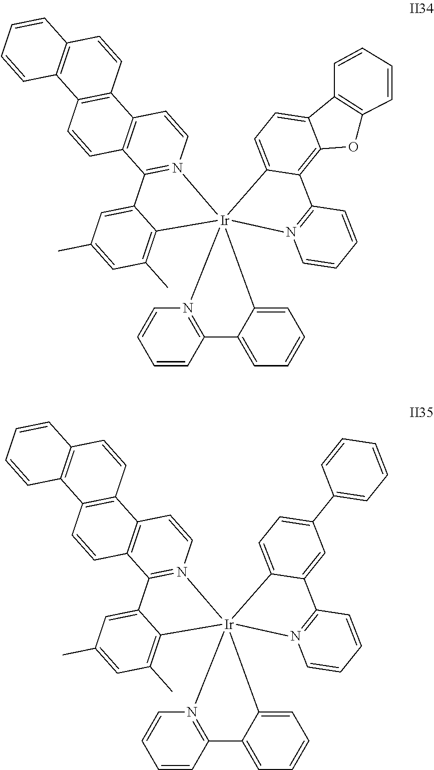

The exemplary compounds belonging to the group AA are organometallic complexes in which the substructure M(L)ₘ is represented by the general formula (Ir-4), and are compounds with at least a triphenylene ring in the ligand. These compounds are particularly stable because the fused rings are composed of an sp² hybrid orbital.

The exemplary compounds belonging to the groups BB and CC are organometallic complexes in which the substructure M(L)ₘ is represented by the general formula (Ir-3), and are compounds with at least a phenanthrene ring in the ligand. These compounds are particularly stable because the fused rings are composed of an sp² hybrid orbital.

The exemplary compounds belonging to the group DD are organometallic complexes in which the substructure M(L)ₘ is represented by one of the general formulae (Ir-5) to (Ir-8), and are compounds with at least a dibenzofuran ring, a dibenzothiophene ring, a benzonaphthofuran ring, or a benzonaphthothiophene ring in the ligand. These compounds contain an oxygen atom or a sulfur atom in the fused ring. Abundant lone pairs in these atoms can enhance charge transport properties and make it particularly easy to adjust the carrier balance of the compounds.

The exemplary compounds belonging to the groups EE to GG are organometallic complexes in which the substructure M(L)ₘ is represented by one of the general formulae (Ir-6) to (Ir-8), and are compounds with at least a benzofluorene ring in the ligand. These compounds have a substituent at position 9 of the fluorene ring in the direction perpendicular to the in-plane direction of the fluorene ring and can therefore particularly reduce the overlap between fused rings. Thus, the compounds have particularly high sublimability.

The exemplary compounds belonging to the group HH are organometallic complexes in which the substructure M(L)ₘ is represented by one of the general formulae (Ir-11) to (Ir-13), and are compounds with at least a benzoisoquinoline ring in the ligand. These compounds contain a N atom in a fused ring, and lone pairs and high electronegativity of the N atom can enhance charge transport properties and make it particularly easy to adjust the carrier balance of the compounds.

The exemplary compounds belonging to the group II are organometallic complexes in which the substructure M(L)ₘ is represented by the general formula (Ir-14), and are compounds with at least a naphthoisoquinoline ring in the ligand. These compounds contain a N atom in a fused ring, and lone pairs and high electronegativity of the N atom can enhance charge transport properties and make it particularly easy to adjust the carrier balance of the compounds.

### (4) Other Compounds

If necessary, an organic light-emitting element according to the present disclosure may be used in combination with a known low-molecular-weight or high-molecular-weight hole injection compound or hole transport compound, light-emitting compound, electron injection compound, electron transport compound, or the like. Examples of these compounds are described below.

The hole injection/transport material can be a material with high hole mobility to facilitate the injection of a hole from a positive electrode and to transport the injected hole to a light-emitting layer. Furthermore, a material with a high glass transition temperature (Tg) can be used to reduce degradation of film quality, such as crystallization, in an organic light-emitting element. Examples of a low-molecular-weight or high-molecular-weight material with hole injection/transport ability include, but are not limited to, a triarylamine derivative, an aryl carbazole derivative, a phenylenediamine derivative, a stilbene derivative, a phthalocyanine derivative, a porphyrin derivative, polyvinylcarbazole, polythiophene, and another electrically conductive polymer. Furthermore, the hole injection/transport material is also suitable for use in an electron-blocking layer. Specific examples of a compound that can be used as the hole injection/transport material include, but are not limited to, the following.

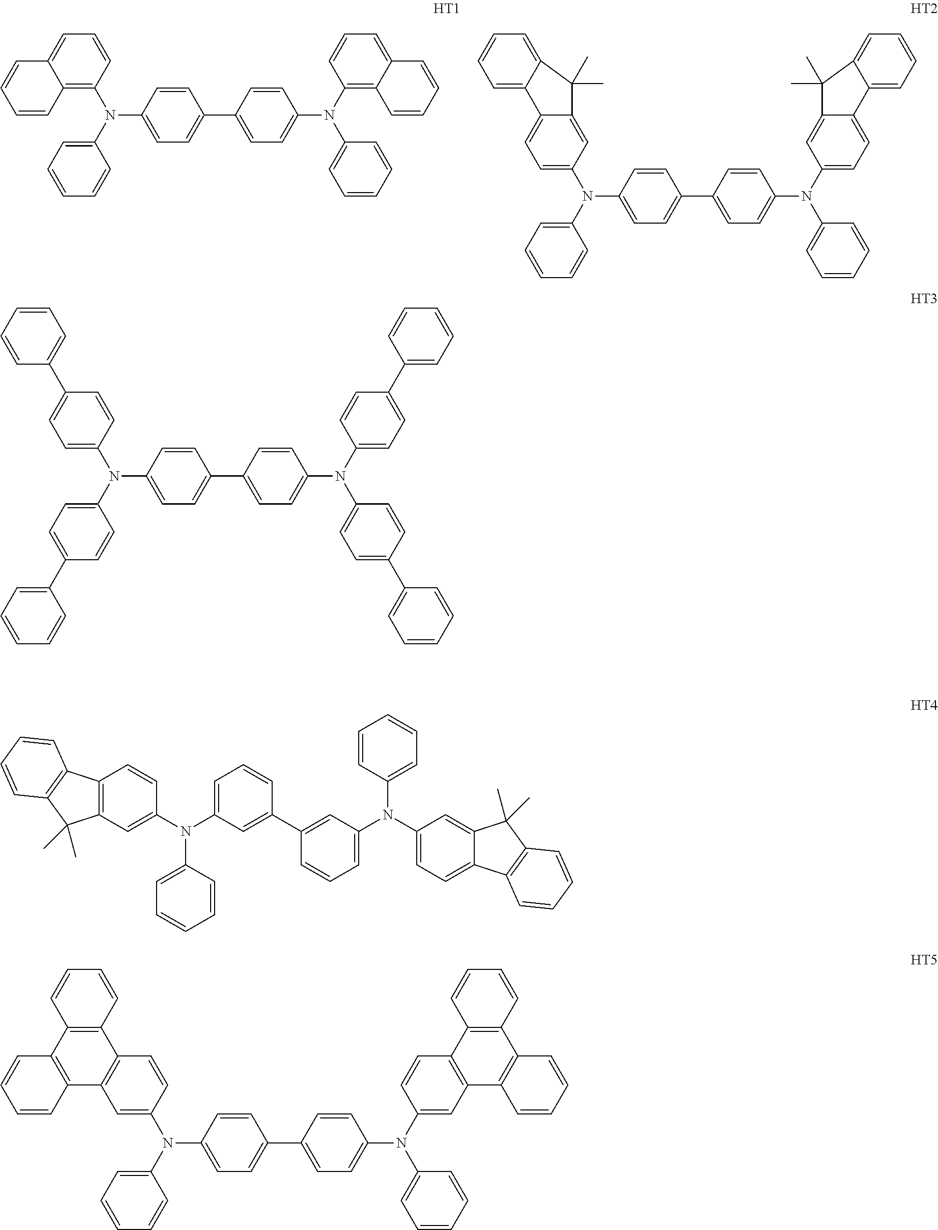 [SMILES: c1ccc(N(c2ccc(-c3ccc(N(c4ccccc4)c4cccc5ccccc45)cc3)cc2)c2cccc3ccccc23)cc1 ; CC1(C)c2ccccc2-c2ccc(N(c3ccccc3)c3ccc(-c4ccc(N(c5ccccc5)c5ccc6c(c5)C(C)(C)c5ccccc5-6)cc4)cc3)cc21 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; CC1(C)c2ccccc2-c2ccc(N(c3ccccc3)c3cccc(-c4cccc(N(c5ccccc5)c5ccc6c(c5)C(C)(C)c5ccccc5-6)c4)c3)cc21 ; c1ccc(N(c2ccc(-c3ccc(N(c4ccccc4)c4ccc5c6ccccc6c6ccccc6c5c4)cc3)cc2)c2ccc3c4ccccc4c4ccccc4c3c2)cc1]

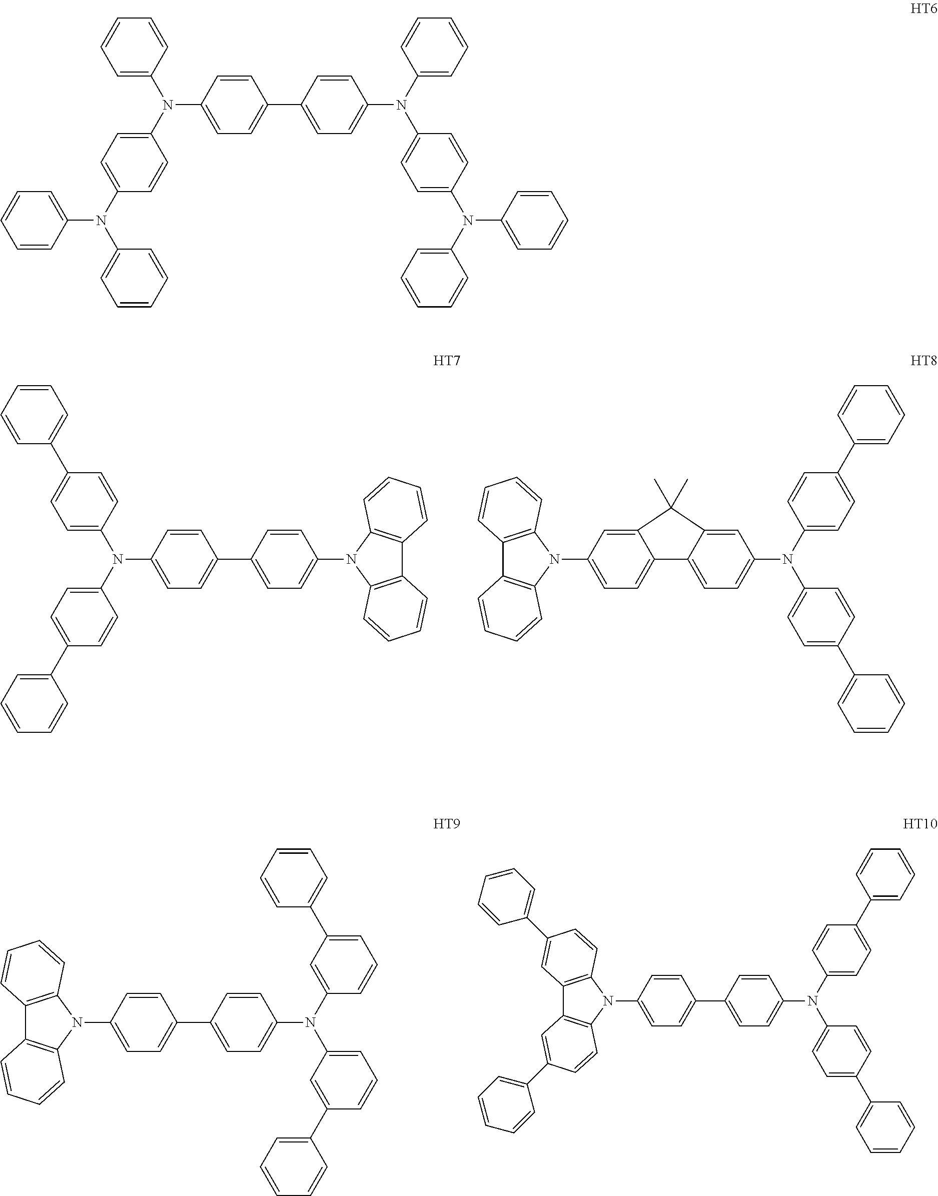 [SMILES: c1ccc(N(c2ccccc2)c2ccc(N(c3ccccc3)c3ccc(-c4ccc(N(c5ccccc5)c5ccc(N(c6ccccc6)c6ccccc6)cc5)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccc(-c4ccccc4)cc3)c3ccc(-c4ccccc4)cc3)ccc2-c2ccc(-n3c4ccccc4c4ccccc43)cc21 ; c1ccc(-c2cccc(N(c3ccc(-c4ccc(-n5c6ccccc6c6ccccc65)cc4)cc3)c3cccc(-c4ccccc4)c3)c2)cc1 ; c1ccc(-c2ccc(N(c3ccc(-c4ccccc4)cc3)c3ccc(-c4ccc(-n5c6ccc(-c7ccccc7)cc6c6cc(-c7ccccc7)ccc65)cc4)cc3)cc2)cc1]

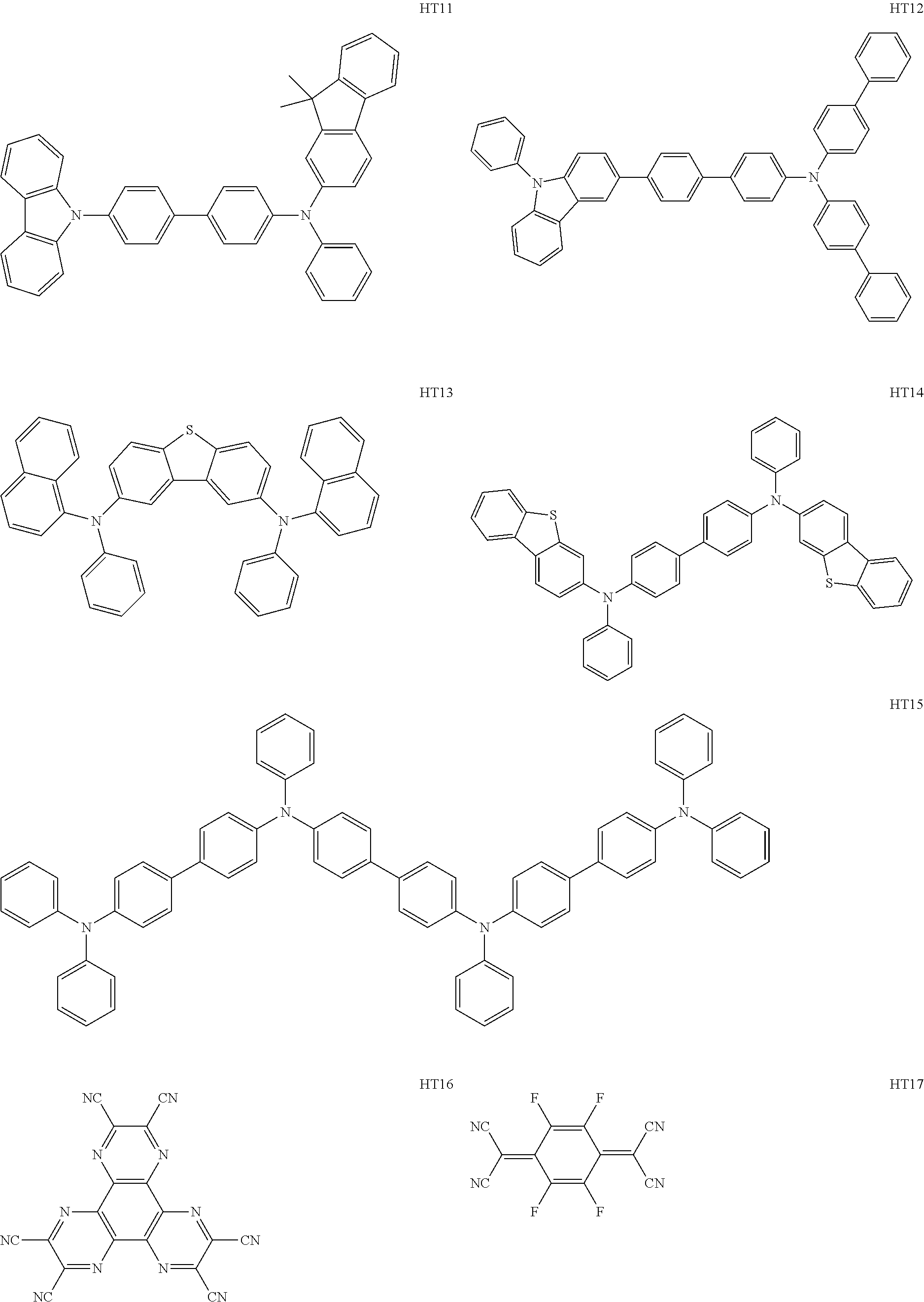

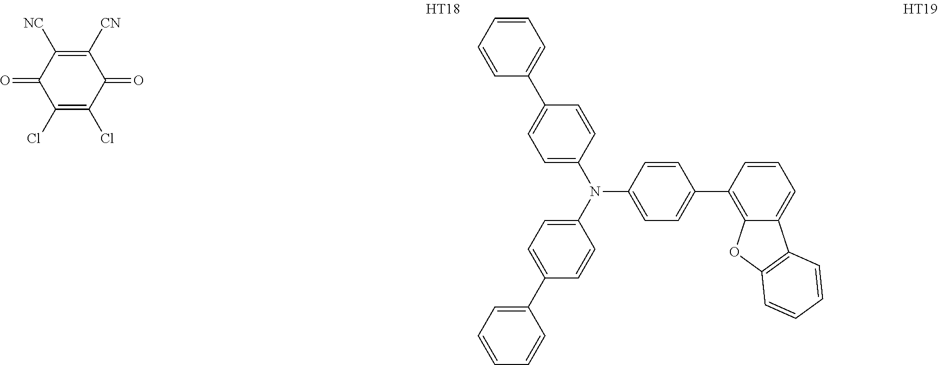 [SMILES: N#CC1=C(C#N)C(=O)C(Cl)=C(Cl)C1=O ; c1ccc(-c2ccc(N(c3ccc(-c4ccccc4)cc3)c3ccc(-c4cccc5c4oc4ccccc45)cc3)cc2)cc1]

A light-emitting layer of an organic light-emitting element according to the present disclosure may contain a guest molecule in addition to an organic compound represented by the general formula (1). A guest molecule mainly related to the light-emitting function may be a fused-ring compound (for example, a fluorene derivative, a naphthalene derivative, a pyrene derivative, a perylene derivative, a tetracene derivative, an anthracene derivative, rubrene, or the like), a quinacridone derivative, a coumarin derivative, a stilbene derivative, an organoaluminum complex, such as tris(8-quinolinolato)aluminum, an iridium complex, a platinum complex, a rhenium complex, a copper complex, an europium complex, a ruthenium complex, or a polymer derivative, such as a poly(phenylene vinylene) derivative, a polyfluorene derivative, or a polyphenylene derivative. Specific examples of a compound that can be used as a light-emitting material include, but are not limited to, the following.

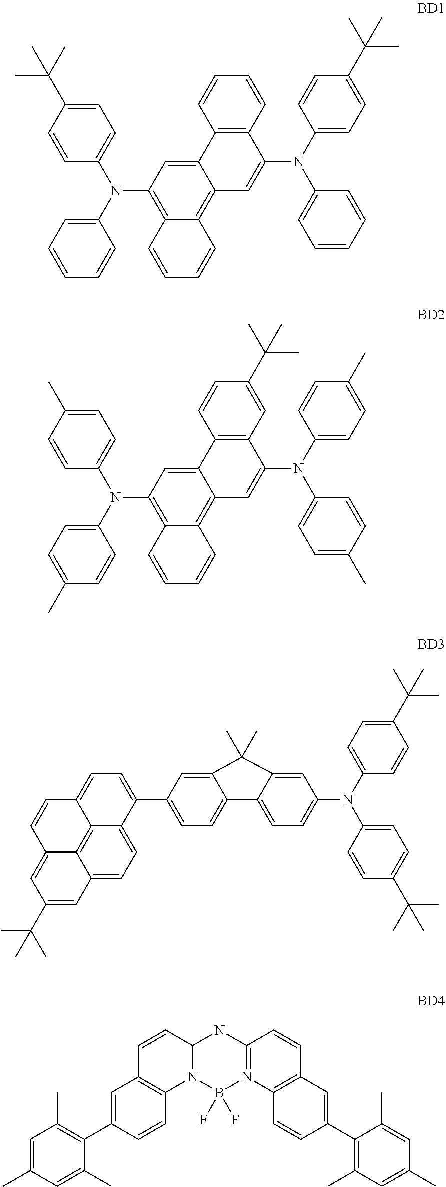

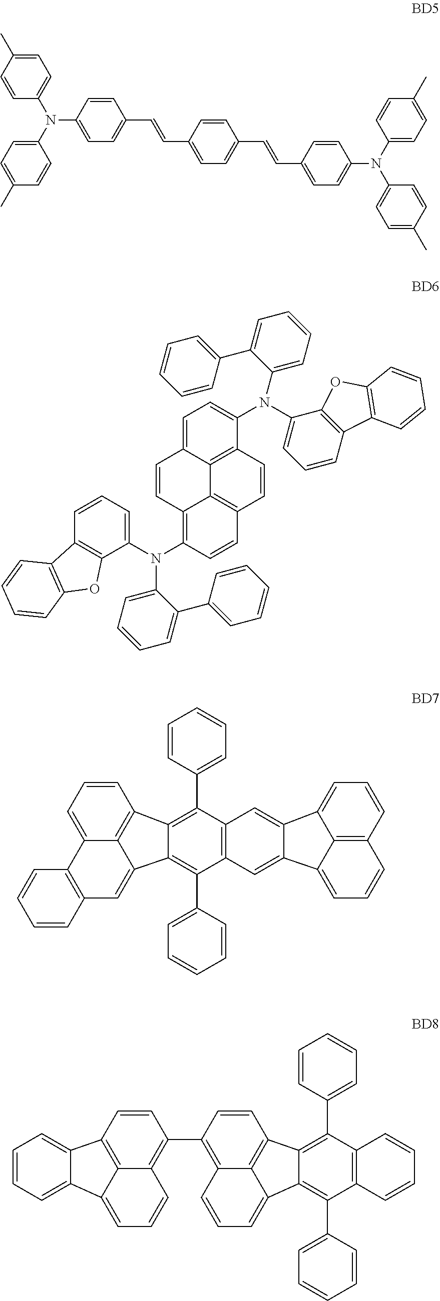

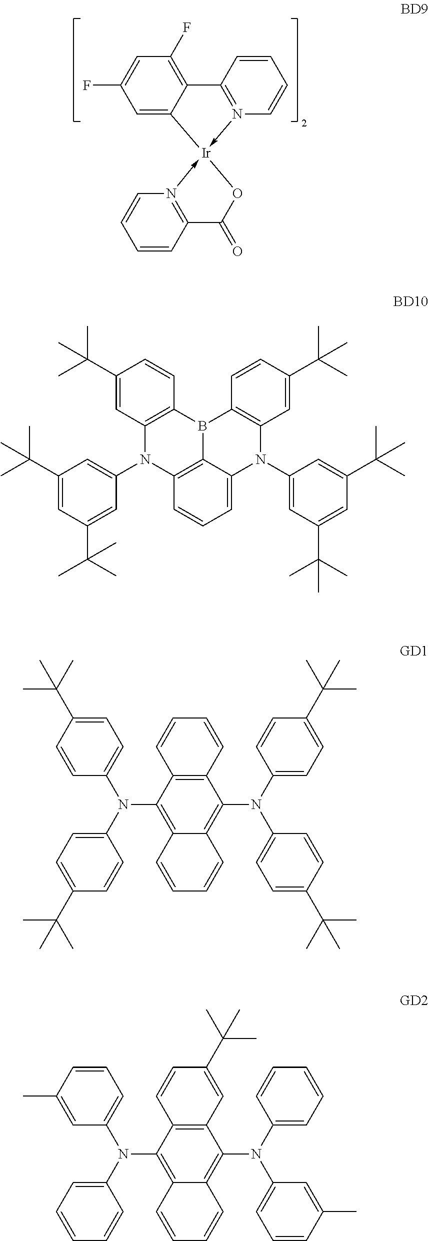

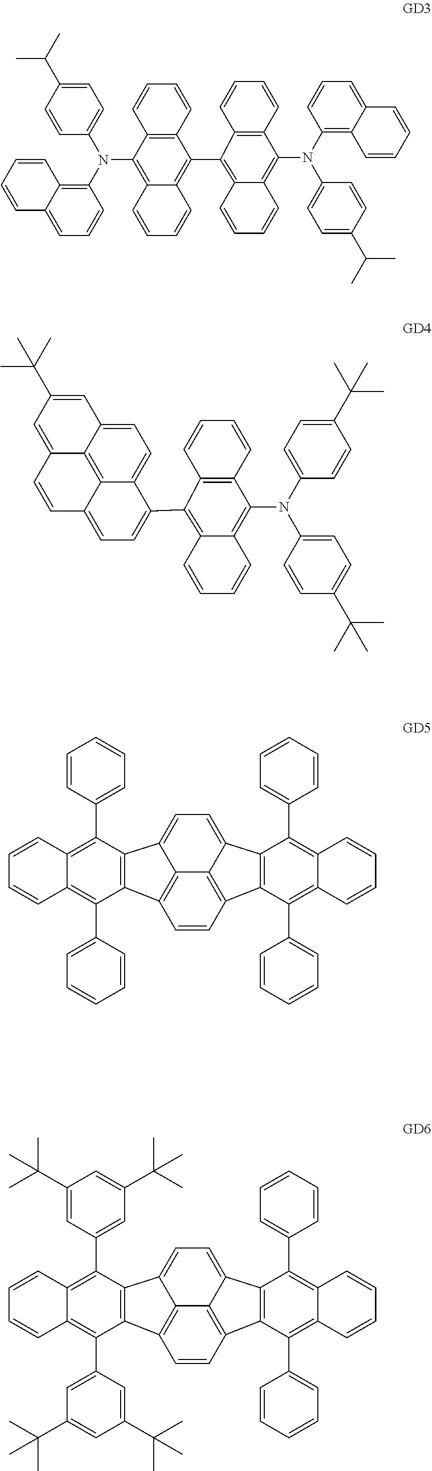

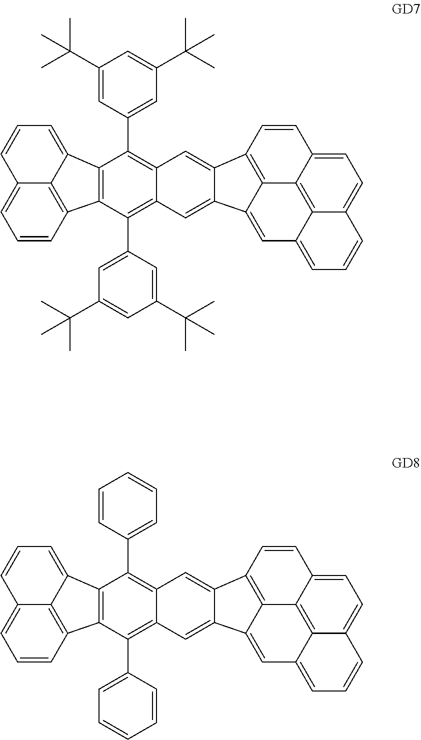

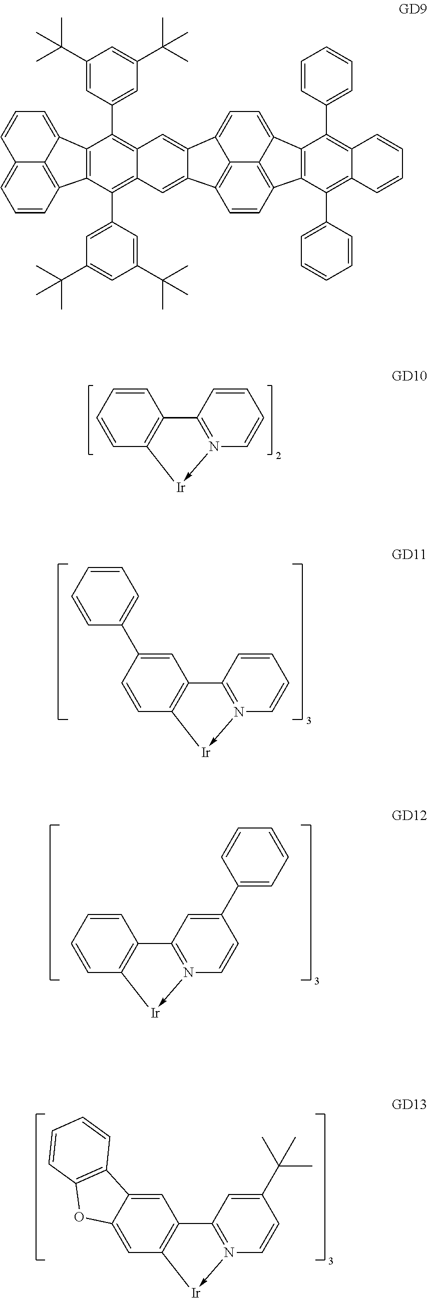

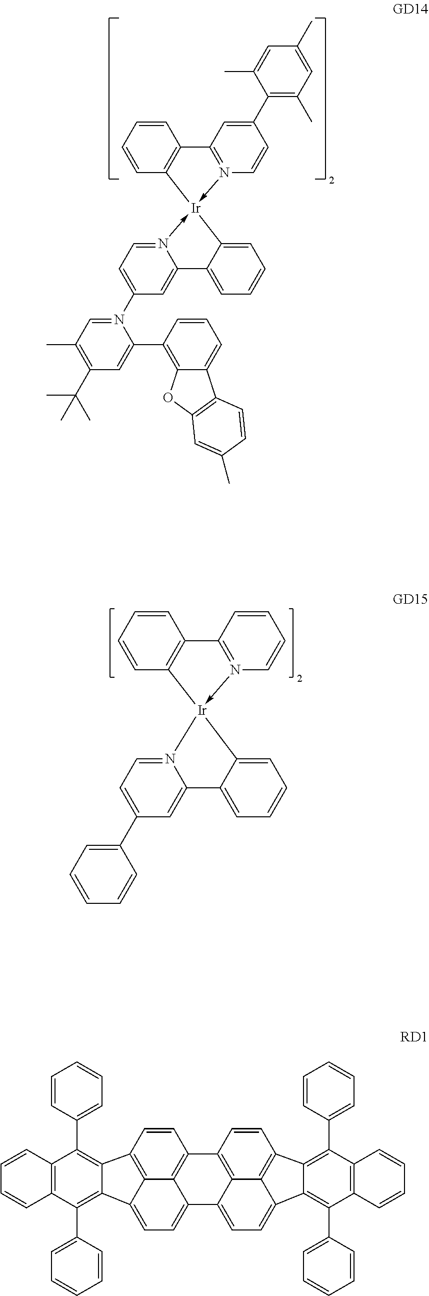

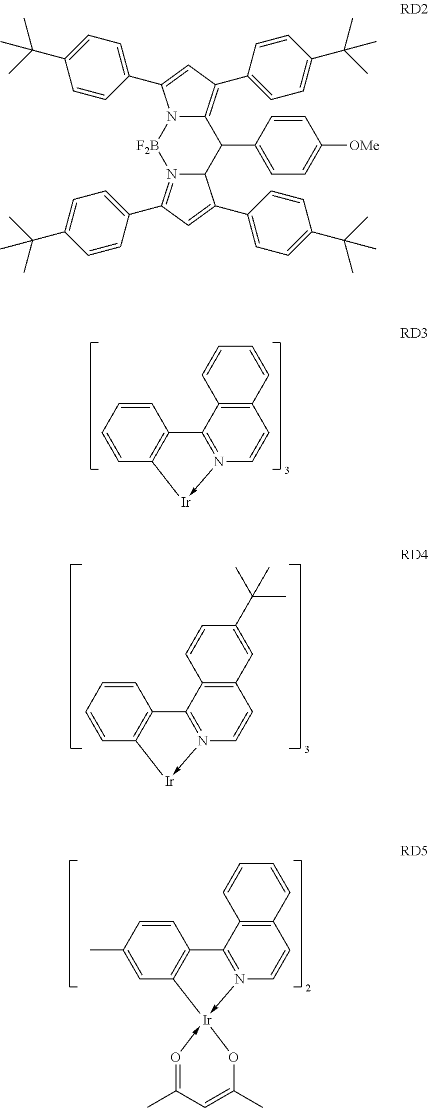

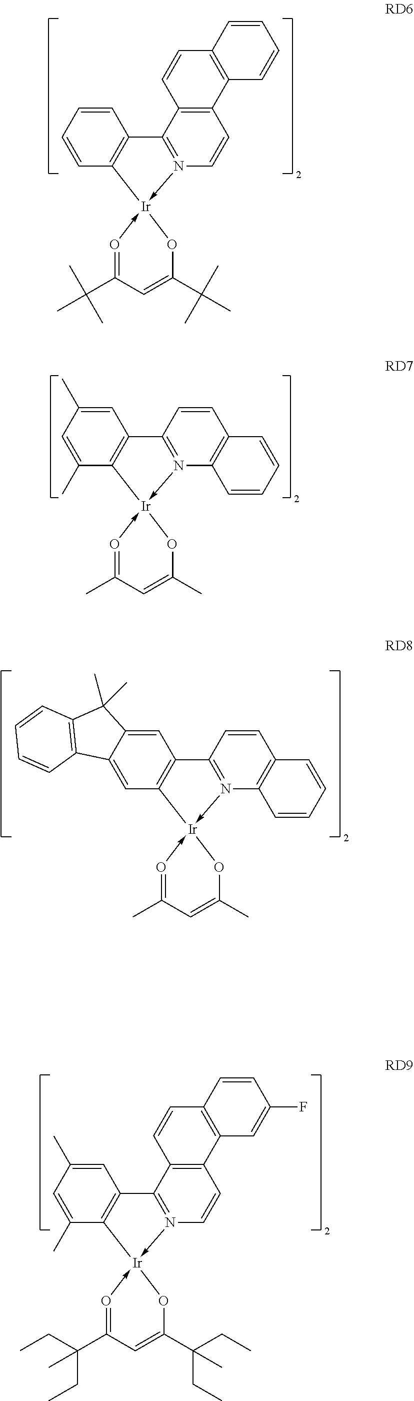

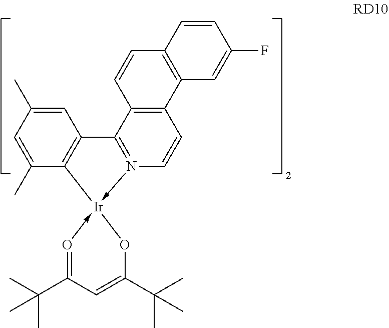

An electron transport material can be selected from materials that can transport an electron injected from a negative electrode to a light-emitting layer and is selected in consideration of the balance with the hole mobility of a hole transport material and the like. A material with electron transport ability may be an oxadiazole derivative, an oxazole derivative, a pyrazine derivative, a triazole derivative, a triazine derivative, a quinoline derivative, a quinoxaline derivative, a phenanthroline derivative, an organoaluminum complex, and a fused-ring compound (for example, a fluorene derivative, a naphthalene derivative, a chrysene derivative, an anthracene derivative, or the like). Furthermore, the electron transport material is also suitable for use in a hole-blocking layer. Specific examples of a compound that can be used as the electron transport material include, but are not limited to, the following.

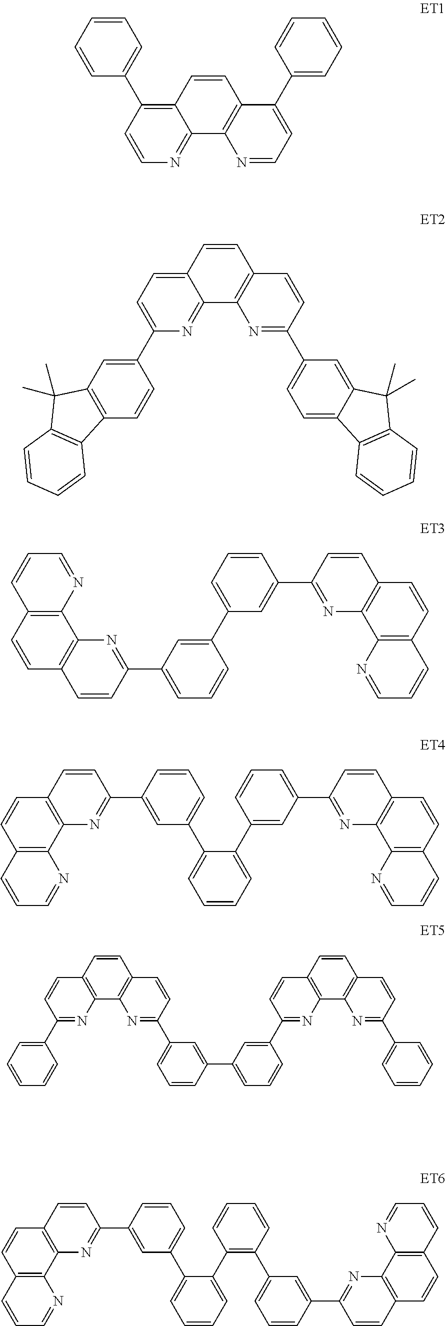 [SMILES: c1ccc(-c2ccnc3c2ccc2c(-c4ccccc4)ccnc23)cc1 ; CC1(C)c2ccccc2-c2ccc(-c3ccc4ccc5ccc(-c6ccc7c(c6)C(C)(C)c6ccccc6-7)nc5c4n3)cc21 ; c1cc(-c2cccc(-c3ccc4ccc5cccnc5c4n3)c2)cc(-c2ccc3ccc4cccnc4c3n2)c1 ; c1cc(-c2ccc3ccc4cccnc4c3n2)cc(-c2ccccc2-c2cccc(-c3ccc4ccc5cccnc5c4n3)c2)c1 ; c1ccc(-c2ccc3ccc4ccc(-c5cccc(-c6cccc(-c7ccc8ccc9ccc(-c%10ccccc%10)nc9c8n7)c6)c5)nc4c3n2)cc1 ; c1cc(-c2ccc3ccc4cccnc4c3n2)cc(-c2ccccc2-c2ccccc2-c2cccc(-c3ccc4ccc5cccnc5c4n3)c2)c1]

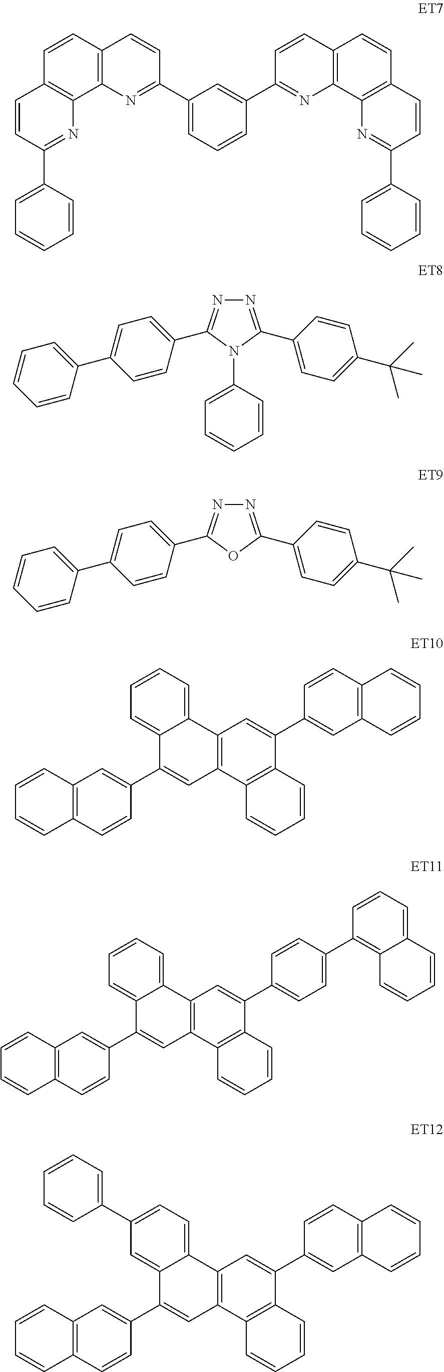

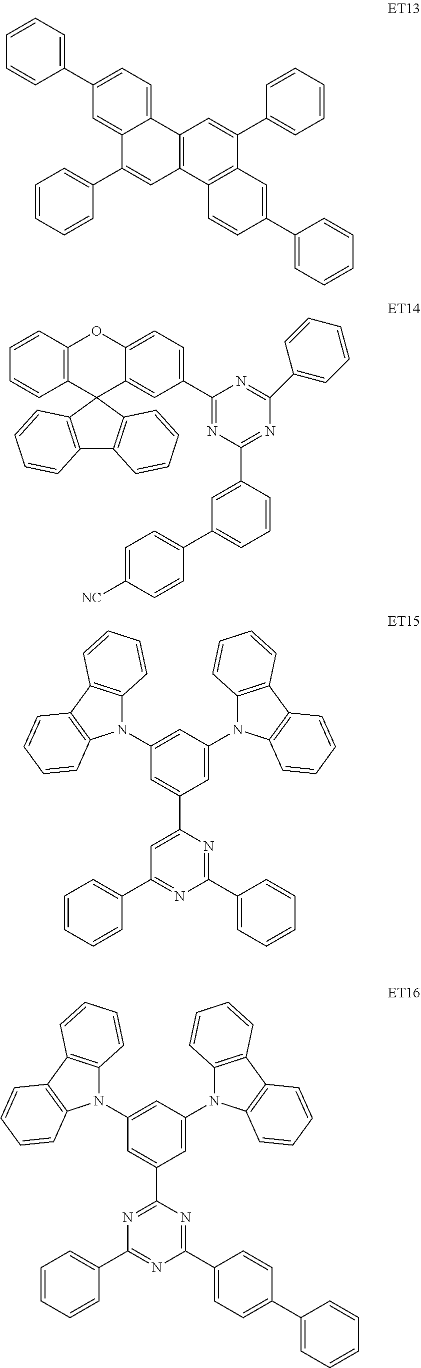

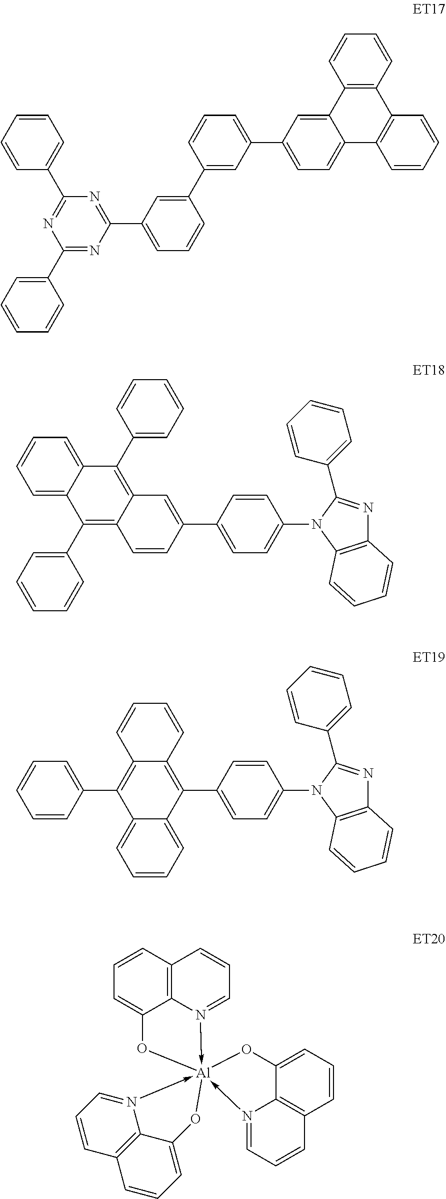

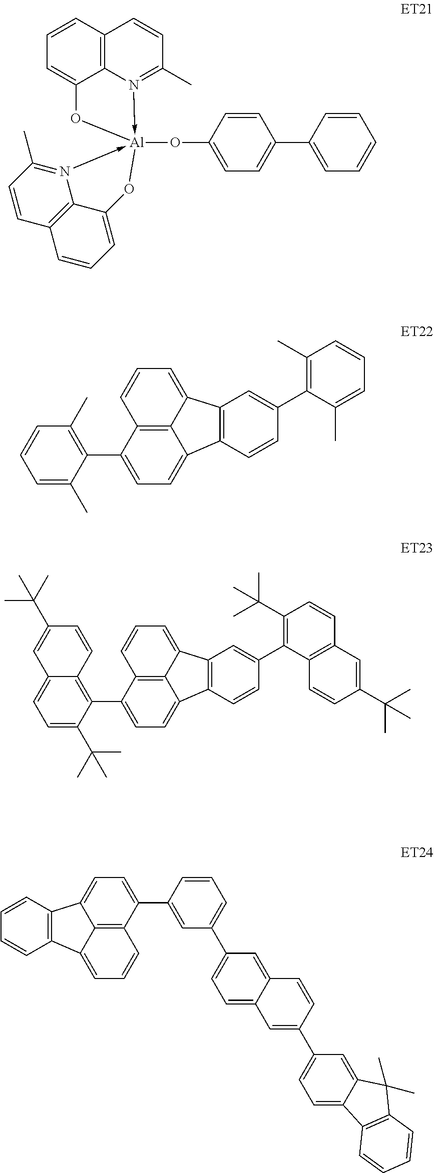

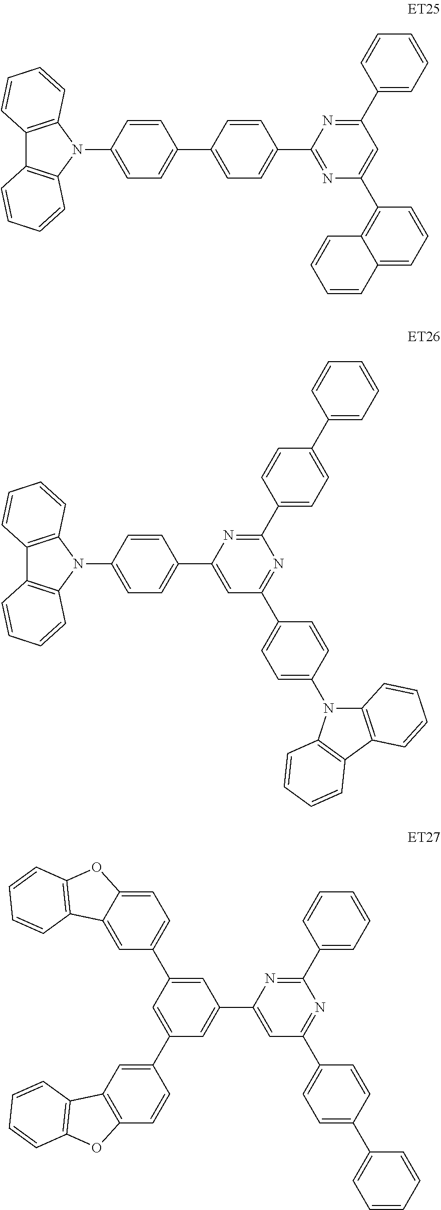 [SMILES: c1ccc(-c2cc(-c3cccc4ccccc34)nc(-c3ccc(-c4ccc(-n5c6ccccc6c6ccccc65)cc4)cc3)n2)cc1 ; c1ccc(-c2ccc(-c3nc(-c4ccc(-n5c6ccccc6c6ccccc65)cc4)cc(-c4ccc(-n5c6ccccc6c6ccccc65)cc4)n3)cc2)cc1 ; c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1]

### (5) Structure of Organic Light-Emitting Element

An organic light-emitting element includes an insulating layer, a first electrode, an organic compound layer, and a second electrode on a substrate. A protective layer, a color filter, a microlens, or the like may be provided on the second electrode. When a color filter is provided, a planarization layer may be provided between the color filter and the protective layer. The planarization layer may be composed of an acrylic resin or the like. The same applies to the planarization layer provided between the color filter and the microlens.

### [Substrate]

The substrate may be formed of quartz, glass, a silicon wafer, resin, metal, or the like. The substrate may have a switching element, such as a transistor, and wiring, on which an insulating layer may be provided. The insulating layer may be composed of any material, provided that the insulating layer can have a contact hole for wiring between the insulating layer and the first electrode and is insulated from unconnected wires. For example, the insulating layer may be formed of a resin, such as polyimide, silicon oxide, or silicon nitride.

### [Electrode]

A pair of electrodes can be used as electrodes. The pair of electrodes may be a positive electrode and a negative electrode. When an electric field is applied in a direction in which the organic light-emitting element emits light, an electrode with a high electric potential is a positive electrode, and the other electrode is a negative electrode. In other words, the electrode that supplies a hole to the light-emitting layer is a positive electrode, and the electrode that supplies an electron to the light-emitting layer is a negative electrode.

A constituent material of the positive electrode can have as large a work function as possible. Examples thereof include a metal element, such as gold, platinum, silver, copper, nickel, palladium, cobalt, selenium, vanadium, or tungsten, a mixture thereof, an alloy thereof, and a metal oxide, such as tin oxide, zinc oxide, indium oxide, indium tin oxide (ITO), or indium zinc oxide. An electrically conductive polymer, such as polyaniline, polypyrrole, or polythiophene, may also be used.

These electrode materials may be used alone or in combination. The positive electrode may be composed of a single layer or a plurality of layers.

When used as a reflective electrode, for example, chromium, aluminum, silver, titanium, tungsten, molybdenum, an alloy thereof, or a laminate thereof can be used. These materials can also function as a reflective film that does not have a role as an electrode. When used as a transparent electrode, an oxide transparent electroconductive layer, such as indium tin oxide (ITO) or indium zinc oxide, can be used. However, the invention is not limited thereto. The electrodes may be formed by photolithography.

On the other hand, a constituent material of the negative electrode can be a material with a small work function. For example, an alkali metal, such as lithium, an alkaline-earth metal, such as calcium, a metal element, such as aluminum, titanium, manganese, silver, lead, or chromium, or a mixture thereof may be used. An alloy of these metal elements may also be used. For example, magnesium-silver, aluminum-lithium, aluminum-magnesium, silver-copper, or zinc-silver may be used. A metal oxide, such as indium tin oxide (ITO), may also be used. These electrode materials may be used alone or in combination. The negative electrode may be composed of a single layer or a plurality of layers. In particular, silver can be used, and a silver alloy can be used to reduce the aggregation of silver. As long as the aggregation of silver can be reduced, the alloy may have any ratio. For example, the ratio of silver to another metal may be 1:1, 3:1, or the like.

The negative electrode may be, but is not limited to, an oxide electroconductive layer, such as ITO, for a top emission element or a reflective electrode, such as aluminum (Al), for a bottom emission element. The negative electrode may be formed by any method. A direct-current or alternating-current sputtering method can achieve good film coverage and easily decrease resistance.

### [Organic Compound Layer]

The organic compound layer may be formed of a single layer or a plurality of layers. Depending on their functions, the plurality of layers may be referred to as a hole injection layer, a hole transport layer, an electron-blocking layer, a light-emitting layer, a hole-blocking layer, an electron transport layer, or an electron injection layer. The organic compound layer is composed mainly of an organic compound and may contain an inorganic atom or an inorganic compound. For example, copper, lithium, magnesium, aluminum, iridium, platinum, molybdenum, zinc, or the like may be contained. The organic compound layer may be located between the first electrode and the second electrode and may be in contact with the first electrode and the second electrode.

An organic compound layer (a hole injection layer, a hole transport layer, an electron-blocking layer, a light-emitting layer, a hole-blocking layer, an electron transport layer, an electron injection layer, or the like) constituting an organic light-emitting element according to an embodiment of the present disclosure is formed by the following methods.

An organic compound layer constituting an organic light-emitting element according to an embodiment of the present disclosure can be formed by a dry process, such as a vacuum evaporation method, an ionized deposition method, sputtering, or plasma. Instead of the dry process, a wet process may also be employed in which a layer is formed by a known coating method (for example, spin coating, dipping, a casting method, an LB method, an ink jet method, or the like) using an appropriate solvent.

A layer formed by a vacuum deposition method, a solution coating method, or the like undergoes little crystallization or the like and has high temporal stability. When a film is formed by a coating method, the film may also be formed in combination with an appropriate binder resin.

The binder resin may be, but is not limited to, a polyvinylcarbazole resin, a polycarbonate resin, a polyester resin, an ABS resin, an acrylic resin, a polyimide resin, a phenolic resin, an epoxy resin, a silicone resin, or a urea resin.

These binder resins may be used alone or in combination as a homopolymer or a copolymer. If necessary, an additive agent, such as a known plasticizer, oxidation inhibitor, and/or ultraviolet absorbent, may also be used.

### [Protective Layer]

A protective layer may be provided on the second electrode. For example, a glass sheet with a moisture absorbent may be attached to the second electrode to decrease the amount of water or the like entering the organic compound layer and to reduce the occurrence of display defects. In another embodiment, a passivation film of silicon nitride or the like may be provided on the second electrode to decrease the amount of water or the like entering the organic compound layer. For example, the second electrode may be formed and then transferred to another chamber without breaking the vacuum, and a silicon nitride film with a thickness of 2 μm may be formed as a protective layer by a chemical vapor deposition (CVD) method. The film formation by the CVD method may be followed by the formation of a protective layer by an atomic layer deposition (ALD) method. A film formed by the ALD method may be formed of any material, such as silicon nitride, silicon oxide, or aluminum oxide. Silicon nitride may be further formed by the CVD method on the film formed by the ALD method. The film formed by the ALD method may have a smaller thickness than the film formed by the CVD method. More specifically, it may be 50% or less or even 10% or less.

### [Color Filter]

A color filter may be provided on the protective layer. For example, a color filter that matches the size of the organic light-emitting element may be provided on another substrate and may be bonded to the substrate on which the organic light-emitting element is provided, or a color filter may be patterned on the protective layer by photolithography. The color filter may be composed of a polymer.

### [Planarization Layer]

A planarization layer may be provided between the color filter and the protective layer. The planarization layer is provided to reduce the roughness of the underlayer. The planarization layer is sometimes referred to as a material resin layer with any purpose. The planarization layer may be composed of an organic compound and can be composed of a high-molecular-weight compound, though it may be composed of a low-molecular-weight compound.

The planarization layer may be provided above and below the color filter, and the constituent materials thereof may be the same or different. Specific examples include a polyvinylcarbazole resin, a polycarbonate resin, a polyester resin, an ABS resin, an acrylic resin, a polyimide resin, a phenolic resin, an epoxy resin, a silicone resin, and a urea resin.

### [Microlens]

An organic light-emitting element or an organic light-emitting apparatus with an organic light-emitting element may include an optical member, such as a microlens, on the light output side. The microlens may be composed of an acrylic resin, an epoxy resin, or the like. The microlens may be used to increase the amount of light extracted from the organic light-emitting element or the organic light-emitting apparatus and control the direction of the extracted light. The microlens may have a hemispherical shape. For a hemispherical microlens, the vertex of the microlens is a contact point between the hemisphere and a tangent line parallel to the insulating layer among the tangent lines in contact with the hemisphere. The vertex of the microlens in any cross-sectional view can be determined in the same manner. More specifically, the vertex of the microlens in a cross-sectional view is a contact point between the semicircle of the microlens and a tangent line parallel to the insulating layer among the tangent lines in contact with the semicircle.

The midpoint of the microlens can also be defined. In a cross section of the microlens, a midpoint of a line segment from one end point to the other end point of the arc can be referred to as a midpoint of the microlens. A cross section in which the vertex and the midpoint are determined may be perpendicular to the insulating layer.

### [Opposite Substrate]

An opposite substrate may be provided on the planarization layer. The opposite substrate is so called because it faces the substrate. The opposite substrate may be composed of the same material as the substrate. When the substrate is a first substrate, the opposite substrate may be a second substrate.

### [Pixel Circuit]

An organic light-emitting apparatus including an organic light-emitting element may include a pixel circuit coupled to the organic light-emitting element. The pixel circuit may be of an active matrix type, which independently controls the light emission of a plurality of light-emitting elements. The active-matrix circuit may be voltage programmed or current programmed. The drive circuit has a pixel circuit for each pixel. The pixel circuit may include a light-emitting element, a transistor for controlling the luminous brightness of the light-emitting element, a transistor for controlling light emission timing, a capacitor for holding the gate voltage of the transistor for controlling the luminous brightness, and a transistor for GND connection without through the light-emitting element.

A light-emitting apparatus includes a display region and a peripheral region around the display region. The display region includes the pixel circuit, and the peripheral region includes a display control circuit. The mobility of a transistor constituting the pixel circuit may be smaller than the mobility of a transistor constituting the display control circuit. The gradient of the current-voltage characteristics of a transistor constituting the pixel circuit may be smaller than the gradient of the current-voltage characteristics of a transistor constituting the display control circuit. The gradient of the current-voltage characteristics can be determined by so-called Vg-Ig characteristics. A transistor constituting the pixel circuit is a transistor coupled to a light-emitting element, such as a first light-emitting element.

### [Pixel]

An organic light-emitting apparatus including an organic light-emitting element may have a plurality of pixels. Each pixel has subpixels that emit light of different colors. For example, the subpixels may have RGB emission colors.

In each pixel, a region also referred to as a pixel aperture emits light. The pixel aperture may be 15 μm or less or 5 μm or more. More specifically, the pixel aperture may be 11 μm, 9.5 μm, 7.4 μm, or 6.4 μm. The distance between the subpixels may be 10 μm or less, more specifically, 8 μm, 7.4 μm, or 6.4 μm.

The pixels may be arranged in a known form in a plan view. Examples include a stripe arrangement, a delta arrangement, a PenTile arrangement, and a Bayer arrangement. Each subpixel may have any known shape in a plan view. Examples include quadrangles, such as a rectangle and a rhombus, and a hexagon. As a matter of course, the rectangle also includes a figure that is not strictly rectangular but is close to rectangular. The shape of each subpixel and the pixel array can be used in combination.

### (6) Apparatus Including Organic Light-Emitting Element

An organic light-emitting element according to the present disclosure can be used as a constituent of a display apparatus or a lighting apparatus. Other applications include an exposure light source for an electrophotographic image-forming apparatus, a backlight for a liquid crystal display, and a light-emitting apparatus with a color filter in a white light source.

The display apparatus may be an image-information-processing apparatus that includes an image input unit for inputting image information from an area CCD, a linear CCD, a memory card, or the like, includes an information processing unit for processing the input information, and displays an input image on a display unit. The display apparatus may have a plurality of pixels, and at least one of the pixels may include an organic light-emitting element according to the present disclosure and a transistor coupled to the organic light-emitting element. The substrate may be a semiconductor substrate formed of silicon or the like, and the transistor may be a MOSFET formed on the substrate.

A display unit of an imaging apparatus or an ink jet printer may have a touch panel function. A driving system of the touch panel function may be, but is not limited to, an infrared radiation system, an electrostatic capacitance system, a resistive film system, or an electromagnetic induction system. The display apparatus may be used for a display unit of a multifunction printer.

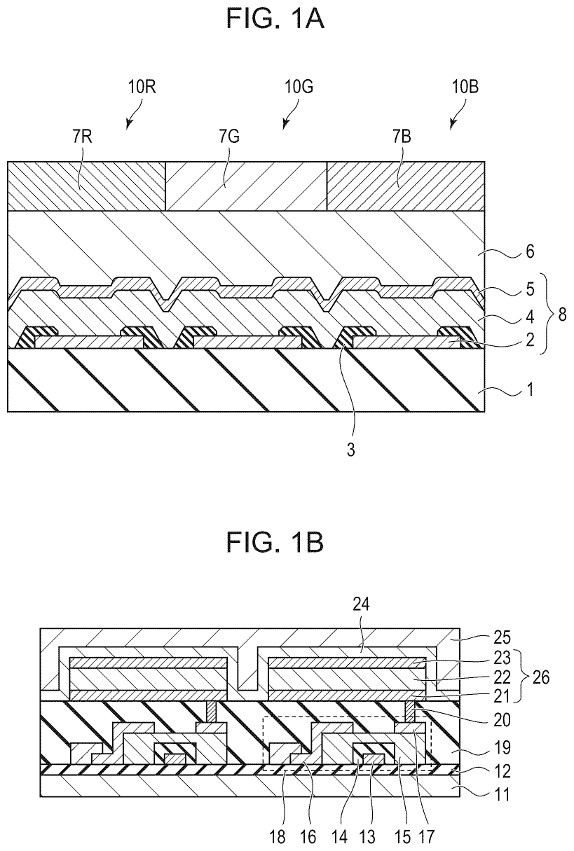

Next, the display apparatus according to the present embodiment is described below with reference to the accompanying drawings. FIGS. 1A and 1B are schematic cross-sectional views of an example of a display apparatus that includes an organic light-emitting element and a transistor coupled to the organic light-emitting element. The transistor is an example of an active element. The transistor may be a thin-film transistor (TFT).

FIG. 1A illustrates an example of a pixel serving as a constructional element of the display apparatus according to the present embodiment. The pixel has subpixels 10. The subpixels are 10R, 10G, and 10B with different emission colors. The emission colors may be distinguished by the wavelength of light emitted from the light-emitting layer, or light emitted from each subpixel may be selectively transmitted or color-converted with a color filter or the like. Each of the subpixels 10 includes a reflective electrode serving as a first electrode 2, an insulating layer 3 covering an end of the first electrode 2, an organic compound layer 4 covering the first electrode 2 and the insulating layer 3, a transparent electrode serving as a second electrode 5, a protective layer 6, and a color filter 7 on an interlayer insulating layer 1.

A transistor and/or a capacitor element may be provided under or inside the interlayer insulating layer 1. The transistor and the first electrode 2 may be electrically connected via a contact hole (not shown) or the like.

The insulating layer 3 is also referred to as a bank or a pixel separation film. The insulating layer 3 covers the ends of the first electrode 2 and surrounds the first electrode 2. A portion not covered with the insulating layer 3 is in contact with the organic compound layer 4 and serves as a light-emitting region.

The second electrode 5 may be a transparent electrode, a reflective electrode, or a semitransparent electrode.

The protective layer 6 reduces the penetration of moisture into the organic compound layer 4. The protective layer 6 is illustrated as a single layer but may be a plurality of layers. The protective layer 6 may include an inorganic compound layer and an organic compound layer.

The color filter 7 is divided into 7R, 7G, and 7B according to the color. The color filter 7 may be formed on a planarizing film (not shown). Furthermore, a resin protective layer (not shown) may be provided on the color filter 7. The color filter 7 may be formed on the protective layer 6. Alternatively, the color filter 7 may be bonded after being provided on an opposite substrate, such as a glass substrate.

A display apparatus illustrated in FIG. 1B includes an organic light-emitting element 26 and a TFT 18, which is an example of a transistor. The display apparatus includes a substrate 11 made of glass, silicon, or the like and an insulating layer 12 on the substrate 11. An active element, such as the TFT 18, and a gate electrode 13, a gate-insulating film 14, and a semiconductor layer 15 of the active element are disposed on the insulating layer 12. The TFT 18 has a drain electrode 16 and a source electrode 17. The TFT 18 is covered with an insulating film 19. A positive electrode 21 constituting the organic light-emitting element 26 is connected to the source electrode 17 via a contact hole 20.

Electrical connection between the electrodes of the organic light-emitting element 26 (the positive electrode 21 and a negative electrode 23) and the electrodes of the TFT 18 (the source electrode 17 and the drain electrode 16) is not limited to that illustrated in FIG. 1B. More specifically, it is only necessary to electrically connect either the positive electrode 21 or the negative electrode 23 to either the source electrode 17 or the drain electrode 16 of the TFT 18.

Although an organic compound layer 22 is a single layer in the display apparatus illustrated in FIG. 1B, the organic compound layer 22 may be composed of a plurality of layers. The negative electrode 23 is covered with a first protective layer 24 and a second protective layer 25 for reducing degradation of the organic light-emitting element 26.

Although a transistor is used as a switching element in the display apparatus in FIG. 1B, another switching element, such as a metal-insulator-metal (MIM) element, may be used instead.

The transistor used in the display apparatus in FIG. 1B is not limited to a thin-film transistor including an active layer on an insulating surface of a substrate and may also be a transistor including a single crystal silicon wafer. The active layer may be single-crystal silicon, non-single-crystal silicon, such as amorphous silicon or microcrystalline silicon, or a non-single-crystal oxide semiconductor, such as indium zinc oxide or indium gallium zinc oxide. The thin-film transistor is also referred to as a TFT element.

The transistor in the display apparatus in FIG. 1B may be formed within a substrate, such as a Si substrate. The phrase “formed within a substrate” means that the substrate, such as a Si substrate, itself is processed to form the transistor. Thus, the transistor within the substrate can be considered that the substrate and the transistor are integrally formed.

In the organic light-emitting element according to the present embodiment, the luminous brightness is controlled with the TFT, which is an example of a switching element. The organic light-emitting element can be provided in a plurality of planes to display an image at each luminous brightness. The switching element according to the present embodiment is not limited to the TFT and may be a transistor formed of low-temperature polysilicon or an active-matrix driver formed on a substrate, such as a Si substrate. The phrase “on a substrate” may also be referred to as “within a substrate”. Whether a transistor is provided within a substrate or a TFT is used depends on the size of a display unit. For example, for an approximately 0.5-inch display unit, an organic light-emitting element can be provided on a Si substrate.

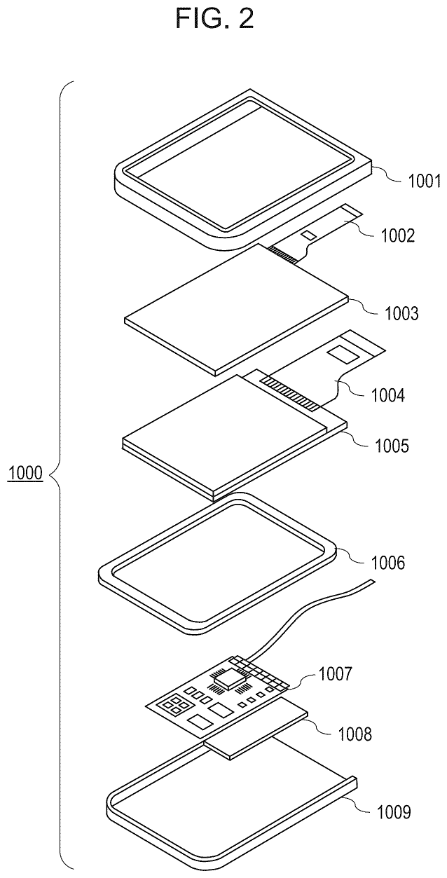

FIG. 2 is a schematic view of an example of the display apparatus according to the present embodiment. A display apparatus 1000 may include a touch panel 1003, a display panel 1005, a frame 1006, a circuit substrate 1007, and a battery 1008 between an upper cover 1001 and a lower cover 1009. The touch panel 1003 and the display panel 1005 are coupled to flexible print circuits FPC 1002 and 1004, respectively. Transistors are printed on the circuit substrate 1007. The battery 1008 is not necessarily provided when the display apparatus is not a mobile device, or may be provided at another position even when the display apparatus is a mobile device.

The display apparatus according to the present embodiment may include color filters of red, green, and blue colors. In the color filters, the red, green, and blue colors may be arranged in a delta arrangement.

The display apparatus according to the present embodiment may be used for a display unit of a mobile terminal. Such a display apparatus may have both a display function and an operation function. The mobile terminal may be a mobile phone, such as a smartphone, a tablet, a head-mounted display, or the like.

The display apparatus according to the present embodiment may be used for a display unit of an imaging apparatus that includes an optical unit with a plurality of lenses and an imaging element for receiving light passing through the optical unit. The imaging apparatus may include a display unit for displaying information acquired by the imaging element. The display unit may be a display unit exposed outside from the imaging apparatus or a display unit located in a finder. The imaging apparatus may be a digital camera or a digital camcorder.

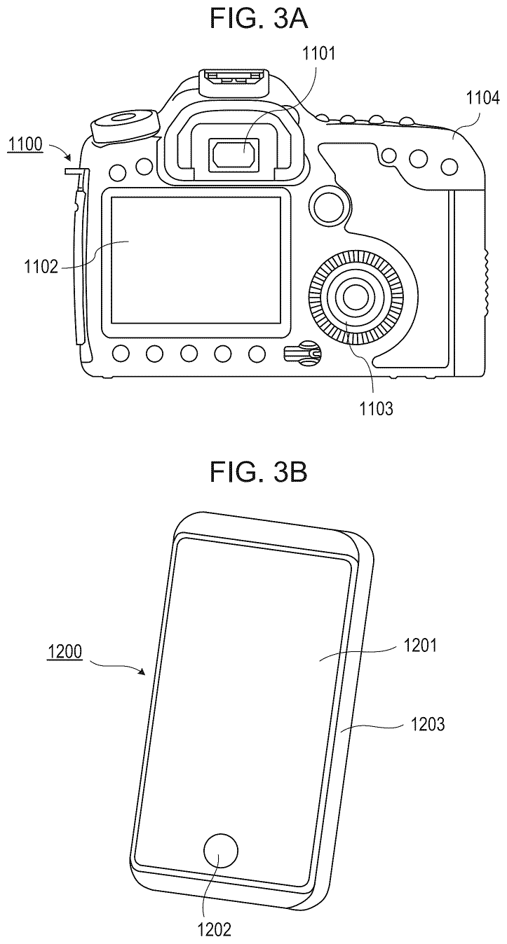

FIG. 3A is a schematic view of an example of an imaging apparatus according to the present embodiment. An imaging apparatus 1100 may include a viewfinder 1101, a rear display 1102, an operating unit 1103, and a housing 1104. The viewfinder 1101 may include the display apparatus according to the present embodiment. In such a case, the display apparatus may display environmental information, imaging instructions, and the like as well as an image to be captured. The environmental information may include the intensity of external light, the direction of external light, the travel speed of the photographic subject, the possibility that the photographic subject is shielded by a shielding material, and the like.

Because the appropriate timing for imaging is a short time, it is better to display information as early as possible. Thus, a display apparatus including an organic light-emitting element according to the present disclosure can be used. This is because the organic light-emitting element has a high response speed. A display apparatus including the organic light-emitting element can be more suitably used than liquid crystal displays.

The imaging apparatus 1100 includes an optical unit (not shown). The optical unit has a plurality of lenses and focuses an image on an imaging element in the housing 1104. The focus of the lenses can be adjusted by adjusting their relative positions. This operation can also be automatically performed. The imaging apparatus may also be referred to as a photoelectric conversion apparatus. The photoelectric conversion apparatus can have, as an imaging method, a method of detecting a difference from a previous image, a method of cutting out a permanently recorded image, or the like, instead of taking an image one after another.

FIG. 3B is a schematic view of an example of electronic equipment according to the present embodiment. Electronic equipment 1200 includes a display unit 1201, an operating unit 1202, and a housing 1203. The housing 1203 may include a circuit, a printed circuit board including the circuit, a battery, and a communication unit. The operating unit 1202 may be a button or a touch panel response unit. The operating unit 1202 may be a biometric recognition unit that recognizes a fingerprint and releases the lock. Electronic equipment with a communication unit may also be referred to as communication equipment. The electronic equipment 1200 may have a lens and an imaging element and thereby further have a camera function. An image captured by the camera function is displayed on the display unit 1201. The electronic equipment 1200 may be a smartphone, a notebook computer, or the like.

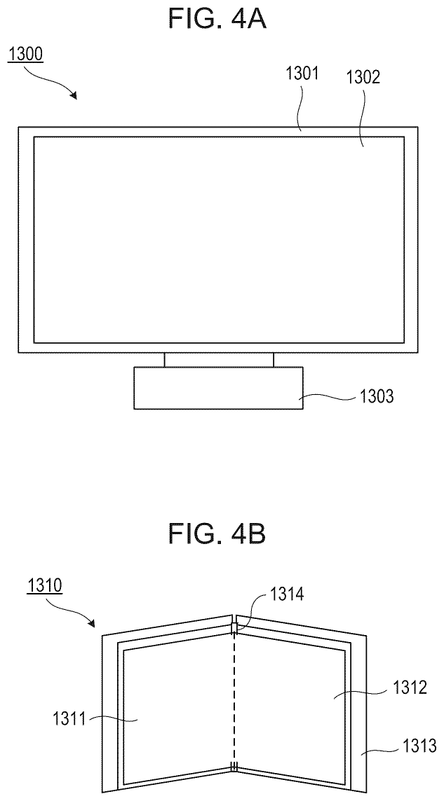

FIGS. 4A and 4B are schematic views of an example of the display apparatus according to the present embodiment. FIG. 4A illustrates a display apparatus, such as a television monitor or a PC monitor. A display apparatus 1300 includes a frame 1301 and a display unit 1302. An organic light-emitting element according to the present disclosure is used for the display unit 1302. The display apparatus 1300 includes a base 1303 for supporting the frame 1301 and the display unit 1302. The base 1303 is not limited to the structure illustrated in FIG. 4A. The lower side of the frame 1301 may also serve as the base. The frame 1301 and the display unit 1302 may be bent. The radius of curvature thereof may be 5000 mm or more and 6000 mm or less.

FIG. 4B is a schematic view of another example of the display apparatus according to the present embodiment. A display apparatus 1310 in FIG. 4B is configured to be foldable and is a so-called foldable display apparatus. The display apparatus 1310 includes a first display unit 1311, a second display unit 1312, a housing 1313, and a folding point 1314. The first display unit 1311 and the second display unit 1312 have an organic light-emitting element according to the present disclosure. The first display unit 1311 and the second display unit 1312 may be a single display apparatus without a joint. The first display unit 1311 and the second display unit 1312 can be divided by the folding point. The first display unit 1311 and the second display unit 1312 may display different images or one image.

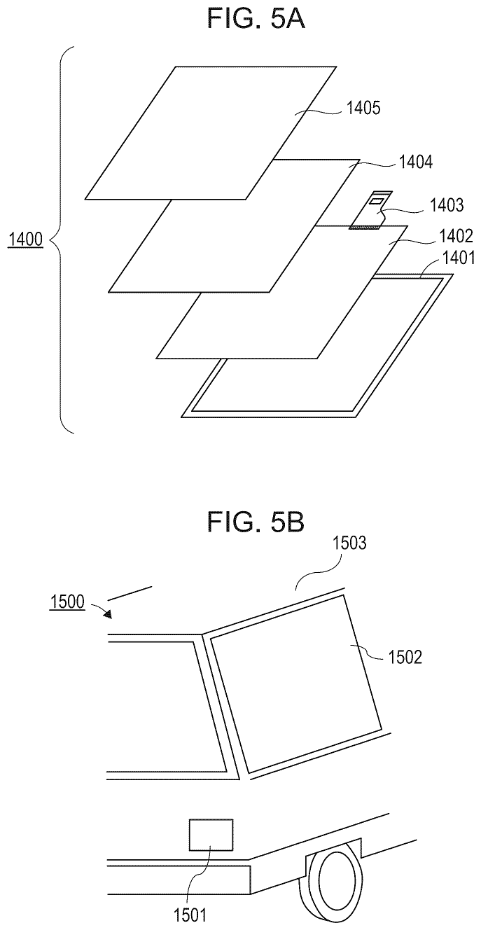

FIG. 5A is a schematic view of an example of a lighting apparatus according to the present embodiment. A lighting apparatus 1400 may include a housing 1401, a light source 1402, a circuit substrate 1403, an optical filter 1404 that transmits light emitted by the light source 1402, and a light-diffusing unit 1405. The light source 1402 has an organic light-emitting element according to the present disclosure. The optical filter 1404 may be a filter that improves the color rendering properties of the light source. The light-diffusing unit 1405 can effectively diffuse light from the light source and widely spread light as in illumination. The optical filter 1404 and the light-diffusing unit 1405 may be provided on the light output side of the lighting apparatus. If necessary, a cover may be provided on the outermost side.

For example, the lighting apparatus is an interior lighting apparatus. The lighting apparatus may emit white light, neutral white light, or light of any color from blue to red. The lighting apparatus may have a light control circuit for controlling such light or a color control circuit for controlling emission color. The lighting apparatus includes an organic light-emitting element according to the present disclosure and a power supply circuit coupled thereto. The power supply circuit is a circuit that converts an AC voltage to a DC voltage. White has a color temperature of 4200 K, and neutral white has a color temperature of 5000 K. The lighting apparatus may have a color filter.

The lighting apparatus according to the present embodiment may include a heat dissipation unit. The heat dissipation unit releases heat from the apparatus to the outside and may be a metal or liquid silicon with a high specific heat.

FIG. 5B is a schematic view of an automobile as an example of a moving body according to the present embodiment. The automobile has a taillight as an example of a lamp. An automobile 1500 may have a taillight 1501, which comes on when a brake operation or the like is performed.

The taillight 1501 may have an organic light-emitting element according to the present disclosure. The taillight 1501 may include a protective member for protecting the organic light-emitting element. The protective member may be formed of any transparent material with moderately high strength and can be formed of polycarbonate or the like. The polycarbonate may be mixed with a furan dicarboxylic acid derivative, an acrylonitrile derivative, or the like.

The automobile 1500 may have a body 1503 and a window 1502 on the body 1503. The window 1502 may be a transparent display as long as it is not a window for checking the front and rear of the automobile. The transparent display has an organic light-emitting element according to the present disclosure. In such a case, constituent materials, such as electrodes, of the organic light-emitting element are transparent materials.

The moving body according to the present embodiment may be a ship, an aircraft, a drone, or the like. The moving body may include a body and a lamp provided on the body. The lamp may emit light to indicate the position of the body. The lamp has an organic light-emitting element according to the present disclosure.

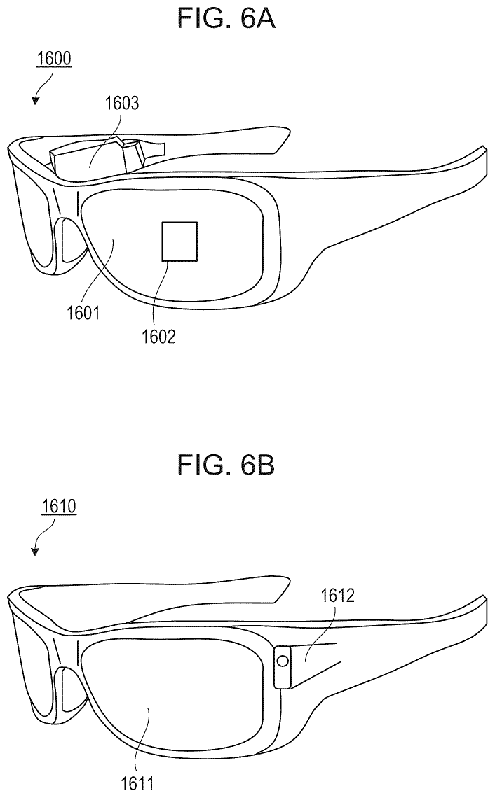

Application examples of the display apparatus according to one of the embodiments are described below with reference to FIGS. 6A and 6B. The display apparatus can be applied to a system that can be worn as a wearable device, such as smart glasses, a head-mounted display (HMD), or smart contact lenses. An imaging and displaying apparatus used in such an application example includes an imaging apparatus that can photoelectrically convert visible light and a display apparatus that can emit visible light.

FIG. 6A is a schematic view of an example of a wearable device according to an embodiment of the present disclosure. Glasses 1600 (smart glasses) according to one application example will be described below with reference to FIG. 6A. An imaging apparatus 1602, such as a complementary metal-oxide semiconductor (CMOS) sensor or a single-photon avalanche photodiode (SPAD), is provided on the front side of a lens 1601 of the glasses 1600. The display apparatus according to one of the embodiments is provided on the back side of the lens 1601.

The glasses 1600 further include a controller 1603. The controller 1603 functions as a power supply for supplying power to the imaging apparatus 1602 and the display apparatus. The controller 1603 controls the operation of the imaging apparatus 1602 and the display apparatus. The lens 1601 has an optical system for focusing light on the imaging apparatus 1602.

FIG. 6B is a schematic view of another example of a wearable device according to an embodiment of the present disclosure. Glasses 1610 (smart glasses) according to one application example will be described below with reference to FIG. 6B. The glasses 1610 have a controller 1612, which includes an imaging apparatus corresponding to the imaging apparatus 1602 of FIG. 6A and a display apparatus. A lens 1611 includes an optical system for projecting light from the imaging apparatus of the controller 1612 and the display apparatus, and an image is projected on the lens 1611. The controller 1612 functions as a power supply for supplying power to the imaging apparatus and the display apparatus and controls the operation of the imaging apparatus and the display apparatus.

The controller 1612 may include a line-of-sight detection unit for detecting the line of sight of the wearer. Infrared radiation may be used to detect the line of sight. An infrared radiation unit emits infrared light to an eyeball of a user who is gazing at a display image. Reflected infrared light from the eyeball is detected by an imaging unit including a light-receiving element to capture an image of the eyeball. A reduction unit for reducing light from the infrared radiation unit to a display unit in a plan view is provided to reduce degradation in image quality. The line of sight of the user for the display image is detected from the image of the eyeball captured by infrared imaging. Any known technique can be applied to line-of-sight detection using the captured image of the eyeball. For example, it is possible to use a line-of-sight detection method based on a Purkinje image obtained by the reflection of irradiation light by the cornea. More specifically, a line-of-sight detection process based on a pupil-corneal reflection method is performed. The line of sight of the user is detected by calculating a line-of-sight vector representing the direction (rotation angle) of an eyeball on the basis of an image of a pupil and a Purkinje image included in a captured image of the eyeball using the pupil-corneal reflection method.

A display apparatus according to an embodiment of the present disclosure may include an imaging apparatus including a light-receiving element and may control a display image on the basis of line-of-sight information of a user from the imaging apparatus. More specifically, on the basis of the line-of-sight information, the display apparatus determines a first visibility region at which the user gazes and a second visibility region other than the first visibility region. The first visibility region and the second visibility region may be determined by the controller of the display apparatus or may be received from an external controller. In the display region of the display apparatus, the first visibility region may be controlled to have higher display resolution than the second visibility region. In other words, the second visibility region may have lower resolution than the first visibility region.

The display region has a first display region and a second display region different from the first display region, and the priority of the first display region and the second display region depends on the line-of-sight information. The first visibility region and the second visibility region may be determined by the controller of the display apparatus or may be received from an external controller. A region with a higher priority may be controlled to have higher resolution than another region. In other words, a region with a lower priority may have lower resolution.

The first visibility region or a region with a higher priority may be determined by artificial intelligence (AI). The AI may be a model configured to estimate the angle of the line of sight and the distance to a target ahead of the line of sight from an image of an eyeball using the image of the eyeball and the direction in which the eyeball actually viewed in the image as teaching data. The AI program may be stored in the display apparatus, the imaging apparatus, or an external device. The AI program stored in an external device is transmitted to the display apparatus via communication.

For display control based on visual recognition detection, the present disclosure can be applied to smart glasses further having an imaging apparatus for imaging the outside. Smart glasses can display captured external information in real time.

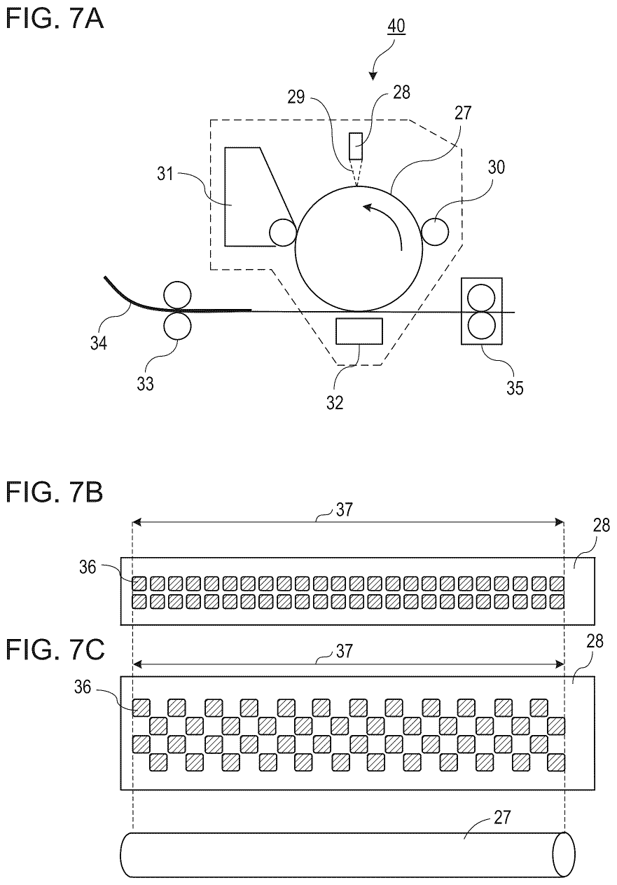

FIG. 7A is a schematic view of an example of an image-forming apparatus according to an embodiment of the present disclosure. An image-forming apparatus 40 is an electrophotographic image-forming apparatus and includes a photosensitive member 27, an exposure light source 28, a charging unit 30, a developing unit 31, a transfer unit 32, a conveying roller 33, and a fixing unit 35. The exposure light source 28 emits light 29, and an electrostatic latent image is formed on the surface of the photosensitive member 27. The exposure light source 28 includes an organic light-emitting element according to the present disclosure. The developing unit 31 contains toner and the like. The charging unit 30 electrifies the photosensitive member 27. The transfer unit 32 transfers a developed image onto a recording medium 34. The conveying roller 33 conveys the recording medium 34. The recording medium 34 is paper, for example. The fixing unit 35 fixes an image on the recording medium 34.

FIGS. 7B and 7C are schematic views of the exposure light source 28, wherein a plurality of light-emitting portions 36 are arranged on a long substrate. An arrow 37 indicates a direction parallel to the axis of the photosensitive member and indicates a column direction in which the organic light-emitting elements are arranged. This column direction is the same as the direction of the rotation axis of the photosensitive member 27. This direction can also be referred to as the major-axis direction of the photosensitive member 27. In FIG. 7B, the light-emitting portions 36 are arranged in the major-axis direction of the photosensitive member 27. In FIG. 7C, unlike FIG. 7B, the light-emitting portions 36 are alternately arranged in the column direction in the first and second columns. The first and second columns are arranged at different positions in the row direction. In the first column, the light-emitting portions 36 are arranged at intervals. In the second column, the light-emitting portions 36 are arranged at positions corresponding to the spaces between the light-emitting portions 36 of the first column. Thus, the light-emitting portions 36 are also arranged at intervals in the row direction. The arrangement in FIG. 7C can also be referred to as a grid-like pattern, a staggered pattern, or a checkered pattern, for example.

As described above, an apparatus including the organic light-emitting element according to the present embodiment can be used to stably display a high-quality image for extended periods.

### [Configurations Included]

The disclosure of the present embodiment includes the following configurations.

### (Configuration 1)

An organic compound represented by the following general formula (1):

Ir(L₁)(L₂)₂ (1)
wherein a substructure Ir(L₁) is represented by the following general formula (1-1), and a substructure Ir(L₂)₂ is represented by the following general formula (1-2):

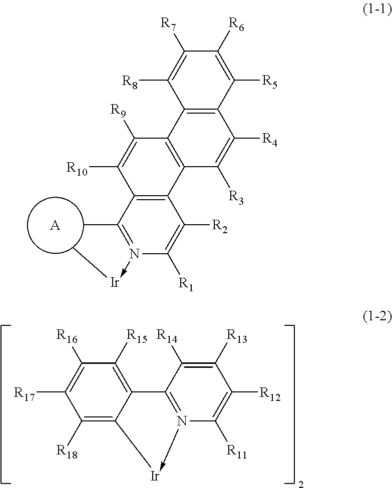

wherein a ring A is selected from a substituted or unsubstituted tricyclic or polycyclic fused ring,
R₁ to R₁₀ in the general formula (1-1) and R₁₁ to R₁₈ in the general formula (1-2) are each independently selected from a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heterocyclic group, a substituted or unsubstituted amino group, a substituted or unsubstituted aryloxy group, a substituted or unsubstituted heteroaryloxy group, and a cyano group,
adjacent substituents Rs in R₁ to R₁₀ and R₁₁ to R₁₈ may be bonded together to form a ring, and
two ligands L₂ may have different structures.

### (Configuration 2)

The organic compound according to Configuration 1, wherein the ring A is selected from a substituted or unsubstituted fluorene ring, a substituted or unsubstituted phenanthrene ring, a substituted or unsubstituted dibenzofuran ring, a substituted or unsubstituted dibenzothiophene ring, and a substituted or unsubstituted carbazole ring.

### (Configuration 3)

The organic compound according to Configuration 1 or 2, wherein at least one of R₁ to R₁₀ is selected from a deuterium atom, a halogen atom, a substituted or unsubstituted alkyl group, a substituted or unsubstituted aryl group, a substituted or unsubstituted heterocyclic group, and a cyano group.

### (Configuration 4)

The organic compound according to any one of Configurations 1 to 3, wherein at least one of R₁₁ to R₁₈ is selected from a deuterium atom, a halogen atom, a substituted or unsubstituted alkyl group, a substituted or unsubstituted aryl group, a substituted or unsubstituted heterocyclic group, and a cyano group.

### (Configuration 5)

An organic light-emitting element including: a pair of electrodes; and an organic compound layer disposed between the pair of electrodes, wherein
the organic compound layer contains the organic compound according to any one of Configurations 1 to 4.

### (Configuration 6)

The organic light-emitting element according to Configuration 5, wherein
the organic compound layer includes a light-emitting layer, and
the light-emitting layer contains the organic compound according to any one of Configurations 1 to 4.

### (Configuration 7)

The organic light-emitting element according to Configuration 6, wherein the light-emitting layer contains the organic compound according to any one of Configurations 1 to 4 as a first organic compound and further contains a second organic compound.

### (Configuration 8)

The organic light-emitting element according to Configuration 7, wherein the second organic compound has at least a fused ring selected from the group consisting of a triphenylene ring, a dibenzothiophene skeleton, and a carbazole skeleton.

### (Configuration 9)

The organic light-emitting element according to any one of Configurations 6 to 8, further including another light-emitting layer on the light-emitting layer, wherein the other light-emitting layer emits light of a color different from that of the light-emitting layer.

### (Configuration 10)

The organic light-emitting element according to Configuration 9, wherein the organic light-emitting element emits white light.

### (Configuration 11)

A display apparatus including a plurality of pixels, wherein at least one pixel of the plurality of pixels includes the organic light-emitting element according to any one of Configurations 5 to 10 and a transistor coupled to the organic light-emitting element.

### (Configuration 12)

A photoelectric conversion apparatus including:
an optical unit including a plurality of lenses; an imaging element configured to receive light passing through the optical unit; and a display unit configured to display an image taken by the imaging element,
wherein the display unit includes the organic light-emitting element according to any one of Configurations 5 to 10.

### (Configuration 13)

Electronic equipment including: a display unit including the organic light-emitting element according to any one of Configurations 5 to 10; a housing configured to be provided with the display unit; and a communication unit provided in the housing and configured to communicate with an outside.

### (Configuration 14)

A lighting apparatus including: a light source including the organic light-emitting element according to any one of Configurations 5 to 10; and a light-diffusing unit or an optical filter configured to transmit light emitted by the light source.

### (Configuration 15)

A moving body including: a lamp including the organic light-emitting element according to any one of Configurations 5 to 10; and a body configured to be provided with the lamp.

### (Configuration 16)

An exposure light source for an electrophotographic image-forming apparatus, including the organic light-emitting element according to any one of Configurations 5 to 10.

### EXEMPLARY EMBODIMENTS

The present disclosure is described below with exemplary embodiments. However, the invention is not limited thereto.

### Exemplary Embodiment 1

Exemplary Compound A-1 and Comparative Compounds 3 and 4 in Table 1 were synthesized by the following reaction formula.

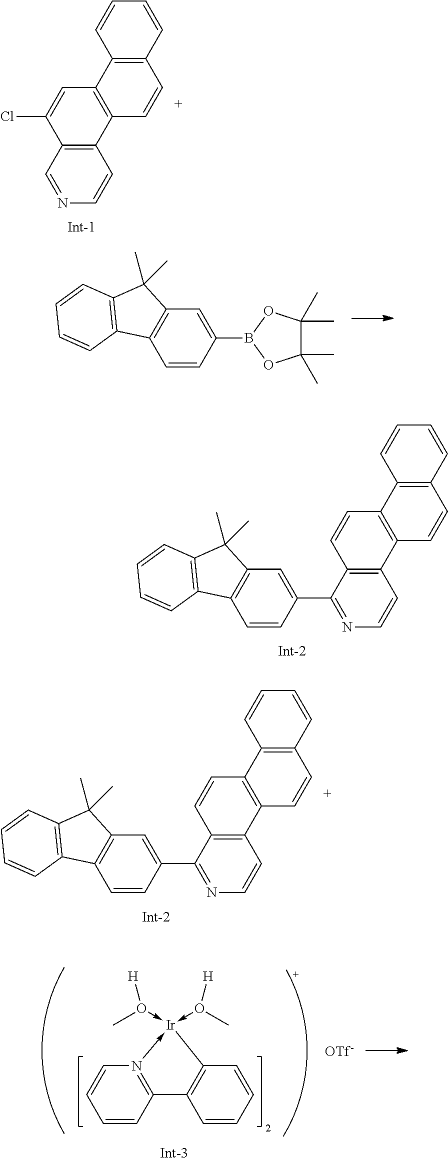

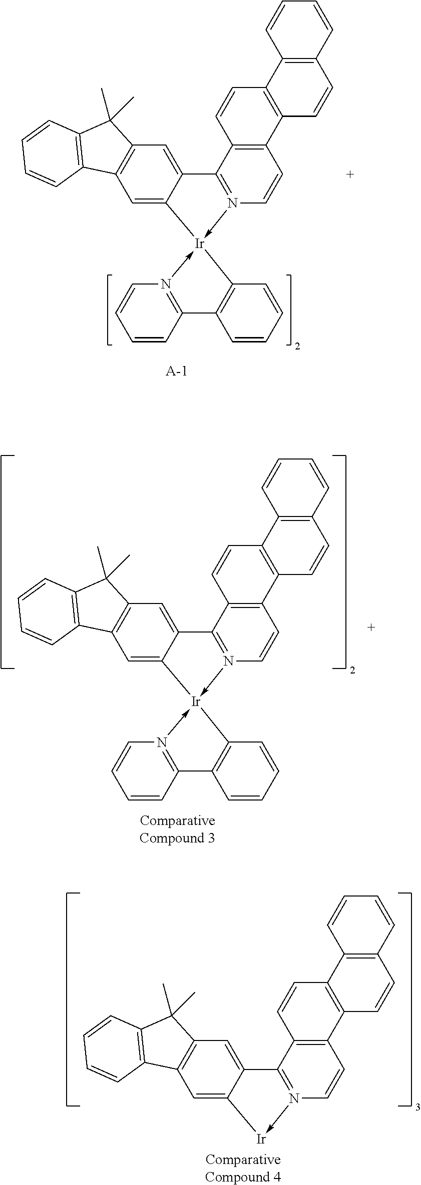

In the reaction formula, Int-1 was synthesized according to “Synthesis of Intermediate 1-4” described in Japanese Patent Laid-Open No. 2014-141425, and Int-3 was synthesized according to “Exemplary Embodiment 1” described in PCT Japanese Translation Patent Publication No. 2012-502046.

### [Reaction Step 1 (Ligand L₁: Synthesis of Intermediate Compound Int-2)]

The following reagent(s) and solvent(s) were charged into a 50-mL recovery flask.
Int-1:1.00 g (3.79 mmol)
2-(9,9-dimethyl-9H-fluoren-2-yl)-4,4,5,5-tetramethyl-1,3,2-dioxaborolane (manufactured by Tokyo Chemical Industry Co., Ltd.): 1.46 g (4.55 mmol)
Sodium carbonate: 1.21 g (11.4 mmol)
Tetrakis(triphenylphosphine)palladium(0): 0.219 g (0.190 mmol)
Toluene: 10 mL
Ion-exchanged water: 6 mL

The reaction solution was heated under reflux with stirring in a nitrogen atmosphere for 18 hours. After completion of the reaction and cooling to room temperature, a precipitated solid was collected by filtration. The solid was purified using a silica gel column (chloroform:heptane=3:1). The resulting white powder was dried in a vacuum dryer at 80° C. for 12 hours to produce 1.34 g of Int-2 (yield: 84%).

### [Reaction Step 2 (Synthesis of Exemplary Compound A-1, Comparative Compound 3, and Comparative Compound 4)]

The following reagent(s) and solvent(s) were charged into a 200-mL recovery flask.
Int-2:1.30 g (3.08 mmol)
Int-3:1.10 g (1.54 mmol)
Ethylene glycol: 8 mL
Diethylene glycol dimethyl ether: 8 mL

The reaction solution was heated under reflux with stirring in a nitrogen atmosphere for 3 hours. After completion of the reaction and cooling to room temperature, a precipitated solid was collected by filtration. The solid was purified using a silica gel column (chloroform:heptane=3:1), and a plurality of components were isolated and dried in a vacuum dryer at 80° C. for 12 hours. Each component was then identified by matrix-assisted laser desorption ionization-time-of-flight mass spectrometry (MALDI-TOF MS). As a result, 0.440 g of Exemplary Compound A-1 (M⁺: 921.3, yield: 31%), 0.256 g of Comparative Compound 3 (M⁺: 1187.4, yield: 14%), and 0.112 g of Comparative Compound 4 (M⁺: 1453.5, yield: 5.0%) were obtained.

### Exemplary Embodiments 2 to 8

Exemplary compounds B-2, C-7, D-3, D-4, D-5, D-7, and D-8 were synthesized.

### [Reaction Step 1 (Ligand L₁: Synthesis of Intermediate Compounds Int-4 to -10)]

Ligands L₁ in Table 4 were synthesized in the same manner as in Reaction Step 1 of Exemplary Embodiment 1 except that Int-1 and 2-(9,9-dimethyl-9H-fluoren-2-yl)-4,4,5,5-tetramethyl-1,3,2-dioxaborolane were changed to a naphtho[2,1-f]isoquinoline derivative and a boronic acid compound or a boronate compound shown in Table 4.

TABLE 4

| | Naphtho[2,1-f]isoquinoline | Boronic acid compound or boronate |
|---|---|---|
| Ligand L₁ | derivative | compound |
| 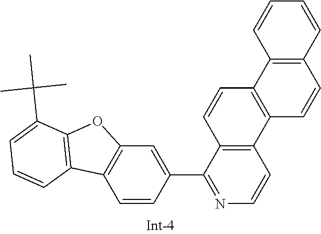 [SMILES: CC(C)(C)c1cccc2c1oc1cc(-c3nccc4c3ccc3c5ccccc5ccc43)ccc12] | 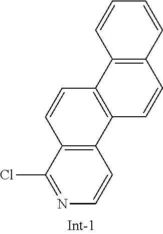 [SMILES: Clc1nccc2c1ccc1c3ccccc3ccc21] | 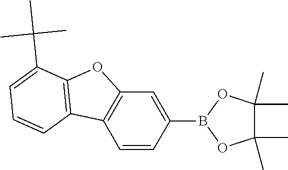 [SMILES: CC(C)(C)c1cccc2c1oc1cc(B3OC(C)(C)C(C)(C)O3)ccc12] |
| 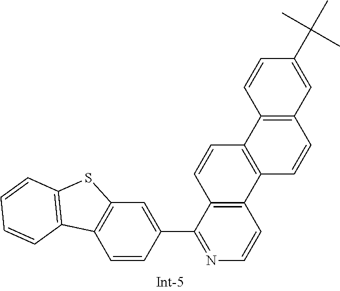 [SMILES: CC(C)(C)c1ccc2c(ccc3c4ccnc(-c5ccc6c(c5)sc5ccccc56)c4ccc23)c1] | 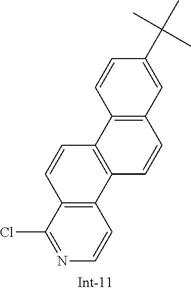 [SMILES: CC(C)(C)c1ccc2c(ccc3c4ccnc(Cl)c4ccc23)c1] | 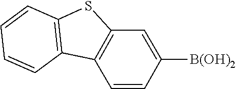 [SMILES: OB(O)c1ccc2c(c1)sc1ccccc12] |
| 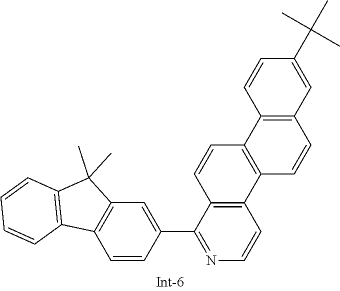 [SMILES: CC(C)(C)c1ccc2c(ccc3c4ccnc(-c5ccc6c(c5)C(C)(C)c5ccccc5-6)c4ccc23)c1] | 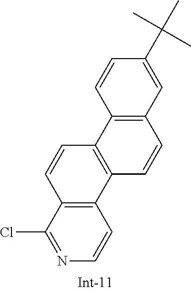 [SMILES: CC(C)(C)c1ccc2c(ccc3c4ccnc(Cl)c4ccc23)c1] | 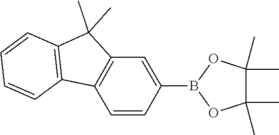 [SMILES: CC1(C)c2ccccc2-c2ccc(B3OC(C)(C)C(C)(C)O3)cc21] |
| 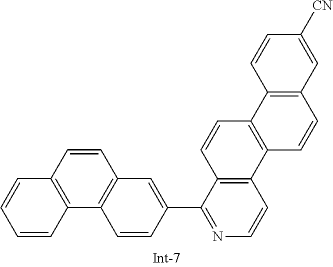 [SMILES: N#Cc1ccc2c(ccc3c4ccnc(-c5ccc6c(ccc7ccccc76)c5)c4ccc23)c1] | 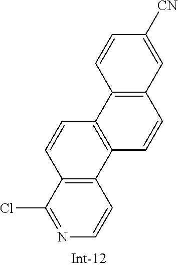 [SMILES: N#Cc1ccc2c(ccc3c4ccnc(Cl)c4ccc23)c1] | 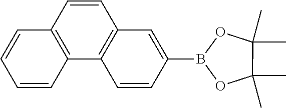 [SMILES: CC1(C)OB(c2ccc3c(ccc4ccccc43)c2)OC1(C)C] |
| 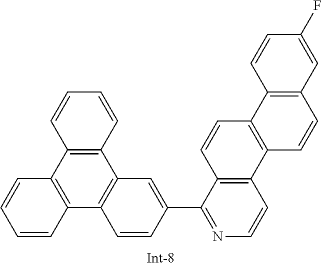 [SMILES: Fc1ccc2c(ccc3c4ccnc(-c5ccc6c7ccccc7c7ccccc7c6c5)c4ccc23)c1] | 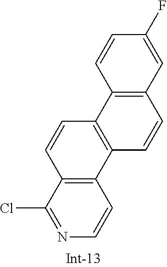 [SMILES: Fc1ccc2c(ccc3c4ccnc(Cl)c4ccc23)c1] | 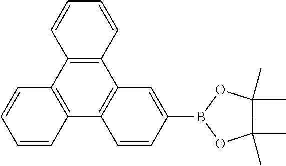 [SMILES: CC1(C)OB(c2ccc3c4ccccc4c4ccccc4c3c2)OC1(C)C] |
| 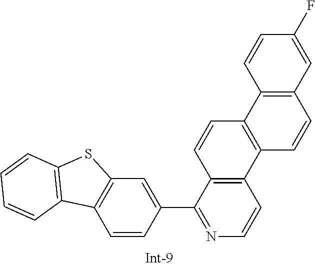 [SMILES: Fc1ccc2c(ccc3c4ccnc(-c5ccc6c(c5)sc5ccccc56)c4ccc23)c1] | 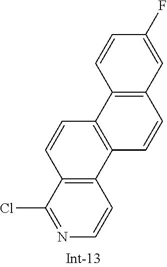 [SMILES: Fc1ccc2c(ccc3c4ccnc(Cl)c4ccc23)c1] | 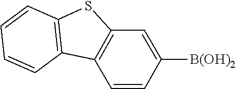 [SMILES: OB(O)c1ccc2c(c1)sc1ccccc12] |
| 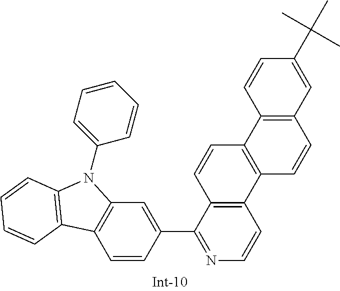 [SMILES: CC(C)(C)c1ccc2c(ccc3c4ccnc(-c5ccc6c7ccccc7n(-c7ccccc7)c6c5)c4ccc23)c1] | 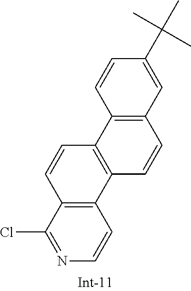 [SMILES: CC(C)(C)c1ccc2c(ccc3c4ccnc(Cl)c4ccc23)c1] | 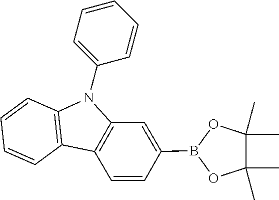 [SMILES: CC1(C)OB(c2ccc3c4ccccc4n(-c4ccccc4)c3c2)OC1(C)C] |

Int-11 in Table 4 was synthesized according to Exemplary Embodiment 4 described in Japanese Patent Laid-Open No. 2014-141425. Int-12 and Int-13 were synthesized in the same manner as in the synthesis of Int-11 except that the intermediate 4-3 (6-(tert-butyl)-2-naphthalenyl-1,1,1-trifluoromethanesulfonate) was changed to 6-bromo-2-naphthonitrile and 2-bromo-6-fluoronaphthalene, respectively.

### [Reaction Step 2 (Synthesis of Exemplary Compounds)]

Exemplary compounds in Tables 5 and 6 were synthesized in the same manner as in Reaction Step 2 of Exemplary Embodiment 1 except that Int-2 and Int-3 were changed to the ligand L₁ and a triflate salt shown in Tables 5 and 6, respectively.

TABLE 5

| Exemplary | Structure- | | |
|---|---|---|---|
| embodiment | Exemplary | | |
| No. | compound name | Ligand L₁ | Triflate salt |
| Exemplary embodiment 2 | 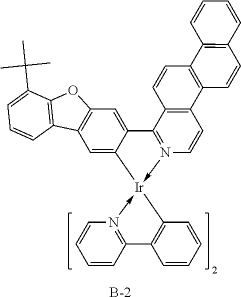 | 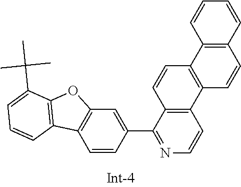 [SMILES: CC(C)(C)c1cccc2c1oc1cc(-c3nccc4c3ccc3c5ccccc5ccc43)ccc12] | 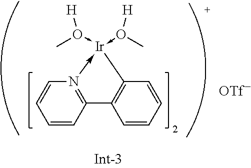 |
| Exemplary embodiment 3 | 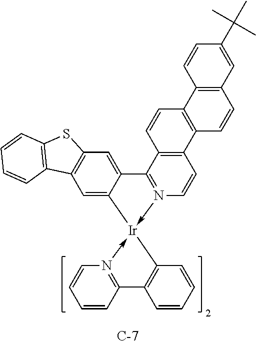 | 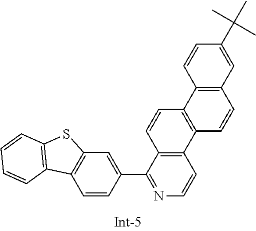 [SMILES: CC(C)(C)c1ccc2c(ccc3c4ccnc(-c5ccc6c(c5)sc5ccccc56)c4ccc23)c1] | 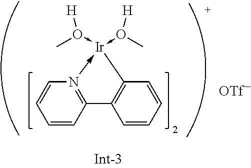 |
| Exemplary embodiment 4 | 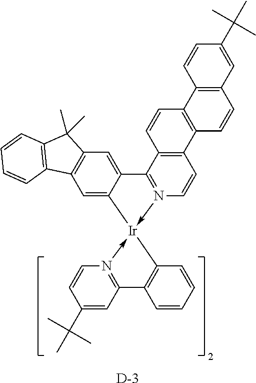 | 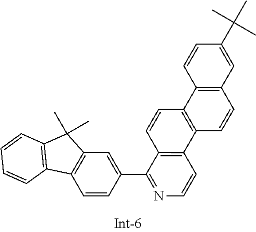 [SMILES: CC(C)(C)c1ccc2c(ccc3c4ccnc(-c5ccc6c(c5)C(C)(C)c5ccccc5-6)c4ccc23)c1] | 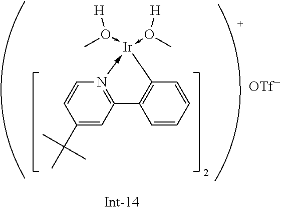 |
| Exemplary embodiment 5 | 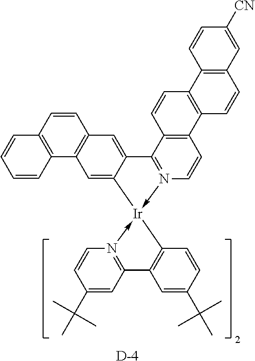 | 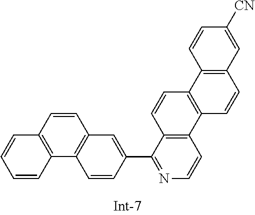 [SMILES: N#Cc1ccc2c(ccc3c4ccnc(-c5ccc6c(ccc7ccccc76)c5)c4ccc23)c1] | 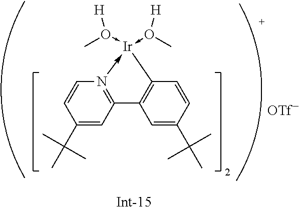 |

TABLE 6

| | Structure- | | |
|---|---|---|---|
| Exemplary | Exemplary | | |
| embodiment No. | compound name | Ligand L₁ | Triflate salt |
| Exemplary embodiment 6 | 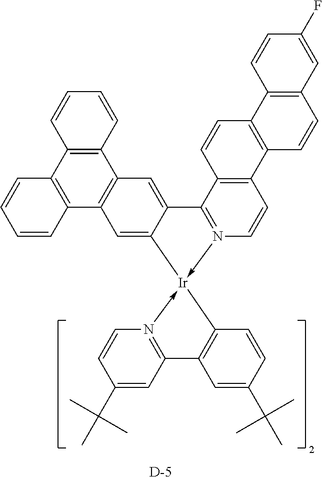 | 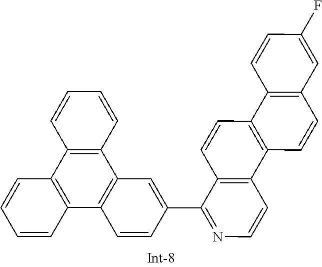 [SMILES: Fc1ccc2c(ccc3c4ccnc(-c5ccc6c7ccccc7c7ccccc7c6c5)c4ccc23)c1] | 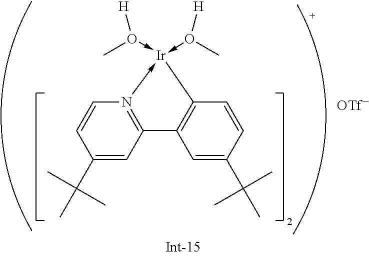 |
| Exemplary embodiment 7 | 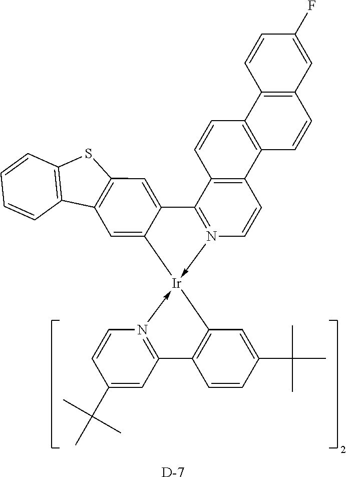 | 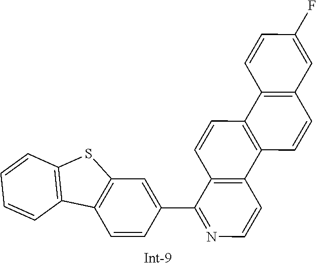 [SMILES: Fc1ccc2c(ccc3c4ccnc(-c5ccc6c(c5)sc5ccccc56)c4ccc23)c1] | 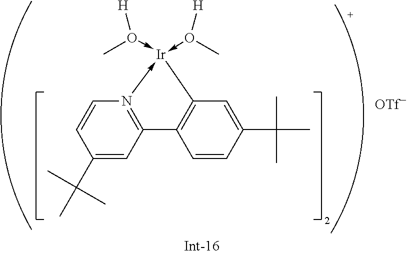 |
| Exemplary embodiment 8 | 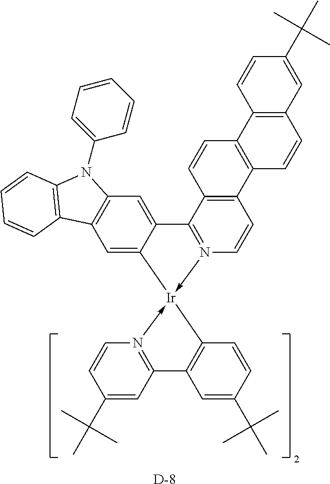 | 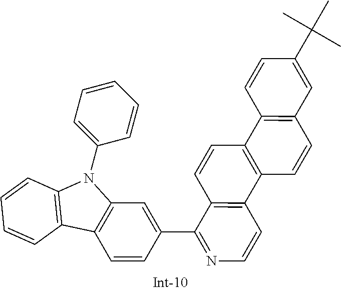 [SMILES: CC(C)(C)c1ccc2c(ccc3c4ccnc(-c5ccc6c7ccccc7n(-c7ccccc7)c6c5)c4ccc23)c1] | 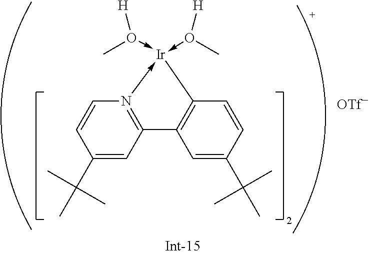 |

Int-14, Int-15, and Int-16 in Tables 5 and 6 were synthesized in the same manner as in PCT Japanese Translation Patent Publication No. 2012-502046 (Exemplary Embodiment 1: Synthesis of PPY dimer) except that 2-phenylpyridine was changed to 4-(tert-butyl)-2-phenylpyridine, 4-(tert-butyl)-2-(3-(tert-butyl)phenyl)pyridine, and 4-(tert-butyl)-2-(4-(tert-butyl)phenyl)pyridine, respectively.

### Comparative Examples 1 and 2

Comparative Compounds 1 and 2 in Table 1 were synthesized according to Synthesis Examples 18 and 17 described in Japanese Patent Laid-Open No. 2014-127687, respectively.

### Comparative Examples 3 and 4

Comparative Compounds 5 and 6 in Table 2 were synthesized.

Comparative Compounds 5 and 6 were synthesized in the same manner as in Reaction Steps 1 and 2 of Exemplary Embodiment 1 except that 2-(9,9-dimethyl-9H-fluoren-2-yl)-4,4,5,5-tetramethyl-1,3,2-dioxaborolane in Reaction Step 1 of Exemplary Embodiment 1 was changed to phenylboronic acid or 2-naphthaleneboronic acid.

### Comparative Example 5

Comparative Compound 7 in Table 2 was synthesized according to Exemplary Embodiment 5 described in Japanese Patent Laid-Open No. 2014-141425.

### Exemplary Embodiment 9

An organic light-emitting element of a bottom emission type was produced. The organic light-emitting element included a positive electrode, a hole injection layer, a hole transport layer, an electron-blocking layer, a light-emitting layer, a hole-blocking layer, an electron transport layer, an electron injection layer, and a negative electrode sequentially formed on a substrate.

First, an ITO film was formed on a glass substrate and was subjected to desired patterning to form an ITO electrode (positive electrode). The ITO electrode had a thickness of 100 nm. The substrate on which the ITO electrode was formed was used as an ITO substrate in the following process. Vacuum evaporation was then performed by resistance heating in a vacuum chamber at 1.33×10⁻⁴ Pa to continuously form an organic compound layer and an electrode layer shown in Table 7 on the ITO substrate. The counter electrode (a metal electrode layer, a negative electrode) had an electrode area of 3 mm².

TABLE 7

| | | | | Thickness |
|---|---|---|---|---|
| | Material | | | (nm) |
| Negative electrode | Al | | | 100 |
| Electron injection layer (EIL) | LiF | | | 1 |
| Electron transport layer (ETL) | ET2 | | | 20 |
| Hole-blocking layer (HBL) | ET11 | | | 20 |
| Light-emitting layer (EML) | Host | EM11 | Mass ratio | 20 |
| | Guest | A-1 | EM11:A-1 = | |
| | | | 97:3 | |

| | | |
|---|---|---|
| Electron-blocking layer (EBL) | HT19 | 15 |
| Hole transport layer (HTL) | HT3 | 30 |
| Hole injection layer (HIL) | HT16 | 5 |

Characteristics of the element were measured and evaluated. The chromaticity coordinates calculated from a spectrum of the light-emitting element were (0.683, 0.315), which were higher in the X value and lower in the Y value than the NTSC standard red (0.670, 0.330), indicating high color purity.

A continuous operation test was performed at a current density of 100 mA/cm² to measure the time when the luminance decay rate reached 5%. Taking the time when the luminance decay rate of an element of Comparative Example 7 described later reached 5% as a reference (1.0), the 5% luminance decay time of the present exemplary embodiment was expressed as a ratio of 2.2.

In the present exemplary embodiment, with respect to measuring apparatuses, more specifically, the current-voltage characteristics were measured with a microammeter 4140B manufactured by Hewlett-Packard Co., and the luminous brightness was measured with BM7 manufactured by Topcon Corporation.

### Exemplary Embodiments 10 to 17 and Comparative Examples 6 and 7

Organic light-emitting elements were produced in the same manner as in Exemplary Embodiment 9 except that the host and the guest were appropriately changed to the compounds shown in Table 8. Characteristics of the elements were measured and evaluated in the same manner as in Exemplary Embodiment 9. Table 8 shows the measurement results. For the color purity evaluation, an element with an X value higher and a Y value lower than the NTSC standard red (0.670, 0.330) was rated as good, while an element with an X value not higher and a Y value not lower was rated as poor.

TABLE 8

| | | | | 5% luminance |
|---|---|---|---|---|
| | EML | | Color purity | decay |
| | Host | Guest | evaluation | time ratio |
| Exemplary | EM13 | A-1 | Good | 2.4 |
| embodiment 10 | | | | |
| Exemplary | EM11 | B-2 | Good | 1.5 |
| embodiment 11 | | | | |
| Exemplary | EM11 | C-7 | Good | 2.0 |
| embodiment 12 | | | | |
| Exemplary | EM11 | D-3 | Good | 2.1 |
| embodiment 13 | | | | |
| Exemplary | EM11 | D-4 | Good | 2.3 |
| embodiment 14 | | | | |
| Exemplary | EM11 | D-5 | Good | 1.7 |
| embodiment 15 | | | | |
| Exemplary | EM11 | D-7 | Good | 1.8 |
| embodiment 16 | | | | |
| Exemplary | EM11 | D-8 | Good | 2.0 |
| embodiment 17 | | | | |
| Comparative | EM11 | Comparative | Poor | 1.6 |
| example 6 | | compound 1 | | |
| Comparative | EM11 | Comparative | Good | 1.0 |
| example 7 | | compound 7 | | |

### Exemplary Embodiment 18

An organic light-emitting element was produced in the same manner as in Exemplary Embodiment 9 except that the organic compound layer and the electrode layer shown in Table 9 were continuously formed.

TABLE 9

| | Material | | | Thickness (nm) |
|---|---|---|---|---|
| Negative electrode | Al | | | 100 |
| Electron injection layer (EIL) | LiF | | | 1 |
| Electron transport layer (ETL) | ET2 | | | 20 |
| Hole-blocking layer (HBL) | ET11 | | | 20 |
| Light-emitting layer (EML) | Host | EM11 | Mass ratio | 20 |
| | Assist | AA22 | EM11:AA22:A-1 = | |
| | (Second host) | | 82:15:3 | |
| | Guest | A-1 | | |

| | | |
|---|---|---|
| Electron-blocking layer (EBL) | HT19 | 15 |
| Hole transport layer (HTL) | HT3 | 30 |
| Hole injection layer (HIL) | HT16 | 5 |

Characteristics of the elements were measured and evaluated in the same manner as in Exemplary Embodiment 9. The chromaticity coordinates calculated from a spectrum of the light-emitting element were (0.682, 0.316), which were higher in the X value and lower in the Y value than the NTSC standard red (0.670, 0.330), indicating high color purity.

A continuous operation test was performed at a current density of 100 mA/cm² to measure the time when the luminance decay rate reached 5%. Taking the time when the luminance decay rate in Comparative Example 9 described later reached 5% as a reference (1.0), the 5% luminance decay time of the present exemplary embodiment was expressed as a ratio of 2.6.

### Exemplary Embodiments 19 to 28 and Comparative Examples 8 and 9

Organic light-emitting elements were produced in the same manner as in Exemplary Embodiment 18 except that the compounds shown in Table 10 were appropriately used. Characteristics of the elements were measured and evaluated in the same manner as in Exemplary Embodiment 18. Table 10 shows the measurement results.

TABLE 10

| | | | | | 5% |
|---|---|---|---|---|---|
| | | | | | luminance |
| | | | | Color | decay |
| | EML | | | purity | time |
| | Host | Assist | Guest | evaluation | ratio |
| Exemplary | EM13 | AA22 | A-1 | Good | 3.0 |
| embodiment 19 | | | | | |
| Exemplary | EM32 | AA22 | A-1 | Good | 2.5 |
| embodiment 20 | | | | | |
| Exemplary | EM29 | AA22 | A-1 | Good | 1.5 |
| embodiment 21 | | | | | |
| Exemplary | EM11 | BB21 | B-2 | Good | 1.7 |
| embodiment 22 | | | | | |
| Exemplary | EM11 | CC21 | C-7 | Good | 2.3 |
| embodiment 23 | | | | | |
| Exemplary | EM11 | AA22 | D-3 | Good | 2.5 |
| embodiment 24 | | | | | |
| Exemplary | EM11 | AA22 | D-4 | Good | 2.5 |
| embodiment 25 | | | | | |
| Exemplary | EM11 | AA22 | D-5 | Good | 2.0 |
| embodiment 26 | | | | | |
| Exemplary | EM11 | AA22 | D-7 | Good | 1.9 |
| embodiment 27 | | | | | |
| Exemplary | EM11 | AA22 | D-8 | Good | 2.1 |
| embodiment 28 | | | | | |
| Comparative | EM11 | AA22 | Comparative | Poor | 1.9 |
| example 8 | | | compound 1 | | |
| Comparative | EM11 | AA22 | Comparative | Good | 1.0 |
| example 9 | | | compound 7 | | |

As shown in Tables 8 and 10, an organic compound according to the present disclosure can be used as a light-emitting material of a light-emitting layer to provide an organic light-emitting element with high color purity and durability. As shown in Table 10, the element life characteristics were improved by using a material with a triphenylene ring, a dibenzothiophene skeleton, or a carbazole skeleton as a host material.

2, 21 first electrode, 8, 26 organic light-emitting element, 5, 23 second electrode, 18 transistor, 27 photosensitive member, 28 exposure light source, 1200 electronic equipment, 1201, 1302, 1311, 1312 display unit, 1203 housing, 1300, 1310 display apparatus, 1400 lighting apparatus, 1402 light source, 1404 optical filter, 1405 light-diffusing unit

The present disclosure can provide an organic compound with high color purity and thermal stability. Furthermore, an organic compound according to the present disclosure can be used as a light-emitting material of a light-emitting layer to provide an organic light-emitting element with high color purity and durability.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-205002 filed Dec. 5, 2023, which is hereby incorporated by reference herein in its entirety.

What is claimed is:

1. An organic compound represented by formula (1):
Ir(L₁)(L₂)₂ (1)
wherein Ir(L₁) is represented by formula (1-1), and Ir(L₂)₂ is represented by formula (1-2): 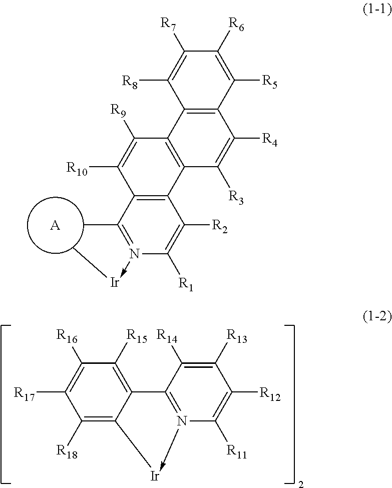
wherein a ring A is selected from a substituted or unsubstituted tricyclic or polycyclic fused ring,
R₁ to R₁₀ in formula (1-1) and R₁₁ to R₁₈ in formula (1-2) are each independently selected from the group consisting of a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heterocyclic group, a substituted or unsubstituted amino group, a substituted or unsubstituted aryloxy group, a substituted or unsubstituted heteroaryloxy group, and a cyano group,
adjacent substituents Rs in R₁ to R₁₀ and R₁₁ to R₁₈ may be bonded together to form a ring, and
two ligands L₂ may have different structures.

2. The organic compound according to claim 1, wherein the ring A is selected from the group consisting of a substituted or unsubstituted fluorene ring, a substituted or unsubstituted phenanthrene ring, a substituted or unsubstituted dibenzofuran ring, a substituted or unsubstituted dibenzothiophene ring, and a substituted or unsubstituted carbazole ring.

3. The organic compound according to claim 1, wherein at least one of R₁ to R₁₀ is selected from the group consisting of a deuterium atom, a halogen atom, a substituted or unsubstituted alkyl group, a substituted or unsubstituted aryl group, a substituted or unsubstituted heterocyclic group, and a cyano group.

4. The organic compound according to claim 1, wherein at least one of R₁₁ to R₁₈ is selected from the group consisting of a deuterium atom, a halogen atom, a substituted or unsubstituted alkyl group, a substituted or unsubstituted aryl group, a substituted or unsubstituted heterocyclic group, and a cyano group.

5. An organic light-emitting element comprising:
a pair of electrodes; and
an organic compound layer disposed between the pair of electrodes,
wherein the organic compound layer contains the organic compound according to claim 1.

6. The organic light-emitting element according to claim 5, wherein
the organic compound layer includes a light-emitting layer, and
the light-emitting layer contains the organic compound.

7. The organic light-emitting element according to claim 6, wherein the light-emitting layer further contains a second organic compound that is different from the organic compound.

8. The organic light-emitting element according to claim 7, wherein the second organic compound has at least a fused ring selected from the group consisting of a triphenylene ring, a dibenzothiophene skeleton, and a carbazole skeleton.

9. The organic light-emitting element according to claim 6, further comprising another light-emitting layer on the light-emitting layer, wherein the other light-emitting layer emits light of a color different from that of the light-emitting layer.

10. The organic light-emitting element according to claim 9, wherein the organic light-emitting element emits white light.

11. A display apparatus comprising a plurality of pixels, wherein at least one pixel of the plurality of pixels includes the organic light-emitting element according to claim 5 and a transistor coupled to the organic light-emitting element.

12. A photoelectric conversion apparatus comprising:
an optical unit including a plurality of lenses;
an imaging element configured to receive light passing through the optical unit; and
a display unit configured to display an image taken by the imaging element,
wherein the display unit includes the organic light-emitting element according to claim 5.

13. Electronic equipment comprising:
a display unit including the organic light-emitting element according to claim 5;
a housing configured to be provided with the display unit; and
a communication unit provided in the housing and configured to communicate with an outside.

14. A lighting apparatus comprising:
a light source including the organic light-emitting element according to claim 5; and
a light-diffusing unit or an optical filter configured to transmit light emitted by the light source.

15. A moving body comprising:
a lamp including the organic light-emitting element according to claim 5; and
a body configured to be provided with the lamp.

16. An exposure light source for an electrophotographic image-forming apparatus, comprising the organic light-emitting element according to claim 5.
